(19) United States
(12) Patent Application Publication
(10) Pub. No.: US 2025/0101564 A1
(43) Pub. Date: Mar. 27, 2025

(54) PROCESSES AND SYSTEMS FOR SPRAY DEPOSITION ONTO POLYMER SUBSTRATES AND VIA MASKS TO PRODUCE FLOW DEVICES

(71) Applicant: THE GOVERNING COUNCIL OF THE UNIVERSITY OF TORONTO, Toronto (CA)

(72) Inventors: Sanjeev Chandra, Toronto (CA); Ramgopal Varma Ramaraju, Toronto (CA); Joshua Palumbo, Toronto (CA)

(21) Appl. No.: 18/573,747

(22) PCT Filed: Jun. 27, 2022
(86) PCT No.: PCT/CA2022/000040

§ 371 Date: Dec. 22, 2023

(30) Foreign Application Priority Data
Jun. 25, 2021 (CA) 3123218

(51) Int. Cl. C23C 4/18; B22D 23/00; B22D 29/00; C23C 4/01; C23C 4/02; C23C 4/06

(52) U.S. Cl. CPC C23C 4/185; B22D 23/003; B22D 29/002; C23C 4/01; C23C 4/02; C23C 4/06

(57) ABSTRACT

Described in this document is a process for making heat transfer devices such as cold plates. The cold plates can be made by 3-D printing a polymer substrate, applying thermal spraying deposition of metal over the substrate, dissolving the substrate for removal to form an enclosed flow region through for passage of heat transfer fluid. Molten metal droplets can be sprayed onto the substrate having a surface region comprising a water-soluble thermoplastic to form metal splats on the surface region at a splat temperature and surface properties such that the metal splats penetrate and interlock to form a solid metal coating adhered to the polymer substrate. A dissolvable substrate can facilitate removal by contacting with a solvent to form the enclosed flow region defined by metallic surfaces, and also can enable complex geometries and enhanced heat transfer performance without the need for extensive machining.

### TECHNICAL FIELD

The technical field generally relates to spray deposition and the manufacture of flow devices, such as heat transfer devices, and more particularly to processes and systems for manufacturing such devices. The processes for manufacturing heat transfer devices, such as cold plates that include a channel for cooling fluid, can use spray deposition over a substrate, such as a thermoplastic substrate, to form the enclosed channel and then dissolving or otherwise liquefying the substrate for removal. The technical field is also related to the use of removable masks that define spray patterns for forming structures on the surface of a base which can be used in flow devices.

### BACKGROUND

In recent years, the physical size of electronic devices such as computers and mobile telephones, has greatly reduced while the number of circuit elements they contain has increased exponentially. Consequently, the energy density of these devices has vastly increased, requiring the development of new cooling methods to dissipate the heat generated in such devices. Several different methods have been used, including finned heat sinks that increase the surface area available for heat transfer, and cold plates that include metal plates with internal channels which receive a flow of cooling liquid. Methods used to fabricate such cooling devices have certain challenges in terms of being economical, easy to scale up for mass production, and flexible enough to manufacture complex shapes. In addition, certain manufacturing techniques that involve machining metal surfaces have been required and complex geometries have been difficult, inefficient, or impractical for making heat transfer devices. There is indeed a need for technologies that overcome at least some of the challenges that exists in the industry for manufacturing heat transfer devices, such as devices that would require extensive machining for complex or specific geometries of the flow channels for heat transfer fluids. There are also challenges related to the manufacture of devices that have small or complex flow channels.

### SUMMARY

Various techniques are described herein for the manufacture of heat transfer devices. The techniques can include spray coating a heat transfer material, such as metal, directly onto a substrate to coat and enclose the substrate, and then dissolving or otherwise liquifying the enclosed substrate to remove it and thereby provide an enclosed cooling channel formed of the coated heat transfer material. These techniques can take many forms and can have many applications for heat transfer devices, particularly those that have a complex channel geometry that would have required extensive machining. The substrate can be a polymer substrate that comprises water-soluble thermoplastic that is contacted with water after formation of the metal coating to dissolve the substrate and form the enclosed cooling channel.

The technology generally involves conformally spray coating metal on a polymer substrate and then removing the polymer to leave a corresponding patterned void suitable for passage of a heat transfer fluid. The heat transfer device thus includes a voided flow region previously occupied by a polymer substrate onto which the metal or other heat transfer material was spray coated. The substrate can also be referred to as a removable core.

For instance, in some implementations, a heat transfer device can be made using a process that includes spraying molten metal droplets onto a polymer substrate having a surface region comprising a soluble thermoplastic to form metal splats on the surface region, wherein the surface region has surface properties and the molten metal droplets impact the surface region at a splat temperature such that the metal splats penetrate into the surface region and mechanically interlock to form a solid metal coating adhered to the polymer substrate; and contacting the polymer substrate with a solvent fluid to dissolve the soluble thermoplastic and remove the polymer substrate to form an enclosed flow region defined at least in part by the solid metal coating, the enclosed flow region being configured for passage of a heat transfer fluid. The soluble thermoplastic can be a water-soluble thermoplastic, and the solvent fluid can be an aqueous fluid. Certain parameters can be managed during the spraying to facilitate adhesion of the metal coating onto the polymer substrate, e.g., preheating the substrate above its glass transition temperature and maintaining it below its melting temperature by removing heat, providing a surface treatment to ensure a surface roughness to increase adhesion, selecting the thermoplastic and the metal such that at the spray conditions the molten metal droplets do not melt the substrate, and providing an adhesion strength of the metal coating on the substrate that is greater than stresses formed in the substrate after cooling.

The properties of the surface region can include a roughness that is between 1 μm and 10 μm, or can include a porosity below a relatively smooth outer surface that is between 1 μm and 10 μm. In some implementations, the surface properties comprise a surface roughness between above 2 μm. In some implementations, the surface roughness enables the metal splats to penetrate the surface region, and the soluble thermoplastic and the splat temperature are provided such that the surface region remains below a melting temperature of the water-solution thermoplastic during contact with the metal splats. In some implementations, the surface properties comprise a porosity with pore size between 1 μm and 10 μm, and the splat temperature is sufficiently high to enable the metal splats to melt an outer surface of the polymer substrate and penetrate into pores thereof. In some implementations, the surface properties and the splat temperature are provided such that the solid metal coating adheres to the surface region at an adhesion strength above 2 MPa.

In some implementations, the process further includes preheating the polymer substrate above a glass transition temperature of the soluble thermoplastic prior to impacting with the metal splats to reduce a temperature difference between the surface region and the metal splats during the spraying. In some implementations, the process further includes removing heat from the polymer substrate during the spraying to restrict a maximum temperature of the surface region below a melting temperature thereof and reduce a temperature differential between the maximum temperature during the spraying and a cooled temperature of the polymer substrate attained after completion of the spraying, thereby reducing stresses generated in the solid metal coating during formation thereof. In some implementations, the polymer substrate is positioned on a metal base prior to the spraying, and the spraying is performed such that the polymer substrate is at least partially enclosed by the solid metal coating and the metal base. In some implementations, the splat temperature is provided based at least on a melting temperature of the metal, a spray distance from the polymer substrate, and a spray pass rate.

In some implementations, the process includes providing an adhesion strength between the solid metal coating and the polymer substrate that is greater than a stress generated in the heat transfer material.

In some implementations, the polymer substrate has a hollow shape and a cooling fluid is provided therein during the spraying to remove heat therefrom. In some implementations, the polymer substrate is configured as grid comprising a network of openings such that the enclosed flow region has the form of an interconnected flow network.

Various materials can be used. In some implementations, the metal comprises copper, aluminum, steel, or zinc, or an alloy. In some implementations, the soluble thermoplastic comprises a water-soluble thermoplastic and the solvent fluid comprises an aqueous fluid. The water-soluble thermoplastic can include polyvinyl alcohol (PVA), polyethylene oxide (PEO), and/or a natural polymer.

In some implementations, the aqueous fluid comprises water that is flowed in contact the polymer substrate to dissolve and remove the polymer substrate.

In some implementations, the polymer substrate is composed entirely of the soluble thermoplastic. In some implementations, the polymer substrate further comprises an additive that reduces a thermal expansion coefficient of the polymer substrate, e.g., the additive can be or comprise metal powder.

In some implementations, the polymer substrate is a 3-D printed component. In some implementations, the polymer substrate is 3-D printed based on a predetermined heat transfer pattern for a battery or circuit board and the heat transfer device is provided as a cold plate.

In some implementations, the spraying is performed such that a single metal or single alloy forms the solid metal coating on the polymer substrate.

In some implementations, the metal base comprises a base surface and raised structures extending from the base surface defining recesses, and the substrate is provided in the recesses prior to the spraying. In some implementations, providing the raised structures comprises metal spray deposition through a mask that overlies the base surface, followed by removal of the mask to expose the recesses. The mask can be composed of metal. The mask can be composed of polymer, and can be positioned to provide a gap between the mask and the base surface, have a smoothness inhibiting adhesion of metal during metal spray deposition, and have a composition and thickness to inhibit thermal deformation during spraying, such that molten metal droplets impact the base surface and agglomerate to form the raised structures having a height at or below a lower surface of the mask for facilitating release of the mask after the metal spray deposition.

In some implementations, the polymer substrate is provided as a prefabricated solid substrate that is fit within the recesses. In some implementations, the polymer substrate is provided as a paste that is provided to fill the recesses and then cured to provide a cured substrate prior to the spraying thereon.

In some implementations, there is provided a heat transfer device comprising: a fluid inlet for receiving a heat transfer fluid; a fluid outlet for expelling the heat transfer fluid; an enclosed flow region in fluid communication between the fluid inlet and the fluid outlet; and a heat transfer contact surface in heat conductive relation with the enclosed flow region, wherein the heat transfer device is made by one of the processes or methods herein.

In some implementations, there is provided a heat transfer device comprising: a fluid inlet for receiving a heat transfer fluid; a fluid outlet for expelling the heat transfer fluid; an enclosed flow region in fluid communication between the fluid inlet and the fluid outlet, wherein the enclosed flow region is defined by a solid metal coating formed by thermal spray deposition and voided by dissolution; and a heat transfer contact surface in heat conductive relation with the enclosed flow region.

In some implementations, a heat transfer device can be made by providing a base plate or base structure; locating a substrate on the base plate or base structure; applying thermal spray deposition of a material over the substrate to a coating that encloses the substrate; and converting the enclosed substrate to a fluid material for removal, thereby forming an enclosed cooling channel. The substrate can be converted by dissolution, for example by contacting with water when the substrate is made of a water-soluble material. The spray material can be metal, but can also include multiple spray layers where the outer layer could be an insulating material, such as ceramic. The substrate can take many forms to define the channel, which can define a curvilinear trajectory, a regular network of interconnected channels, or a flow region that includes flow redirection structures.

In some implementations, the enclosed flow region of the heat transfer device can be defined on a first side by a metal base and a second side by the solid metal coating.

The substrate can be made using materials that have properties permitting subsequent removal, which could be performed by dissolution, liquefying or combustion for example. It is nevertheless noted that in the polymer substrate examples described herein, the substrate could be removed or “voided” using any suitable technique. After being enclosed by spraying, the substrate can for example be removed by converting it to a fluid (e.g., via dissolution in a solvent, via liquefication via melting, or other techniques) and removing the fluid from the enclosure.

The substrate can be made using 3D printing or other suitable techniques. The substrates can be 3D printed directly onto the base plate or other base structure, if desired. The 3D printing can be programmed according to a desired channel geometry, which can be based on fluid dynamic modeling and/or specific heat transfer properties and geometries of specific equipment, such as circuits or batteries. The 3D printed substrates can have complex and small geometries which would be difficult or inefficient to produce using conventional machining methods.

It is noted that the base plate or base structure can take various forms. For example, the base plate can be a relatively flat plate with a recessed region onto which the substrate is placed prior to spray deposition. The recessed region may be machined into the base plate or formed by spraying metal through a mask to form raised structures and then subsequently removing the mask. The base structure can be a pipe around which the substrate is wound prior to spray deposition. It is possible for the base plate to have a preformed open channel or trough that corresponds to the shape of the substrate and thus forms part of the final enclosed cooling channel. It is also possible to do without the base structure, by suspending the substrate and conducting the spray deposition onto its surfaces to form the enclosed product. The substrate can have inlet and outlet members that protrude from the spray coating and define the inlet and outlet of the heat transfer device.

It is also noted that the substrate can be placed within recesses that were previously formed by overlaying a mask, which may be polymeric, above the base; spraying through the mask to form raised metal structures; and then removing the mask to expose the recesses. Various mask-related features of the process are described in more detail herein. It is also noted that polymer substrate can be provided as a prefabricated solid substrate that is fit within the recesses or as a paste that is provided to fill the recesses and then cured to provide a cured substrate prior to the spraying thereon.

Any number of complex channel geometries—which are two- or three-dimensional, based on a predetermined model of heat patterns for specific applications, coated with one or more layers of metal and/or insulating material like ceramic—can therefore be provided for heat transfer devices. The spray coating of the substrate can be conducted to provide an unfinished block or plate in which the substrate is embedded and is subsequently removed, and the unfinished block can also undergo finishing treatments to provide a desired outer surface of the heat transfer device.

There is also provided a process for manufacturing a heat transfer device, comprising: spraying molten metal droplets through a mask comprising openings and overlying a metal base to form raised metal structures extending from the base; removing the mask to expose a recessed region defined between the raised metal structures; filing the recessed region with a substrate; spraying molten metal droplets to form a solid metal coating adhered to the substrate; and liquefying and removing the substrate to form an enclosed flow region defined by the solid metal coating, the metal base and the raised structures. The mask can be composed of metal or a polymer.

The mask can be positioned to provide a gap between the mask and the base surface, can have a smoothness inhibiting adhesion of metal during metal spray deposition, and can have a composition and thickness to inhibit thermal deformation during spraying, such that molten metal droplets impact the base surface and agglomerate to form the raised structures having a height at or below a lower surface of the mask for facilitating release of the mask after the metal spray deposition.

The polymer substrate can be provided as a prefabricated solid substrate that is fit within the recesses or as a paste that is provided to fill the recesses and then cured to provide a cured substrate prior to the spraying thereon.

In some implementations, the mask is composed of metal. In some implementations, the mask is composed of polymer, is positioned to provide a gap between the mask and the base surface, has a smoothness inhibiting adhesion of metal during metal spray deposition, and has a composition and thickness to inhibit thermal deformation during spraying, such that molten metal droplets impact the base surface and agglomerate to form the raised structures having a height at or below a lower surface of the mask for facilitating release of the mask after the metal spray deposition. In some implementations, the polymer substrate is provided as a prefabricated solid substrate that is fit within the recesses. In some implementations, the polymer substrate is provided as a paste that is provided to fill the recesses and then cured to provide a cured substrate prior to the spraying thereon. In some implementations, the substrate is water soluble and the liquefying and removal thereof is performed by dissolution.

In some implementations, there is provided a process comprising: spraying molten metal droplets through a polymeric mask comprising openings and overlying and being spaced-away from a metal base to form raised metal structures extending from the base to a height at or below a lower surface of the mask; removing the mask to expose a recessed region defined between the raised metal structures; filing the recessed region with a substrate; spraying molten metal droplets to form a solid metal coating adhered to and enclosing the substrate; and removing the substrate to form an enclosed flow region defined by the solid metal coating, the metal base and the raised structures.

In some implementations, the substrate is composed of a polymer, and the removing comprises dissolving using a solvent. In some implementations, the substrate is provided as a prefabricated solid polymer substrate that is fit within the recessed region. In some implementations, the substrate is provided as a paste that is provided to fill the recessed region and then cured to provide a cured substrate prior to the spraying thereon. In some implementations, the substrate is composed of a metal having a melting temperature below that of the base and the raised metal structures, and the substrate is removed by melting and then removing molten material.

There is also provided a process comprising: spraying molten metal droplets through a polymeric mask comprising openings and overlying a metal base to form raised metal structures extending from the base; and removing the mask to expose a recessed region define between the raised metal structures; wherein the polymeric mask is positioned to provide a gap between a lower surface of the mask and the base surface, has a smoothness inhibiting adhesion of metal during the spraying, and has a composition and thickness to inhibit thermal deformation during spraying, such that molten metal droplets impact the base and agglomerate to form the raised structures having a height at or below a lower surface of the mask for facilitating release of the mask after the spraying. The process can have one or more additional features as describe herein.

The heat transfer devices and other devices can thus be made efficiently with complex geometries as well as high heat transfer performance for a wide variety of applications.

### BRIEF DESCRIPTION OF THE DRAWINGS

FIG. 1 is a photograph of a base plate composed of copper in which trough has been machined.

FIG. 2 is a photograph of a dissolvable structure insertable into the trough of a base plate.

FIG. 3 is a photograph of the base plate with the dissolvable structure positioned within the trough.

FIG. 4 is a photograph of the cold plate made by spraying copper over the base plate and the dissolvable structure of FIG. 3, after which the structure is removed by dissolution.

FIGS. 5a to 5d show stages for manufacturing a two-pass cold plate composed of aluminum using a U-shaped tubular structure inserted into the channel of the base plate and then subjected to aluminum spraying followed by dissolution of the tubular structure.

FIGS. 6a to 6d show stages for manufacturing a four-pass cold plate composed of aluminum using a U-shaped tubular structure inserted into the channel of the base plate and then subjected to aluminum spraying followed by dissolution of the tubular structure.

FIG. 7 is a graph of cold plate temperature versus flow rate with a constant heat load of 1 kW applied to compared two example cold plates with a commercial cold plate, with the water flow rate through the cooling channel being varied from 1 to 3 liters per minute (LPM).

FIG. 8a is a top perspective view schematic of a curved base plate in which a curved channel has been provided and a curved dissolvable structure has been inserted, while FIG. 8b is a bottom view photograph of an example of the curved cold plate.

FIG. 9a is a top perspective open view schematic of a base plate, illustrating a pattern of metal sprayed posts forming a fluid channel network, while FIG. 9b is a photograph of an example structure used to help form the fluid channel network. The general shape and configuration of the structure shown in FIG. 9b could be applied for use as a dissolvable substrate or a removable mask, with the structure's properties and spray conditions being adapted accordingly.

FIG. 10 is a side view schematic of an apparatus for deposition of metal structures by spraying with a twin wire arc spray system through a masking top plate.

FIG. 11 is a side view of copper posts, approximately 1 mm high, deposited on a copper surface by spraying metal through a mask.

FIGS. 12a and 12b are schematics of cold plates in which structures have been built inside the fluid channel, e.g., to increase the area for heat transfer and promote fluid mixing. FIG. 12a includes walls that extend lengthwise along the flow direction, while FIG. 12b includes pillars that are spaced-apart from each other and are distributed about the volume.

FIG. 13 is a top perspective exploded view of a cold plate including a base in which channels have been machined, a polymer substrate, and a metal lid. The cold plate was made to increase the flow of liquid under heat emitting elements on a circuit board placed on the plate. A close-up view of part of the polymer substrate is also shown.

FIG. 14 is a perspective view of a heater assembly for a commercial cold plate.

FIG. 15 is a perspective view of a heater assembly for a cold plate with curved surface.

FIG. 16 is a perspective view of a flow loop for testing cold plates.

FIGS. 17a and 17b are graphs showing variation of the average temperature with water flow rate for (a) the heater block and (b) aluminum cold plates, with 1000 W of heat applied to their surfaces.

FIG. 18 is a graph showing pressure-drop across the three aluminum cold plates with 1000 W of heat applied to their surfaces as a function of water flow rate.

FIG. 19 is a graph showing comparison of the thermal resistances of the two aluminum cold plates fabricated with that of the commercial cold plate at a constant thermal load of 1000 W. The line shows data for the commercial cold plate taken from the manufacturer's data sheet.

FIGS. 20a to 20c are graphs showing cold plate temperature (T_{cp}) and water temperature at the exit to the cold plate (Tₒ) as a function of water flow rate for the (a) commercial (b) two-pass and (c) four-pass cold plate. Data points show experimentally measured values and lines show results from numerical simulations.

FIG. 21 shows images of calculated temperature distribution at the mid-sectional plane of the (a) commercial (b) two-pass and (c) four-pass cold plate with 1000 W of heat applied to the upper surface and a water flow rate of 3 LPM.

FIG. 22 shows images of turbulent kinetic energy intensity in the (a) commercial (b) two-pass and (c) four-pass cold plate with 1000 W of heat applied to the upper surface and a water flow rate of 3 LPM.

FIG. 23 is a graph showing thermal resistance of the copper cold plate with a conformal cooling channel in it. Data points show experimentally measured values, and the solid line predictions from simulations. The dashed line shows the predicted thermal resistance of a block with a straight channel in it.

FIGS. 24a and 24b are images showing simulated temperature contours along the midplane of a copper block with 100 W of heat applied to the curved surface of a copper block with a (a) conformal coolant channel and (b) straight channel.

FIG. 25 is a series of schematics showing different arrangements and configurations of channels within heat transfer devices.

FIG. 26 is a perspective transparent view of a multiple pass cold plate with reduced thickness.

FIG. 27 is a perspective transparent view of a device with hot and cold fluids passing through channels on opposing faces of the same plate, acting as a compact heat exchanger.

FIG. 28 is a perspective view of a base plate and a mesh like substrate (also referred to as a “mask”) inserted in a recessed region of the base plate. The mask can be made of soluble polymer that defines an array of fins and is placed in a recess in the cold plate over which metal is sprayed. The fins increase internal surface area for heat transfer and promote fluid mixing.

FIG. 29 is a perspective view of a base plate and a substrate (also referred to as an “insert” or “mask”) inserted in a recessed region of the base plate. The mask can be made of soluble polymer that defines structures to guide fluid flow so as to maximize heat transfer, and is placed in a recess in the cold plate over which metal is sprayed.

FIG. 30 is a perspective view of a base plate and a substrate inserted in a recessed region of the base plate. The sheet like substrate can be made of soluble polymer with recesses and/or openings in it that define surface structures to promote fluid turbulence, and is placed in a recess in the cold plate over which metal is sprayed.

FIG. 31 is a perspective view of a metal pipe substrate around which a spiral substrate is positioned for spray deposition to form a spiral coolant channel on the outer surface of the pipe through which hot fluid is flowing.

FIG. 32 is a perspective view of a tubular combustion chamber as a substrate around which a spiral substrate is positioned for spray deposition to form a spiral coolant channel on the exterior of the of the tubular combustion chamber.

FIG. 33 is an SEM image of a zinc splat trapped in the asperities of a rough polyethylene (PE) substrate.

FIG. 34: Temperature variation of a polyethylene substrate initially at 55° C. during ten passes of a wire arc spray while coated with zinc.

FIG. 35: Single splats of zinc on PE preheated to 55° C. (a) viewed from above and (b) section through substrate made using a focused ion beam.

FIG. 36. (a) Coupon of Polyvinyl Alcohol (PVA), 50 mm×50 mm, fabricated by 3 D printing (b) Scanning Electron Microscope (SEM) image of coupon (c) SEM image after grit-blasting.

FIG. 37. SEM of coupon surface with aluminum splats after (a) first pass (b) second pass and (c) third pass of spray torch.

FIG. 38. Cross section through aluminum coating on PVA substrate with magnification (a) 200X and (b) 500X.

FIG. 39. Adhesion test of copper coatings on coupons of, from left to right, copper, PVA, PLA/Aluminum composite, PLA/Carbon Fibre composite. PLA/Copper composite.

FIG. 40. Surface roughness and adhesion strength of copper coatings on coupons of copper, PVA, PLA/Aluminum composite, PLA/Carbon Fibre composite. PLA/Copper composite.

FIG. 41. Stresses in a metal coating deposited on a polymer substrate as it cools after thermal spraying.

FIG. 42. Initial planar substrate and curved substrate after a coating is applied on the substrate.

FIGS. 43 to 48 provide additional information and test results.

FIG. 49 shows example heat sink fabrication steps. (a) Surface preparation. (b) 3D printed polymer mask with custom structures. (c) Structures grown onto the heat sink. (d) PVA paste deposited into the cavity. (e) PVA paste cured and ground to expose structures. Surface preparation for the top layer. (f) Final plate after machining and polishing.

FIG. 50 is a side view schematic of structure deposition through a polymer mask.

FIG. 51. Examples of internal 1 mm tall structures sprayed onto heat sinks. (a) Parallel fin structures. (b) Complex internal structures distributed throughout the pocket. (c) Complex internal structures with a modified outer wall shape. (d) Another complex structure.

FIG. 52 is an SEM image of a 2 mm gap between 1 mm wide fins.

FIG. 53. Coating evolution at various standoff distances where one pass represents a single line across the coupon. All samples were sprayed using a robot with a linear scanning speed of 250 mm/s.

FIG. 54. (a) Substrate temperature during 3 spray pass patterns at a 14-inch standoff distance. Solid arrows in the serpentine pattern represent when the spray nozzle is on, and dashed arrows represent when the spray nozzle is off. (b) Delaminated 0.3 mm thick coating after 18 pass patterns.

FIG. 55. Coating evolution of the heat sink sprayed manually with a scanning speed of approximately 1 m/s and a standoff distance of 14 inches.

FIG. 56. SEM images of a sample heat sink demonstrating delamination of structures from 1 mm thick top coating.

FIG. 57. 3D-printed coupons 50 mm×50 mm×3 mm; a) PLA with aluminum fillers, b) PLA with copper fillers; c) PLA with carbon fibers, and d) polyvinyl alcohol water-soluble polymer.

FIG. 58. Wire-arc spray depositing aluminum on polymer substrate.

FIG. 59 SEM images of (a) copper and (b) aluminum particles collected by spraying into a water bath.

FIG. 60. a) SEM image of the 3D printed coupon without grit blasting; b) SEM image of aluminum splat deposited on the coupon.

FIG. 61. Metal build-up on the PVA substrates, SEM of coupon surface with aluminum splats after; a) first pass; b) the second pass; and c) the fourth pass of spray torch.

FIG. 62. Cross-section through metal coating on PVA substrate a) aluminum; b) copper.

FIG. 63. PVA test coupon showing the location of thermocouples.

FIG. 64. a) Temperature recorded by thermocouples during aluminum deposition with 8 passes and b) Temperature variation during copper deposition with 5 passes.

FIG. 65. Cross-section through the copper coating on PLA substrate filled with a) aluminum b) Cu and c) Carbon fiber.

FIG. 66. Surface roughness and adhesion strength of copper coatings on coupons of copper, PVA, PLA/Aluminum composite, PLA/Carbon Fiber composite. PLA/Copper composite.

FIG. 67. Stresses in a metal coating deposited on a polymer substrate as it cools after thermal spraying.

FIG. 68. Delamination around edges of copper coatings sprayed on polymer coupons.

FIG. 69. a) 3D printed PVA plaque b) aluminum sprayed on plaque c) aluminum plaque after dissolving PVA.

FIG. 70 Cross-section through a copper plate with an internal channel made using thermal spray.

FIG. 71. Shows a final cold plate with the insert dissolved and cold plate surface ground flat, as a final version of the device shown in FIGS. 6a to 6d.

### DETAILED DESCRIPTION

Techniques described herein can facilitate manufacturing various cold plate and other heat transfer device designs using metal spray techniques in combination with a dissolvable or liquefiable structure that defines at least part of the channel during the spraying stage and then is dissolved or otherwise converted to a fluid for removal from the channel. The heat transfer devices can thus define an enclosed channel as well as the contact surfaces for heat transfer defined by one or more spray deposited materials for enhanced manufacturing and heat transfer performance.

The heat transfer device can be manufactured by spray deposition of material onto an outer surface of a substrate, which may have been 3D printed based on a complex or highly specific design tailor made for a particular heat transfer application, to form an embedded structure within a spray coated material and which is subsequently removed to provide a channel for passage of a heat transfer fluid. The channel can have a curvilinear trajectory, such as a serpentine channel; can be a network of interconnected regions such as a lattice- or grid-like channel network; or can be a flow region that includes flow direction structures that act as baffles or redirection elements to impact the fluid flow and heat transfer. The channels can also include texture elements, such as bumps or fins or grooves, which enhance fluid mixing and heat transfer.

The channel design can be based on a specific application and the substrate can be made accordingly. For example, the channel design can be based on the geometry and heat characteristics of a particular piece of equipment, e.g., a circuit or a battery, to be cooled with the cold plate. The equipment can have specific hot spots that require cooling, and the cold plate can thus be designed to provide coordinated cooling at those specific hot spots. The channel design can also be based on fluid dynamic modelling to provide a particular flow pattern and/or to reduce dead zones in the fluid flow through the channel. In addition, certain pieces of equipment, such as electronic circuit boards, can have a protective metal enclosure and it is possible to incorporate the cooling channels into these protective metal enclosures such that the enclosures are also used for heat transfer. It is noted that other equipment having an enclosure (e.g., reactor vessels, microfluidic devices) could be adapted by incorporating heat transfer channels based on the methods described herein, to provide enclosures with enhanced heat transfer capabilities.

In some implementations, a heat transfer device such as a cold plate can be manufactured by first providing a base plate that includes a channel or trough defined in its top surface. The trough has open top and can in some instances have open ends. The substrate (also referred to as an insert herein) having a shape and configuration that corresponds with than of the trough is also made. The substrate is positioned within the trough of the base plate, and then a metal is sprayed over the top of the trough to contact surfaces of the base plate and the substrate. The metal spray forms a coating that encloses the substrate and defines, with other parts of the base plate, a continuous metal channel surrounding the substrate. The substrate is composed of a material that can be dissolved in a fluid, such as water, for subsequent removal. This technique can facilitate manufacturing cold plates having complex geometries and/or small sizes, while providing high performance in terms of heat transfer.

Alternatively, the base plate could have a large recess or a flat surface onto which the substrate is placed prior to spray coating. The spray coating would then be performed to cover the substrate with a coating, after which the substrate is removed by dissolution to provide the enclosed channel defined by the coating material. It is also possible to provide a temporary wall on the base plate surrounding the substrate, the wall defining the lateral limits of the sprayed material and being removed after the spray stage is finished. The wall could define various shapes and could be composed of a material that can facilitate removal after spray coating or the wall could adhere to the coating material and become part of the heat transfer device. When the wall is removable after coating, the wall could be composed of a dissolvable or liquefiable material that is the same or different from that of the substrate.

When a base plate is used, the substrate can be configured so that its lower surface is in contact with an upper surface of the base plate, such that the upper contact surface of the base plate forms part of the enclosed channel of the heat transfer device.

In another embodiment, a base support could be used during an initial spray coating step where the top and side surfaces of the substrate are coated, and then the base support can be removed so that a second spray coating step can be performed to coat the lower surfaces of the substrate.

In another alternative embodiment, the substrate could be suspended and thus not supported by a base plate, and the spray coating would be conducted to cover the substrate with the coating material, after which the substrate would be removed by dissolution. The spray coating in this scenario could be performed by rotating the substrate during the spray coating, and/or by rotating the spray coating apparatus around the substrate. The rotation or movement could be performed continuously or with discrete movements depending on the shape of the substrate and the heat transfer device to be fabricated, among other factors. The substrate could be held by one end or two opposed ends, and could be held from the top, from the bottom or from both ends. Preferably the substrate would be held from at least one end that will defines the channel inlet or outlet, or the substrate could be provided with a dedicated part for this holding procedure.

The spray coating can be performed using a single material that can be continuously sprayed over the substrate, or performed in stages to provide multiple layers of sprayed material which can be the same or different from each other for each layer. In addition, the first layer can be sprayed at temperature conditions that would not melt and/or warp the substrate, and subsequent layers can be sprayed at different conditions that may be hotter and may use a different spray material. Thus, the spray coating operating conditions can be the same for each layer or for the entire coating stage, or can change over time.

In some implementations, the base plate can be composed of a heat transfer metal, such as copper, aluminum, steel, zinc, as well as various alloys that may be used in particular applications, such as Inconel®. It is also possible to form the base plate of another type of material, such as ceramic or plastic for certain applications where heat insulation may be desired. The base plate may be made of layers of different materials, such as an aluminum plate on which a thin coating of copper is applied to resist corrosion caused by water flowing in the passages. The base plate can be made of the same material or materials compared to the spray coating, or different materials.

The base plate can also have various forms and configurations. For example, the base plate can have a generally block-like structure with a flat bottom, side surfaces, and a flat top in which the trough is provided. The channel can be provided as a groove or a machined pathway using various techniques. The base plate can also be configured to have curved geometries, including a top surface having a domed configuration for example, for particular applications. The base plate can also have different sizes, such as having a relatively small footprint of about 1 cm² to 100 cm² (e.g., 1 cm by 1 cm to 10 cm by 10 cm for square geometries); or having a larger footprint of 400 cm² to 1000 cm². However, it is noted that smaller or larger geometries can also be implemented without limitation on size. The base plate can have a single surface that is provided with an open trough; it can be provided with multiple open troughs on the same or different surfaces; it can be flat or have a wide recess for supporting the substrate; or it can have various other shapes and configurations, depending on the final design of the cold plate.

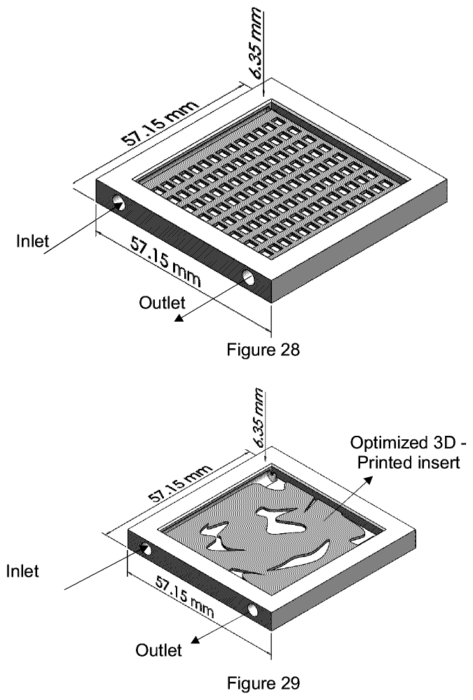

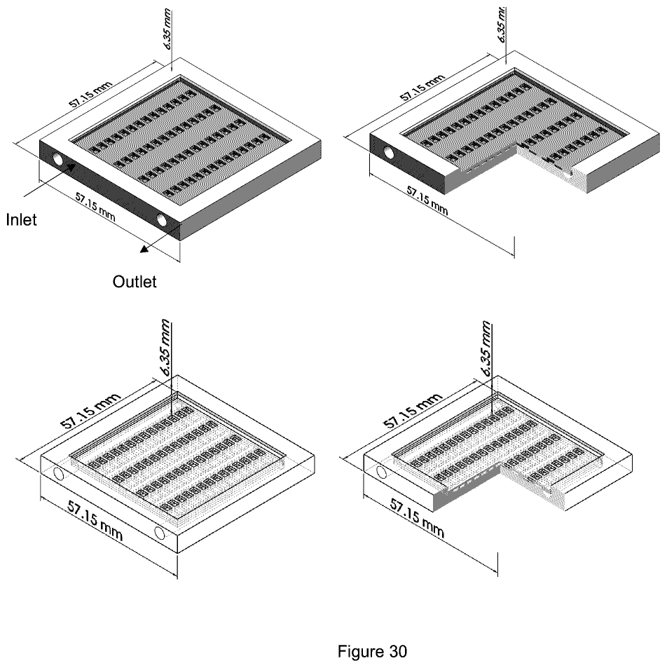

The base plate or structure can be provided with various types of indentations to support the substrate. As noted above, the base plate can include a trough-like indentation that can have a similar shape as the substrate or a different shape for receiving the substrate. The base plate can also include a recessed region, which can be a simple recess into the material of the base plate such that the recess is defined by side walls that meet the upper surface that may run around the perimeter of the base plate. The recessed region can have a depth that is greater than the height of the substrate, such that the spray coating fills in the recessed region, embeds the substrate and meets the surrounding upper surface of the base plate after spray coating to form a generally continuous upper surface. The depth of the recessed region can be calibrated based on the height of the substrate so that the final coated plate has a desired thickness of sprayed-on material above the substrate. Examples of a base plate with a simple recessed region are shown in FIGS. 28 to 30 where the recessed region has a square shape in top plan view and it receives a mask-type substrate that has a corresponding square shape to fit within the recessed region. However, it is noted that the recessed region can have other shapes and configurations.

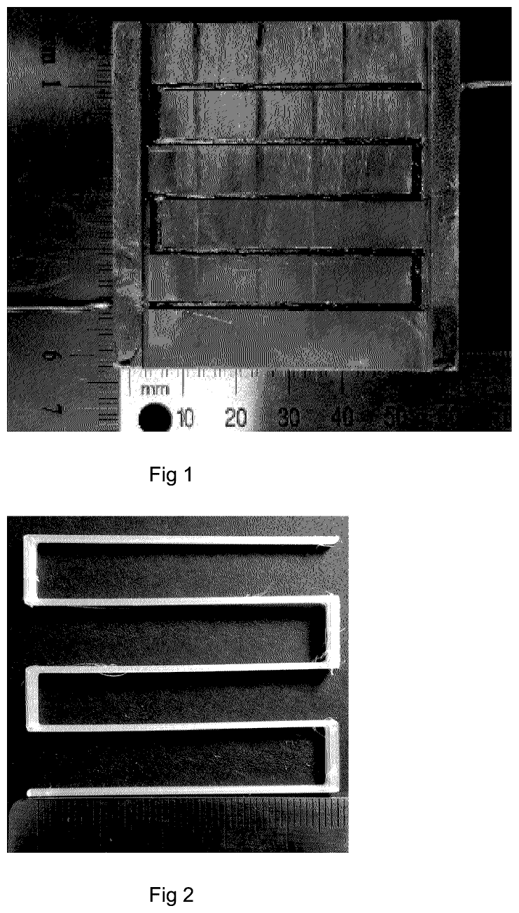

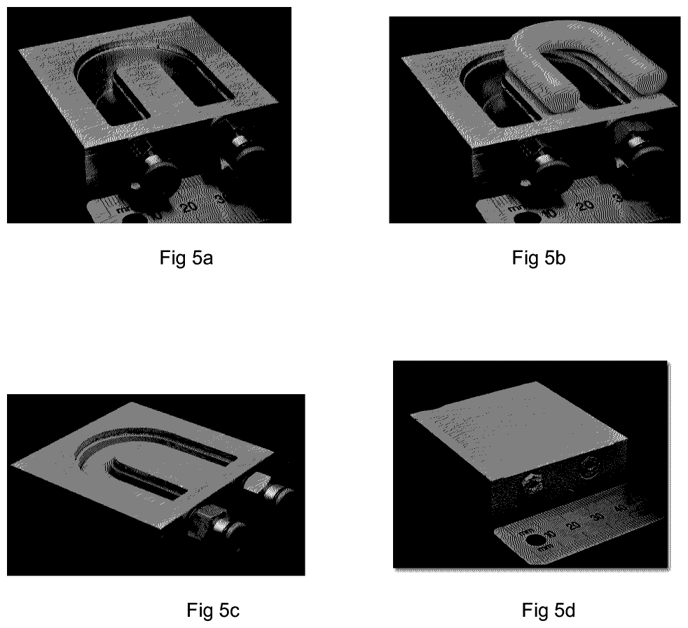

In some implementations, the indentation in the base plate is in the form of a trough that can be configured with certain geometries that form part of the final channel through which cooling fluid can flow as well as for manufacturing considerations. Examples of such base plates are shown in FIGS. 1 and 5a, for example. The trough can include a lower region that is shaped and configured to receive the substrate which can fit snugly against the lower and adjacent metal surfaces of the base plate or can have a certain amount of play within the lower region of the trough. Once installed, the top of the substrate can be inset with respect to the top surface of the base plate, thus leaving an upper region of the trough unoccupied. The upper region of the trough can be wider than the lower region, as shown in FIGS. 5a, 6a and 8a for example. The upper region can be defined by a rim that extends around both sides of the trough along its length. The upper region facilitates providing an available volume that can be filled by metal spraying, as will be described below. The substrate can be inset by about 0.3 mm to about 3 mm, for example depending on the pressure maintained in the flow channels, so that the spray coated layer can have at least that thickness above the trough.

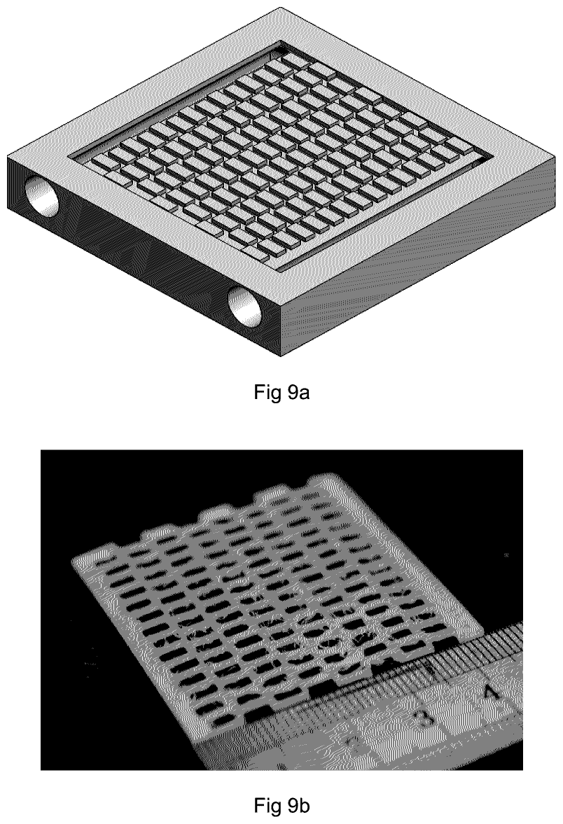

The trough can have various shapes, which can be generally elongated (e.g., a U-shape, a serpentine shape with multiple passes, a zig-zag shape, or a shape that targets predetermined locations for cooling such as on a circuit board) for formation of an elongated tubular channel in the cold plate, as shown in FIGS. 1, 3, 5, 6 and 8. Alternatively, instead of a trough, there can be a recessed region in the top of the base plate, an example of which is shown in FIG. 9. The depth, width and length of the trough or recessed region can be predetermined and coordinated with the configuration of the substrate and the final configuration of the cooling channel for the cold plate. In some implementations, the trough can have a width between about 0.5 mm and about 20 mm, between about 0.75 mm and about 15 mm, or between about 1 mm and about 10 mm. When the based plate includes the recession region as in FIG. 9, it can be generally square in plan view and can have an area of 1 cm² to 100 cm², 2 cm² to 50 cm², or 4 cm² to 20 cm², for example. It is noted that various other sizes and geometries can be used for the trough depending on the application. For example, the troughs can have a width much greater than the height for certain applications such as thin cold plates.

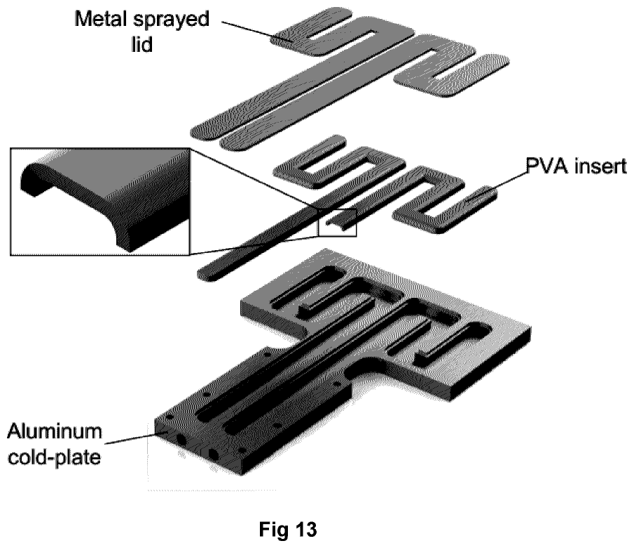

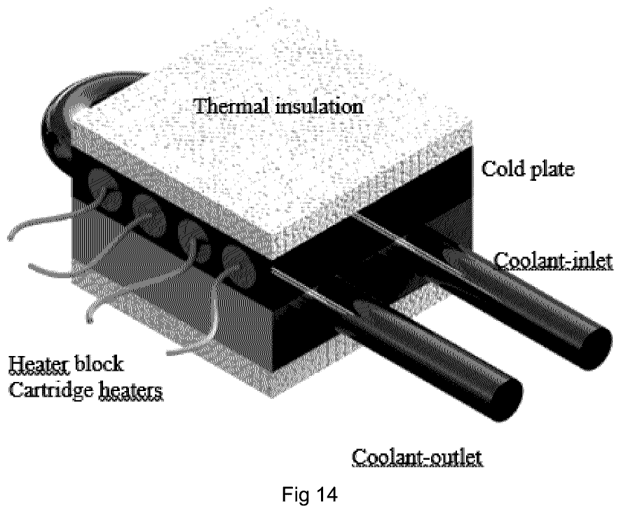

The trough is optionally formed in the base plate such that it has an open top along its entire length, although it is possible that one or more portions of it could be closed. The trough preferably has two opposed ends, although other configurations with more than two ends are possible, as in FIG. 13 for example. In addition, the trough may be closed at either end in terms of not having an aperture or a portion of the trough communicating out of the side wall of the base plate. Alternatively, the trough could have one or more of its ends that are open out the side of the base plate.

In an alternative scenario, the base plate or base structure has a recessed region into which the substrate is placed, or is flat or has another geometry that does not need to correspond with the substrate. The recessed region can be a simple inset region with a flat bottom surface that could be parallel with the upper surface of the base plate, or the recessed region could have various other shapes, sizes, and textures provided on its surface. The base plate could also be associated with mounting members that engage the substrate in a certain position on the base plate. The mounting members could be composed of metal (e.g., the same metal as the base plate and/or as the spray coating). The mounting members could include clamp members that hold one or more parts of the substrate down against the base plate, and/or spacer members that hold certain parts of the solids structure in relation to each other. When the substrate takes the form of a thin elongated structure, it may have a tendency to deviate from its original shape and therefore alignment, clamp or spacer members can be used to retain the substrate against the base plate. It is also possible to use an adhesive in small target locations over the substrate to adhere it to the base plate, although adhesives should be used sparingly to avoid compromising heat transfer performance. It is also possible to clamp the substrate onto the surface and spray metal over a portion of it and the substrate below; the metal coating anchors the structure onto the substrate so that the clamps can be removed, and the remaining portion sprayed with metal.

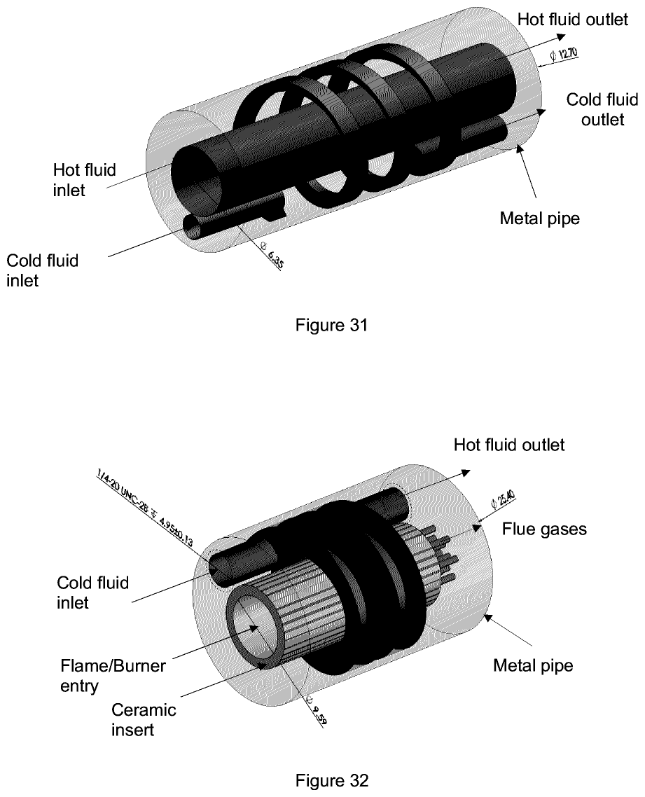

In some implementations, the substrate is configured to have a corresponding shape to fit with the base plate or structure. In one example, the substrate can be fit within the recessed region as in FIGS. 28 to 30, or trough of a base plate as in FIGS. 1 and 5A. In another example, the substrate can be configured to wrap around a tubular base structure, as shown in FIGS. 31 and 32. The solid substrate can indeed take many forms to fit within or around or otherwise with respect to the base structure depending on its configuration and the desired end result.

In one example, the substrate is configured so as to fit within the trough and define a surface onto which the metal is sprayed to form the upper coating. In this scenario, the substrate provides upper support surfaces that work to support the metal coating that forms a metallic cap which defines the top of the cold plate. The substrate may thus have a continuous outer surface that prevents penetration of the metal spray. This scenario corresponds to when the trough is elongated and has sides walls defined by the base plate, and thus the pattern of the trough is the same as the final pattern of the channel within the cold plate. Alternatively, the substrate can have openings that allow passage of sprayed metal to form additional metal structures that are spaced apart from each other. In one example, the substrate can be a mesh- or grid-like structure as shown in FIGS. 9b, 28 and 30, and can be placed within a recessed region of the base plate. After the metal spray stage, the metal coating covers the entire grid-like substrate and thus defines metal posts and a network of fluid passages. It is also noted that while the substrate positioned in the trough is preferably a one-piece structure, it is also possible to place two or more substrates within a same trough or recessed region. Thus, depending on the configuration of the substrate, the resulting channel of the cold plate can have various forms.

In some implementations, the substrate has the same length as the trough so as to fit within it from end to end. Alternatively, if the trough or recessed region has open ends, the substrate could be longer such that its opposed extremities extend out of the open ends and beyond the side wall of the base plate. This latter configuration can enable the spray coating not to cover the open ends to avoid or reduce subsequent machining steps for finishing the cold plate as openings may not have to be drilled. In addition, for troughs and recessed regions that have open ends or ports passing through part of the base plate, the open ends can be masked using tape to prevent blockage during spraying, in some implementations.

The substrate can be composed of various materials to facilitate removal after the metal spray stage has been completed. In some implementation, the substrate is composed of a polymeric material that has solubility properties enabling dissolution when contacted with a fluid. The dissolution can be performed by a flow of fluid or by contacting with fluid in other ways. The substrate can be water soluble or soluble in other fluids that can be liquid or gas. The solubility properties of the substrate can be such that heating the cold plate, e.g., by applying a heat source on an external surface and/or by heating the dissolution fluid, can accelerated dissolution and removal. In one example, the substrate is composed of a water soluble polymer, such as Polyvinyl Alcohol (PVA). Natural polymers, such as starch- or sugar-based polymers, that are formable and resistant to warpage at the spray coating conditions could also be used.

Water soluble polymers that are available in the form of filaments used in 3D printers can be particularly useful when 3D printing is employed for complex or small geometries. PVAs are one example of such a polymer type. The solid material should be soluble enough that it can be completely removed after immersing in a solvent, which could be water or another solvent. Certain polymers, such as Polylactic Acid (PLA), are soluble in organic solvents, such as ethylacetate, and therefore could be used to form the substrate and can be subsequently dissolved using organic solvent.

In general, the composition of the substrate can be provided to favor good performance in terms of formability and spray coating—which will depend on the particular size and configuration of the form of the structure as well as the operating conditions of the spray coating process—and will also be removable from the channel, which will depend on the removal method to be used. During spray coating, it is desirable that the substrate experience minimal or no warpage due to heating to maintain its shape during the spray coating. Small amounts of warpage can be acceptable depending on the precision required of the final channel of the heat transfer device. Materials that can be 3D printed to form certain shapes can be useful for producing the substrate. When removal involves dissolution using water, the material can be a water-soluble polymer that also has the formability and heat resistance properties mentioned above.

Furthermore, the substrate can be hollow or canalized, or it can be solid through its entire volume. It has been found that hollow or canalized substrates can have thin walls that can reduce warpage during spray coating, since the thermal stresses are weaker and the thinner structures can cool more quickly. In addition, it is possible to include a cooling fluid inside the substrate to receive heat from the solid material during the spray coating. The cooling fluid can be a liquid, such as water, that is provided inside a hollow volume of the substrate or is flowed through a canalized substrate. Of course, if water is used as a cooling fluid with a water-soluble substrate, then care should be taken to not prematurely dissolve the material through to its outer surface. It is also possible to cool the substrate during the thermal spraying in various ways, such as be directing compressed air or cooling gas in the form of jets or other flows, or by mounting the substrate on a cold plate that is water cooled. Various direct and/or indirect cooling methods can be used. The cooling can facilitate reducing thermal stresses and warping.

The substrate can be formed so as to have a relatively rigid body owning to the properties of the solid material composition from which it is made. Alternatively, the substrate could include a flexible outer material, such as mylar film, that is shaped into an enclosure and filled with a liquid to provide rigidity and to provide cooling during the spray coating. After spraying, the liquid can be drained and the film can be removed. In this scenario, the balloon-like substrate could be removed by leveraging volume reduction rather than dissolution, liquification or combustion.

In another implementation, the substrate can be removed by liquifying the material, which could be performed by heating or other means. This implementation could include the use of a low melting temperature metal, such as tin or bismuth, polymers, or waxes that can withstand thermal spraying without melting. Polymers and other organic materials could alternatively be removed by placing them in an oven at a temperature high enough that they burn. The substrate could also be a granular material mixed with a binder that can be melted or dissolved, where once the binder is liquified the granular material becomes unbound and can be removed.

In some implementations, the composition of the substrate can be a mixture of metal powder and a polymer. During spray coating, the metal powder that is close to the surface of the substrate can melt and join with the spray coating, especially if the metal powder is the same as the metal spray material. This approach can facilitate spray coating and can result in harder surfaces of the substrate. Some of the metal powder is integrated, but the metal powder that is closer to the center of the substrate can be removed with the polymer. The binder of the metal can be a polymer that is water-soluble or another material like epoxy that can be removed by combustion. It is also possible to make a substrate with a polymer core and an outer surface that includes another material, such as metal that can be dusted on, such that the exterior is more heat resistant and the metal dusted powder could itself become part of the metal spray coating.

The substrate can have mechanical properties suitable for fabrication, installation on the base plate or structure, and providing support during metal spraying to define the channel passage. For example, the substrate can be rigid or flexible, can be hollow (e.g., tubular) or be solid through its volume. Preferably the substrate can be suitable for certain pre-treatment applications, such as roughening (e.g., grit-blasting) and cleaning processing that could be used to roughen and/or clean exposed surfaces prior to the spray coating stage. The substrate can also have properties such that its shape remains generally constant during the spray coating stage and thus does not notably deform. The substrate can have a generally circular cross-section or can have other cross-sections that may vary. For example, channels may have cross-sections that vary periodically with distance along their length, which may be useful in enhancing fluid mixing and heat transfer.

The substrate can be manufactured using various techniques which may depend on the complexity of the shape, the size, and other factors. In one example, the substrate can be made using 3D printing. Commercially available 3D printers allow making structures out of a variety of polymers and metals and are useful for custom manufacturing small batches. The substrate can also be made by molding or extrusion techniques. The precision that is desirable for manufacturing the substrate can vary depending on the size and application, but in general the substrate need not be made with overly high precision at least because during spray coating the metal is able to coat and define the metal channel despite imperfections of the substrate.

Regarding the spray coating stage, it can be performed using various techniques and materials. In some implementations, the spray coating is performed using the same metal or alloy as that of the base plate, although it is possible to utilize different materials. The feed material can be in the form of metal powder or metal wire, for example. The operating conditions of the spray coating can vary depending on the type of metal being used and the material of the substrate. It is also possible to perform the spray coating using another type of material, such as ceramic or plastic, for certain applications where heat and/or electrical insulation may be desired. The process can also include pre-treating the base plate and/or the substrate in preparation for spray coating to enhance adherence of the metal drops for example. One pre-treatment includes cleaning the contact surfaces and increasing their roughness.

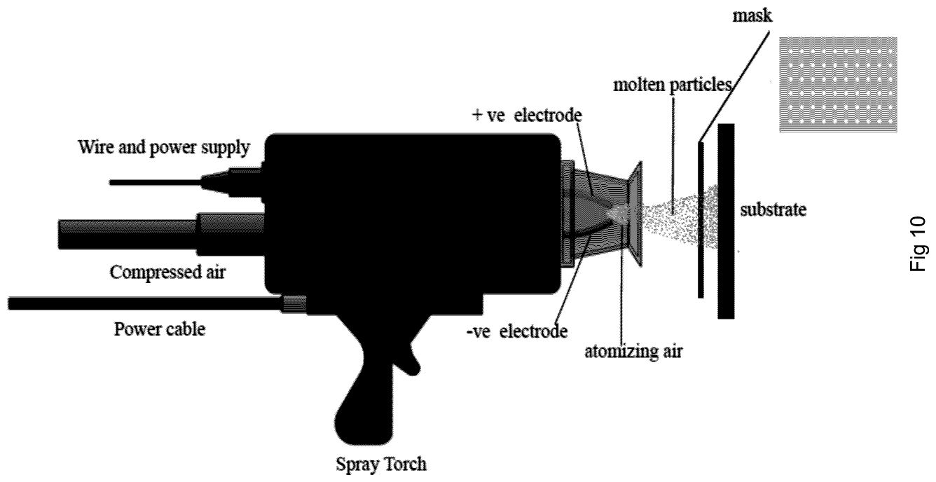

In some implementations, the spray coating comprises Thermal Spray Deposition (TSD), which refers to a family of technologies to deposit dense coatings on surfaces, in which metal, ceramic or polymers are introduced into a high temperature gas jet where they melt and atomize to create a spray of droplets. The droplets land on a solid surface, coalesce with each other and freeze to form a dense solid layer. One widely used form of thermal spray is “twin-wire arc spray”, in which an electric arc is struck between the tips of two continuously fed metal wires while a compressed air jet strips off molten metal droplets to create a spray (see FIG. 10). Another common form of thermal spray is Plasma Spray, in which a gas is converted to a thermal plasma using an electric arc, creating a high velocity and high temperature gas jet into which powders are fed. Other thermal spray methods such as High-Velocity Oxy-Fuel Spray and Flame Spray, use the combustion of a fuel gas to create a high temperature jet into which powders are injected and deposited on surfaces to coat them. There are also Cold Spray techniques in which powders are fed into high velocity gas jets that are at relatively low temperatures (200-800° C.) and accelerated to such high velocities (>1000 m/s) that the kinetic energy of the particles is enough to melt them upon impact and form a dense coating. It is noted that the composition and properties of the substrate can be varied depending on the particular spray coating technique that is used. For example, spray coating techniques that operate at high temperature can be used in conjunction with substrate that do not melt or deformed at those temperatures. Preventing or mitigating melting, deformation or other undesirable effects can be considered when selecting the material of the substrate.

The spray coating can be conducted to apply a metal material to contact exposed metal surfaces of the trough (when a base plate with channel is used) as well as the substrate, such that a single metal material fills the open region and covers the substrate to define an upper surface of the cold plate. Alternatively, a first material layer of metal coating could be applied followed by a second material layer in direct contact with the first. Water can sometimes cause corrosion and pitting in aluminum cold plates. By spraying a thin layer of copper on the base plate and more copper on top of the polymer insert, it is possible to create a protective copper layer on the inner surface of channels that resists corrosion.

Thermal spray deposition also facilitates application of layers of materials other than metals, including ceramics and polymers, if desired. For example, the process could apply a thin (e.g., approximately 20 μm) layer of ceramic on the surface of cooling plates to provide electrical insulation while still preserving cooling abilities. This can provide advantages in electrically isolating the cooling water, a concern in high-voltage and high-power circuits. Coatings can be made of ceramics such as Alumina (Al₂O₃) or Zirconia (ZrO₂) that are electrically insulating and can be deposited using thermal spray techniques. It is also possible to deposit a layer of ceramic powders such as Aluminum Nitride or Boron Nitride that are electrically insulating but thermally conductive by suspending them in a polymeric liquid that is sprayed on the surface and allowed to cure. Such coatings could be sprayed on the surface of the cold plate that is in contact with the electrical circuit to prevent transmission of electrical currents.

Furthermore, the thermal spray deposition stage can be designed and controlled in accordance with various known techniques for applying such coatings. The operating conditions can be provided to account for deposition onto both the substrate and adjacent parts of the base plate. For example, the thermal spray deposition stage can be controlled for deposition onto polymer surfaces of the substrate as well as the metal surfaces of the base plate to form a continuous coating layer. The thermal spray deposition can be controlled based on various methods and criteria, some of which are described in Devaraj et al. “Thermal spray deposition of aluminum and zinc coatings on thermoplastics” (2020) which is incorporated herein by reference. The distance of the spray nozzle from the polymer surface should be kept sufficiently large and the power supplied to the spray torch low enough that the polymer does not overheat and melt during coating. Operating conditions, such as temperature and spray distance, can be adapted for particular applications and substrate materials.

Furthermore, when the substrate is composed of a polymer, the spray deposition can be operated according to certain preferred methods. For example, the polymer insert can be preheated prior to spray deposition to enhanced adhesion. The spray deposition can also be conducted to avoid chemical changes to the polymer that would inhibit subsequent dissolution or liquification of the polymer after coating. In some implementations, the spray coating is conducted at temperature conditions that are at least 10° C., at least 20° C. or at least 30° C. lower than the degradation temperature of the polymer of the substrate.

Regarding the stage of removing the substrate from the cold plate after spray coating, there are various techniques that can be used depending on the configuration of the cold plate and the composition of the substrate. For example, when the substrate is a water soluble material, such as a water soluble polymer or another water soluble material that can withstand heating during the spray coating, the dissolution stage can be performed using operating conditions including water contact time, water flow rate, temperature, pressure, water composition (e.g., salt or additive contents), and the like to remove the polymer economically. In addition, this removal stage can be operated based on predetermined operating conditions for certain polymers as well as configurations and sizes of the substrate and channel. The dissolution stage can include continuously flowing water through the substrate when it is tubular, for example, but it can also include one or more soaking stages where the dissolution water is allowed to soak in contact with the polymer material to allow penetration and dissolution. Other techniques can also be used to dissolve the substrate. Placing the plate in an ultrasonic bath can speed up the dissolution process significantly by continuously agitating the liquid solvent.

In addition, the process can include monitoring or detecting to assess whether all of the polymer has been removed. For example, certain variables such as water passage and pressure drop can be measured to help determine whether the polymer has been removed. In addition, for cold plates that are used with water or an aqueous fluid as the cooling medium, even if small amounts of polymer residue remain in the channel, the operation of the cold plate will enable complete dissolution of the polymer. Other measurement techniques could also be used to determine whether all of the polymer has been removed from the channel, such as weighing the plate before and after dissolving the polymer and comparing the difference with the weight of the polymer, using non-destructive ultrasonic or x-ray diagnostics, and/or inputting fresh water and sampling the water exiting the channel and detecting whether it contains any dissolved polymer components.

In some implementations, prior to removing the substrate, the cold plate is prepared to facilitate the removal stage. The coolant inlet and outlet ports can be covered with tape or another type of covering during spraying to prevent them from being blocked. If the spray coating stage closed off fluid communication ports into the channel, then there may be a step of drilling or otherwise providing a port to enable access to the channel and the substrate from the outside.

After removal of the substrate, the cold plate can be further processed using various techniques depending on previous manufacturing steps. For example, the outer metal surfaces may be treated by polishing or other finishing steps. Mounting holes to attach a circuit board or other accessories may be drilled.

Implementations of the cold plates described herein can have one or more advantages over the commercial cold plates. Commercial cold plates have been made by adhering a copper tube to an aluminum plate using thermal epoxy, which can lead to significant thermal resistance and limitations in design based on the minimum radius of curvature the tube can be bent. For example, there is no distinct copper tube to be mounted within a cold plate block which eliminates the need for epoxy to bond the copper tube to the plate and therefore reduces thermal contact resistance. Indeed, the cold plates described herein do not require adhesives or other compounds to be present since the spray coating of the metal followed by removal of the substrate enables the plate body and the channel surfaces to be composed of a continuous solid metal material which enhances heat transfer. In addition, since the manufacturing technique is not restricted by the bending radius of the copper pipe, it is possible to provide a greater number of passes and/or tighter passes of the cooling channel in the same space. The manufacturing techniques described herein facilitate more flexible designs and enhanced performance. In terms of performance parameters, some examples are described herein, such as the Experimentation & Modelling section, and it is understood that operating parameters ranging around any particular value described herein by plus or minus 10% could be used, although other operating conditions are also possible.

Implementations of the devices, such as cold plates, described herein can be used in various applications. For example, in a hot stamping process, cooling channels are made in stamping dies. It is advantageous to have the channels lie just below the surface of the die, which may not be flat. In injection molding or die-casting, the molds are cooled and this process may be used to build cooling channels close to the surface of the mold. Applications such as liquid or gas heaters and water boilers require rapid heating of a fluid, which may be achieved by placing heaters on the surface of a plate in which internal channels are made. Compact heat exchangers can be made by creating channels on opposite faces of a single plate, providing efficient heat exchange between two fluid streams. Micro-reactors can be made in which different reagents enter from separate ports into the same channel in a solid plate, are allowed to mix and react, and then leave from a single port. The advantage of this arrangement over a reactor vessel is that the temperature of reaction, and therefore the product composition, can be controlled very tightly. Regarding cold plates, the cooling fluid that is passed through the cold plates can be liquid, such as a water based medium that may include additives. It is noted that various fluids and materials can be flowed through the devices described herein.

While the main implementations described herein relate to cold plates, it is noted that various heat transfer devices could be manufactured using the techniques described herein. The heat transfer devices could be using for cooling or heating or both depending on the application.

In some implementations, this design can be used to make large cooling plates, which can be placed under a large circuit board. The cooling system can be custom designed for the board, with cooling channels placed directly under heat generating elements of the board. This can greatly increase cooling efficiency. FIG. 13 is an example of a cold plate in which the channels have a serpentine shape under the locations where large heat emitting electronic components are to be located. The plate is cut away where there are no heat generating components on the board to minimize its weight.

Thermal spray can be used to make cold plates that have sub-surface mini-channels with complex geometries. Mini-channels can be considered as channels that are approximately 1 mm in diameter. Experiments were conducted to make cold plates with mini-channels using spray deposition as well as a dissolvable structure.

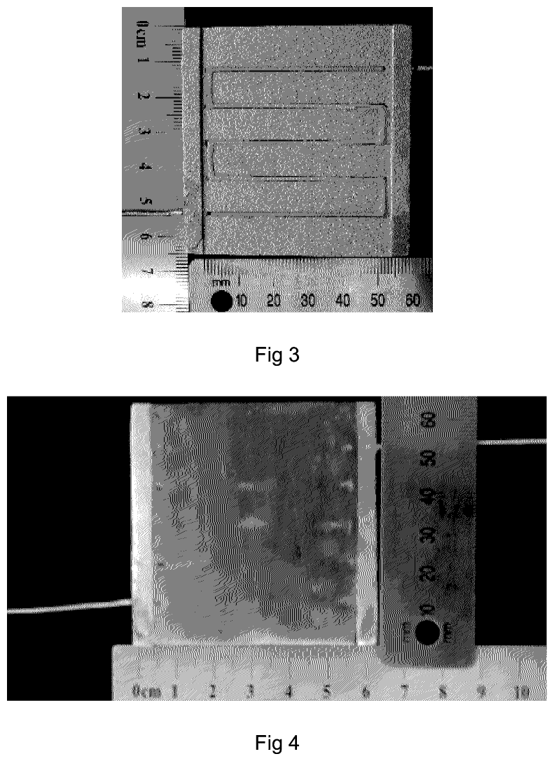

In one experiment, channels were first machined in a copper plate (see FIG. 1), then filled with a serpentine substrate, which had been 3D printed from water-soluble polymer. FIG. 2 shows the substrate while FIG. 3 shows the base plate with the substrate positioned within the trough. Copper was then sprayed over the entire plate to make a solid top layer, which can be seen in FIG. 4. The polymer was then dissolved in a water bath, leaving behind an empty channel through which cooling water can be pumped. FIG. 4 shows the final cold plate that is about 6 cm by 6 cm and includes a serpentine mini-channel.

In another experiment, cold plates having larger channels and complex shapes were manufactured. A similar method as described above for the small cold plate was used for the larger cold plates. Referring to FIGS. 5a to 5d, an aluminum plate was provided with 10 mm deep machined channels as well as integrated connection ports in fluid communication with the internal channel (see FIG. 5a). A solid polymer structure was 3D printed so as to have a corresponding shape with respect to the channel (see FIG. 5b). The structure here was U-shaped and had a hollow passage therethrough so as to be tubular. The structure was then installed within the channel (see FIG. 5c). The structure is inset below the top surface of the cold plat base. The entire plate was then grit-blasted to clean it and roughen the surfaces prior to the coating stage. Aluminum was then sprayed on top to enclose the channel (see FIG. 5d). In this experiment, the aluminum was applied with a wire-arc spray. The top of the cold plate can then be machined to make it smooth and the polymer channel is also dissolved in water to make the final cold plate. For the dissolution stage, water was passed through these channels, while a heat source was placed on the upper surface of the cold plate to raise the temperature and increase the dissolution rate. The dissolution mater was fed through the hollow tube structure to effect dissolution from the inside out and using a continuous flow of water. This type of cold plate can be referred to as a two-pass cold plate owning to the number of times the cooling fluid passes across the plate through the channel.

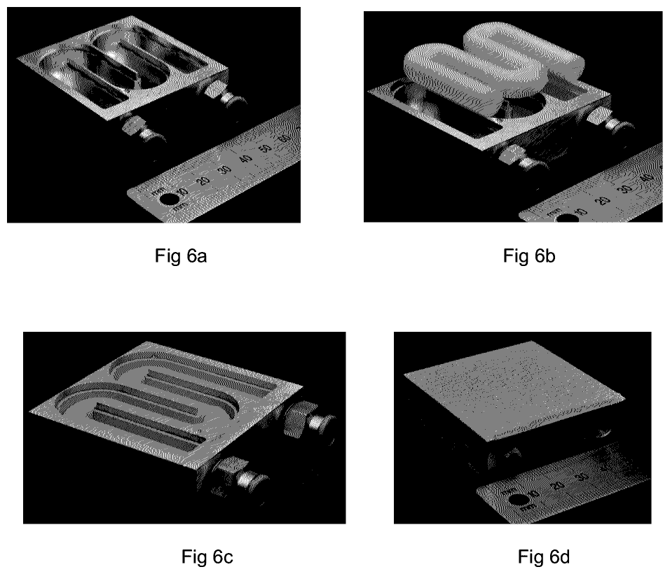

Turning now to FIGS. 6a to 6d, another example in shown where a four-pass cold plate was manufactured. This four-pass cold plate was made using similar steps as the two-pass cold plate.

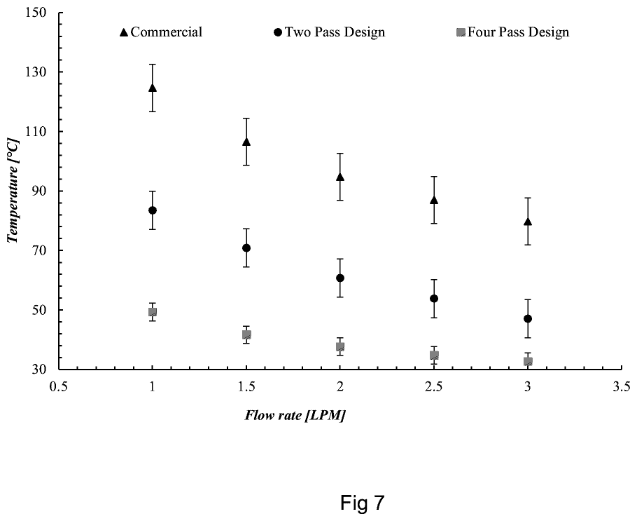

Experiments were also conducted to assess performance of the two- and four-pass cold plates in comparison to a commercially available cold plate consisting of an aluminum plate in which a copper tube is fitted and held in place by thermally conducting epoxy. FIG. 7 shown the variation in temperature of the three cold plates (commercial, two-pass and four-pass) when 1 kW of heat was applied uniformly distributed on their upper surfaces while water flowed through the channel at rates varying from 1 LPM to 3 LPM. Both spray-formed cold plates performed much better than the commercial plate, with the four-pass design being the best. At the lowest flow rate (1 LPM) the four-pass spray-formed cold plate reduced the plate temperature to 49° C., compared to the commercial plate which achieved 125° C. This is a very significant decrease. It would therefore be possible to match the performance of the commercial plate with a spray-formed cold plate that is much smaller and/or lighter and uses less water. This is a notable advantage for cooling applications on board an electric vehicle and other applications where weight and size are notable considerations.

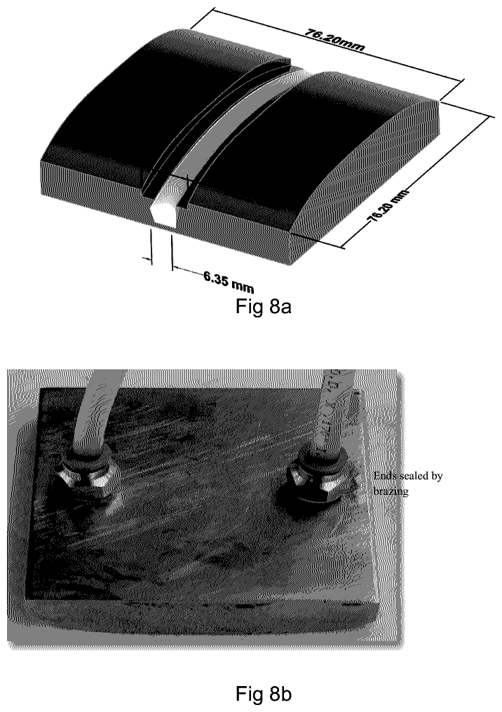

In additional experiments, the fabrication technique was used to make cooling channels on curved surfaces, which is very challenging using known methods. Curved cooling channel applications are important in certain applications, such as cooling the surface of molds or stamping dies. FIG. 8a shows a copper cooling plate with a curved upper surface. A channel was machined in the curved surface and a polymer structure with the same dimensions as the channel was made by 3D printing and installed in the channel. Copper was sprayed over it and the polymer was subsequently dissolved in water. The ends were then sealed by brazing and water inlet and outlet ports drilled through the back of the plate, as shown in FIG. 8b.

In further experiments, the fabrication technique can be used to make complex internal channels without requiring much machining. FIG. 9a shows a proposed design for a cold plate, in which the only machining required are the inlet and outlet channels and a recess on the upper surface. A polymer mask structure, which can be 3D printed, is placed in the recess and metal is then sprayed on the surface to fill the openings in the mask and form raised structures. An example of a mask structure is shown in FIG. 9b. After removal of the mask, the recessed region defined in between the raised metal structures can be filled with a substrate, and then a top coating of metal can be applied by spraying using methodologies that are described herein. In this scenario, the mask and the initial spraying through the mask are provided to promote formation of the raised structures extending from the base through the openings of the mask, releasability of the raised metal structures from the edges defining the openings of the mask and avoiding warpage of the mask during spraying.

It is also noted that a cold plate having design features illustrated in FIG. 9a could be made by placing a substrate having a plurality of openings into the recess of the base and then spraying metal on the surface to completely cover the substrate. The substrate could have the general shape and configuration as shown in FIG. 9a although it would be provided with properties to promote adherence of the sprayed metal, as described in further detail herein. In this scenario, application of the spray coatings, the substrate would be dissolved. After dissolving the substrate, the internal structure will consist of a network of channels that are separated by posts that greatly enhance the area available for heat transfer. The network structure also promotes mixing of the cooling liquid, further increasing heat transfer. This technique allows great flexibility in making different designs of cooling channels.

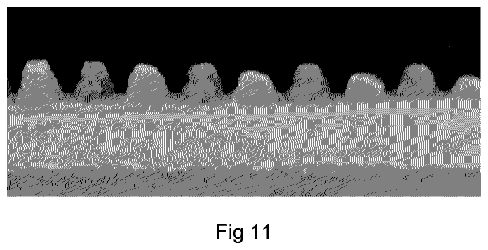

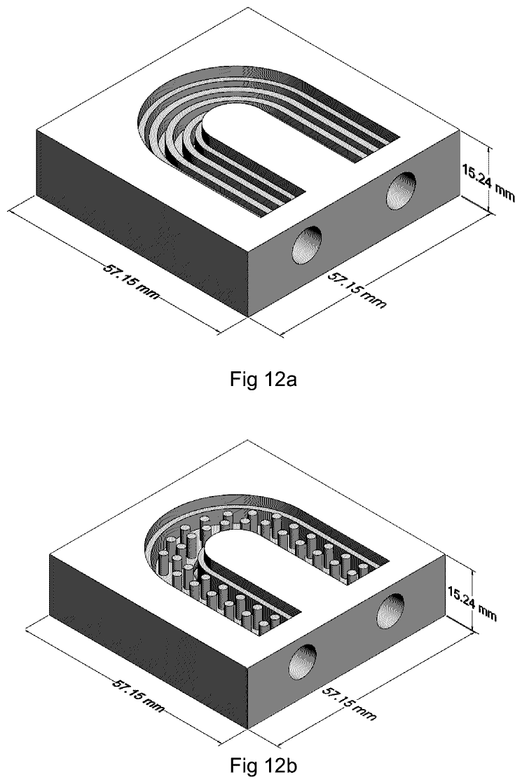

Regarding thermal spray deposition on top of a mask type structure, FIG. 11 shows 1 mm wide copper pillars that were formed by spraying copper through a mask. While the article shown in FIG. 11 did not spray until the copper covered the mask, it nevertheless shows the progression of the copper pillars that were formed by thermal spray deposition as well as the valleys formed in between the pillars. By continuing the spray coating, a top layer could be formed thereby enclosing the valleys to form a channel network. It is also possible to make cavities in the substrate that will be filled by metal during spraying. This can be used to create structures such as walls or pillars within the channels, as shown in FIGS. 12a and 12b. The internal metal structures can serve to increase the internal heat transfer area and promote fluid mixing.

In some implementations, the substrate has a predetermined geometry and is used as the template for spray coating a heat transfer material and is subsequently removed by dissolution or otherwise to provide the enclosed channel. The base plate may not be used such that most or substantially all of the enclosed channel is formed by the spray coated heat transfer material. In such as case, the substrate can be placed on a turntable to rotate it and the spray gun is held by a programmable robot that moves, as necessary, to spray the various parts of the substrate.

Regarding the arrangement of the enclosed channel in the heat transfer device, the optimum layout for cooling channels depends on the distribution of heat sources, for example, the location of components on a circuit board. There are now various computational techniques that allow optimizing the layout of cooling channels, but there has been no easy way to make complex channel shapes. An advantage of the present technology is that one can custom-make cooling plates for each unique circuit board design. In addition, the present spray-based techniques facilitate making very narrow channels. The smaller the diameter of a channel, the higher the heat transfer. This has created interest in microchannel cooling devices, but small channels are difficult to make and seal effectively. There are companies making “microchannel heat exchangers” where they use machining or chemical etching to make channels and then bond the plates together using diffusion bonding, but these are very expensive and made in a vacuum furnace. With the present techniques, one could make these types of exchangers much more easily, on larger surfaces, and on curved surfaces if required. Another advantage is the ability to make conformal cooling channels, that follow a curved surface, which is a powerful technique. Applications for conformal cooling channels include (a) stamping dies (b) die casting or injection moulding dies, and (c) furnace and oven walls.

The technology can be described as having one or more of the following combinations of features:

In some implementations, the technology includes a method for manufacturing a heat transfer device, comprising: heating a substrate to an initial temperature (Tₛ₋ᵢₙᵢₜᵢₐₗ); spraying a heat transfer material onto an outer surface of the substrate, to mechanically bond the heat transfer material with the substrate at an adhesion strength (σ_{A}); during the spraying, cooling the substrate to restrict a maximum temperature of the substrate (Tₛ₋ₘₐₓ) below a melting point of the substrate (Tₛ₋ₘₑₗₜ) to reduce a temperature differential (ΔT) as the substrate cools from the maximum temperature (Tₛ₋ₘₐₓ) to a room temperature (Tᵣₒₒₘ) and reduce a stress generated in the heat transfer material (σ_{c}) such that the stress generated in the heat transfer material (σ_{c}) is less than the adhesion strength (σ_{A}); and removing the substrate to form an enclosed flow region of a heat transfer device for passage of a heat transfer fluid.

In some implementations, the adhesion strength (σ_{A}) is between 1 to 6 MPa. The adhesion strength (σ_{A}) can also be approximately 2 MPa. The adhesion strength (σ_{A}) is based at least in part on a surface roughness of the substrate, and the surface roughness is between 1 μm to 10 μm. In some implementations, the surface roughness is approximately between 2 and 4 μm. In some implementations, the initial temperature (Tₛ₋ᵢₙᵢₜᵢₐₗ) is at approximately a glass transition temperature (T_{s-glass}) of the substrate. In some implementations, the initial temperature (Tₛ₋ᵢₙᵢₜᵢₐₗ) is above a glass transition temperature (T_{s-glass}) of the substrate. In some implementations, the stress generated in the heat transfer material (σ_{c}) is such that the deflection of the ends of the heat transfer material due to stress induced curvature is less than 1% of the length of the material. In some implementations, the heat transfer material has a coefficient of thermal expansion (α_{c}) and the substrate has a coefficient of thermal expansion (αₛ), and a difference between the coefficient of thermal expansion of the heat transfer material (α_{c}) and the coefficient of thermal expansion of the substrate (αₛ) is below 5×10⁻⁴° C.⁻¹ to reduce the stress generated in the heat transfer material (σ_{c}). In some implementations, the difference between the coefficient of thermal expansion of the heat transfer material (α_{c}) and the coefficient of thermal expansion of the substrate (αₛ) is approximately 10⁻⁴° C.⁻¹.

In some implementations, the substrate extends lengthwise along a length (L), and the stress generated in the heat transfer material (σ_{c}) based at least in part on the length (L). In some implementations, the substrate defines a hollow opening extending through the length (L) of the substrate.

In some implementations, the cooling comprises circulating air through the hollow opening. The hollow opening can have various shapes, such as cylindrical or elongated if the substrate is tubular.

In some implementations, the substrate is composed of a soluble material, and the removing the substrate comprises dissolving the substrate.

In some implementations, the substrate is a polymer. In some implementations, the substrate is a thermoplastic.

In some implementations, the technology includes a heat transfer device mold comprising: a substrate; and a heat transfer material defining an enclosed flow region formed by the substrate, wherein the heat transfer material is mechanically bonded with an outer surface of the substrate at an adhesion strength (σ_{A}) that is greater than a stress generated in the heat transfer material (σ_{c}) when the substrate is at an initial temperature (Tₛ₋ᵢₙᵢₜᵢₐₗ) and the heat transfer material is sprayed onto the outer surface of the substrate and the substrate is cooled to restrict a maximum temperature of the substrate (T_{s_max}) below a melting point of the substrate (Tₛ₋ₘₑₗₜ) to reduce a temperature differential (ΔT) as the substrate cools from the maximum temperature (Tₛ₋ₘₐₓ) to a room temperature (Tᵣₒₒₘ) and reduce the stress generated in the heat transfer material (σ_{c}), the substrate removable to form an enclosed flow region for passage of a heat transfer fluid.

In some implementations, the technology includes a heat transfer device comprising: a heat transfer material defining an enclosed flow region formed by a substrate, the substrate mechanically bonded with the heat transfer material at an adhesion strength (σ_{A}) that is greater than a stress generated in the heat transfer material (σ_{c}) when the substrate is at an initial temperature (Tₛ₋ᵢₙᵢₜᵢₐₗ)) and the heat transfer material is sprayed onto the outer surface of the substrate, the substrate is cooled to restrict a maximum temperature of the substrate (Tₛ₋ₘₐₓ) below a melting point of the substrate (Tₛ₋ₘₑₗₜ) to reduce a temperature differential (ΔT) as the substrate cools from the maximum temperature (Tₛ₋ₘₐₓ) to a room temperature (Tᵣₒₒₘ) and reduce the stress generated in the heat transfer material (σ_{c}), and the substrate removed from the heat transfer material.

In some implementations, there is provided a method for manufacturing a heat transfer device, comprising spray coating a heat transfer material directly onto an outer surface of a substrate to form an embedded substrate and then removing the substrate to form an enclosed flow region of heat transfer device for passage of a heat transfer fluid.

In some implementations, the substrate is formed based on predetermined fluid dynamic modelling for the enclosed flow region to be formed. In some implementations, the substrate is formed using three-dimensional printing. In some implementations, the substrate is formed to have a configuration based on specific predetermined heat transfer requirements of an electronics device. In some implementations, the electronics device comprises a battery or a circuit board. In some implementations, the substrate is composed of a soluble material that is dissolved for removal. In some implementations, the substrate is composed of a combustible material that is combusted for removal. In some implementations, the substrate is composed of a liquefiable material that is liquefied for removal. In some implementations, the substrate is composed of a deflatable material that is deflated for removal.

In some implementations, the substrate is hollow or canalized. This can facilitate flowing a cooling fluid through the substrate during the spraying to keep the substrate below a maximum temperature, such as a melting temperature. The substrate can be kept at least 15, 20 or 25 degrees C. below the melting temperature, for example.

In some implementations, the substrate is placed on a base structure prior to spray coating, and the base structure forms part of the heat transfer device. In some implementations, the base structure comprises a base plate. In some implementations, the base plate comprises a recessed region into which the substrate is placed for the spray coating. In some implementations, the recessed region has a depth that is greater than the height of the substrate. In some implementations, the base structure comprises a pipe. The substrate can be coiled around the pipe prior to spray coating. In some implementations, the pipe receives hot gas and the enclosed flow region is spiral shaped and receives cooling fluid to cool the hot gas within the pipe.

In some implementations, the substrate has a curvilinear trajectory such that the enclosed flow region has the form of a curvilinear flow channel passing through the heat transfer device. In some implementations, the substrate is configured as grid-like structure comprising a grid of openings such that the enclosed flow region has the form of an interconnected flow network. In some implementations, the substrate is configured as mask comprising openings, recesses and/or protrusions, such that the enclosed flow region has the form of a flow region comprising flow direction elements. The mask can be designed such that the flow direction elements provide predetermined flow dynamics to the heat transfer fluid.

In some implementations, the spray coating provides multiple coating layers. The spray coating can provide an outer layer composed of metal. In some implementations, the spray coating provides an outer layer composed of an electrically insulating material. In some implementations, the electrically insulating material comprises a ceramic.

In some implementations, the substrate has texture on an outer surface thereof to form corresponding texture elements on an inner surface of the enclosed flow region.

In some implementations, the technology provides a heat transfer device comprising an inlet, an outlet, and an enclosed flow region in fluid communication between the inlet and the outlet, the enclosed flow region being formed by a spray coated heat transfer material. The device can include one or more features as defined in any one of the paragraphs above or herein. The heat transfer device can be a cooling device.

In some implementations, the technology includes a process for manufacturing a cold plate, comprising: providing a metal base plate that includes a recess defined therein; locating within the recess a substrate having a corresponding shape as the channel; applying thermal spraying deposition of a metal material over the substrate to contact surfaces of the substrate and form a metal coating that encloses the substrate within the recess; and dissolving the substrate for removal from the channel, thereby forming an enclosed cooling flow region. In some implementations, the metal base plate is composed of copper, aluminum, steel or zinc or a high temperature alloy. In some implementations, the recess of the base plate is a trough has serpentine pattern. In some implementations, the recess of the base plate is U-shaped, serpentine or boustrophedonic, or includes a channel section that is U-shaped, serpentine, boustrophedonic. In some implementations, the substrate comprises a water soluble material. In some implementations, the water soluble material comprises a water soluble thermoplastic. In some implementations, the water soluble thermoplastic comprises Polyvinyl Alcohol (PVA), Polyethylene Oxide (PEO), and/or natural polymers such as starch. In some implementations, the substrate is a one-piece structure that fits within the recess. In some implementations, the substrate is sized to fit snugly within the recess, or to fit with a space which is at least partly filled with the metal material. In some implementations, the substrate has a circular or round cross-section or has a rectangular cross-section. In some implementations, the substrate is configured to fit within the recess and to be inset with respect to an upper edge of the recess to define an upper region between the substrate and a top surface of the base plate. In some implementations, the thermal spraying deposition is applied so that the metal material fills the upper region. In some implementations, the inset is 0.3 mm to 3 mm. In some implementations, the metal material is sprayed using twin wire arc spray, plasma spray, high-velocity oxy-fuel spray, flame spray or cold spray. In some implementations, the recess is machined into the base plate. In some implementations, the recess is an elongated channel having a width between 0.5 mm and 20 mm. In some implementations, the width of the channel is between 0.5 mm and 2 mm. In some implementations, the base plate has a flat top region in which the recess is provided, and the metal coating is provided so that a top surface of the cold plate is substantially flat and continuous. In some implementations, the process includes, after the thermal spray deposition, providing openings through portions of the base plate and into the recess to provide inlet and outlet ports; and flowing a dissolution fluid via the ports to contact and dissolve the substrate and remove dissolved material from the recess. In some implementations, the openings are drilled into the base plate, and optionally threads are tapped to install screw-in fittings to couple to a source of the dissolution fluid. In some implementations, the substrate is tubular, and the dissolution fluid is provided to flow therethrough to dissolve the same. In some implementations, the recess has an elongate channel shape that is oriented along a trajectory that lies on a flat plane, and the top of the cold plate defines a flat surface that is parallel to the flat plane. In some implementations, the recess has an elongate channel shape that has a curved profile, and the top of the cold plate defines a curved surface that follows the curved profile of the channel. In some implementations, the process includes subjecting the substrate and/or the base plate to cleaning and/or roughening prior to the thermal spraying deposition. In some implementations, the substrate has a grid shape including interconnected strands that define openings, and the enclosed cooling flow region comprises a channel network. In some implementations, the openings are arranged in a regular grid arrangement, and comprise rows and columns that are staggered or aligned with each other. In some implementations, the substrate and the corresponding enclosed cooling flow region have a predetermined configuration that corresponds to a circuit or battery having predetermined hot locations for cooling by the cold plate. In some implementations, the substrate is formed by three-dimensional printing.

In some implementations, there is provided a process for manufacturing a heat transfer device, comprising: providing a base structure; locating a substrate on the base structure; applying thermal spraying deposition of a spray material over the substrate to contact surfaces of the substrate and form a coating to enclose the substrate; and converting the substrate to a fluid material for removal, thereby forming an enclosed cooling flow region.

In some implementations, the base structure is composed of metal, ceramic, plastic or a layered combination thereof. In some implementations, the spray material is composed of metal, ceramic or plastic. In some implementations, the converting of the substrate to the fluid material comprises dissolving the substrate. In some implementations, the base structure comprises a base plate or a pipe. In some implementations, the base structure comprises a recess in which the substrate is provided for the thermal spraying deposition. In some implementations, the process includes one or more features of any one of the features described herein.

In some implementations, the technology includes the use of the cold plate or heat transfer device as defined above or herein for cooling electronic equipment, cooling mold and die surfaces.

In some implementations, the technology includes the use of the cold plate or heat transfer device as defined above or herein, as a heat exchanger, a fluid heater, and/or a microreactor.

In some implementations, the technology includes system for manufacturing a heat transfer device, comprising: a base structure; a substrate configured to be placed on the base structure; a thermal spraying deposition apparatus configured to provide a spray of material over the substrate when located on the base structure to contact surfaces of the substrate and form a coating to enclose the substrate; and a removal assembly configured to convert the substrate to a fluid material for removal, thereby forming the heat transfer device with an enclosed cooling flow region. In some implementations, the base plate and/or the substrate have one or more features as defined above or herein. In some implementations, the thermal spraying deposition apparatus is configured to receive a powder or a wire to form the spray of material. In some implementations, the spray of material comprises a metal. The thermal spraying deposition apparatus can have one or more features as described herein and/or can be operated as described herein. In some implementations, the removal assembly comprises a source of aqueous liquid, a pump, and conduits in fluid communication with the channel for circulating the aqueous liquid to effect dissolution of the substrate.

In some implementations, the technology provides a spray-formed cold plate, comprising: a base plate that includes a recess; a spray-formed metal coating enclosing the recess and defining, with the base plate, an enclosed cooling flow region defined by spray-coated surfaces for contacting a heat transfer fluid flowing there-through; a fluid inlet in fluid communication with the enclosed cooling flow region; and a fluid outlet in fluid communication with the enclosed cooling flow region. In some implementations, the fluid inlet and outlet are machined through a side of the base plate to join the enclosed cooling flow region. In some implementations, the cold plate includes an outer spray-coated layer that is composed of metal. In some implementations, the cold plate includes an outer spray-coated layer that is composed of ceramic. In some implementations, the enclosed cooling flow region has an elongate channel shape defining a curvilinear trajectory. In some implementations, the enclosed cooling flow region comprises a network of interconnected channels. In some implementations, the enclosed cooling flow region comprise flow direction elements for enhancing fluid mixing and/or reducing dead zones in the enclosed cooling flow region. In some implementations, the enclosed cooling flow region is arranged based on fluid dynamic modelling for a target cooling application. In some implementations, the cold plate includes one or more additional features as defined herein, e.g., in terms of materials, shape and/or manufacture.

In some implementations, there is provided a process for manufacturing a heat transfer device, comprising: forming a substrate by three-dimensional printing; spray coating a material over the substrate to form a coating to enclose at least a portion of the substrate to define an enclosed flow region in which the at least a portion of the substrate is embedded; and dissolving, liquifying, deflating or combusting at least a part of the substrate to enable removal of the substrate from the enclosed flow region. In some implementations, the substrate is placed into a recess defined in a base plate, and the spray coating is performed to enclose the at least a portion of the substrate within the recess of the base plate, which forms part of the heat transfer device. In some implementations, the substrate is suspended and/or rotated while being subjected to the spray coating. In some implementations, the substrate is placed on a support, the spray coating is performed to enclose the at least a portion of the substrate on the support, the support is then removed to expose an uncoated portion of the substrate, and further spray coating is performed to coat the uncoated portion of the substrate. In some implementations, the substrate is composed of a polymer. In some implementations, the substrate comprises a particulate material and a binder that binds the particulate material together, and at least the binder is subjected to the dissolving, liquifying, deflating or combusting. In some implementations, the spray coating comprises spraying a first layer of a first material and then spraying at least one subsequent layer of a second material. In some implementations, the first layer is composed of a first metallic material. In some implementations, the subsequent layer is composed of a second metallic material. In some implementations, an outer layer of the spray coating is composed of an outer metallic material. In some implementations, an outer layer of the spray coating is composed of an outer insulating material. In some implementations, the insulating material comprises a ceramic.

It is also noted that the processes and methods described above can use various operating parameters for spray coating the heat transfer material onto the substrate to enable adhesion of the metal coating onto the surface of the substrate. Factors that can be adapted includes the melting temperature of the sprayed metal and that of the polymer, the glass transition temperature of the polymer substrate, the composition of the polymer substrate, the splat temperature of the metal when impacting the polymer, surface properties of the polymer substrate such as roughness and porosity, preheating of the substrate prior to spraying, cooling of the substrate during spraying, spray pass rate and spray distance, among other factors.

Implementations with Removable Mask

In another implementation, the heat transfer device can be manufactured by providing a removable mask having openings; overlaying the mask with respect to a base; spraying through the mask so that the spray contacts the base through the openings and forms a pattern of raised structures on the base; removing the mask to expose recesses in between the raised structures; providing a substrate in the recesses; spray coating the top of the substrate; and then removing the substrate to define an enclosed flow region. In this case, the mesh is used temporarily for spray deposition of the raised structures and is removed before the next step where the recesses are enclosed. In this example, the process can be viewed as having two spraying stages: a mask-spray stage and a substrate-spray stage.

It is noted that in some embodiments a device can be manufactured using a process that includes providing a removable mask having openings; overlaying the mask with respect to a base; spraying through the mask so that the spray contacts the base through the openings and forms a pattern of raised structures on the base, to form open channels or flow regions, where subsequent enclosing of the flow regions is optional and can optionally be performed using the polymer substrate as described herein.

The removable mask can be composed of a polymeric material, a metal, or another material having properties that discourage adhesion of the sprayed-on raised metal structures that would damage the structures upon removal of the mask, and that would maintain shape and position during the metal spraying process. Polymeric masks can be 3D printed to provide various complex shapes and structures. Polymeric masks used in the process can also have a suitable surface roughness to avoid adherence of the sprayed metal, where the low surface roughness is provided by a treatment or is an inherent or target feature of the mask due to the material or fabrication. In addition, the polymeric masks can also have certain thickness to avoid warpage due to the temperature change conditions experienced during thermal spray deposition, and the spray process can be controlled (e.g., distance from mask, temperature of droplets, speed and frequency of spray passes) to minimize thermal stresses in the mask.

It is also noted that the process can be controlled such that the polymer mask remains below its glass transition temperature during the thermal spraying. Temperature control can involve providing a certain distance from the thermal spray device and also managing the timing of the passes (e.g., speed of each pass and time in between each pass). Depending on the polymer that is selected for use as the polymer mask, the glass transition temperature can change and thus the process can be controlled accordingly. The thermal spraying can be performed so that the polymer mask remains at least 5° C., at least 10° C., or at least 15° C. below its glass transition temperature. It is also noted that a gap can be provided in between the mask and the base, and the thermal spraying is performed so that the raised structures remain within the gap and thus are at or below the lower surface of the mask. Other features regarding the mask and thermal spraying therethrough will be discussed in more detail below.

Once the mask is removed and recesses are exposed, the substrate can be provided in the recesses to facilitate a second stage of spray deposition to form the top of the device and enclose the flow regions. In this case, the substrate can be polymer as described herein or can be another material that can be subsequently removed from the enclosed regions. For example, the substrate could be a metal having a lower melting temperature compared to the metal of the base and spray-deposited metal, such that subsequent removal of the substrate is performed by heating about the substrate's melting temperature and providing fluid communication with the exterior to remove the melted metal substrate. Such metal substrate could be provided into the recesses by pouring molten metal to fill the recesses and then allowing the metal substrate to cool before spray deposition of the top coating.

In addition, the substrate could be a solid polymer substrate that is 3D printed or otherwise prepared to have a configuration corresponding to the recesses for insertion. The solid polymer substrate could have various profiles (e.g., solid as shown in FIG. 1, tubular with a hollow center as shown in FIGS. 5 and 6, or U-shaped as shown in FIG. 13). Alternatively, the substrate could be a paste or other semi-solid material that can be applied by injection, spreading or other methods into the recesses.

The mask is composed a material that can withstand the impact of thermal spray particles but to which the particles have low adherence. Details regarding example properties of a polymer mask are described further below. If the mask is made of metal its surface should be smooth enough to prevent adhesion of impinging molten metal droplets. If the mask is made of polymer the surface should have a roughness below 0.4 μm, below 0.3 μm or below 0.2 μm, for example, to prevent adhesion to the mask, and its temperature during spraying can be kept well below its glass transition temperature to prevent softening. Polymer masks can be made by 3D printing using a high temperature resin, for example. The masks may be separated by a distance of 0.5 mm to 1 mm from the base plate during spraying to facilitate mask removal after the structures are formed, although this spacing can vary depending on the height of the structures to be deposited. This gasp between the mask and the base can be provided by building a step into the mask, placing a thin metal shim under the edges of the mask, holding the mask in place using a support member to hover above the base, etc. Additional information regarding the process of spraying through a polymer mask to provide the raised structures will be described further below.

An example process of spray depositing through the mask has various steps and considerations for enhancing manufacture of the product. It is noted that the use of the mask provides a method of additively manufacturing surface structures in complex patterns on a workpiece (which can also be referred to as the base) using thermal spray techniques to deposit metals. Thermal spray refers to techniques in which molten or softened metal is accelerated toward a workpiece. By controlling the location of metal deposition, which is facilitated by the mask, complex metal structures can be fabricated onto the workpiece.

A first step in the process can be roughening the workpiece surface to improve adhesion of the molten metal to the workpiece. The workpiece can be roughened using various methods, such as grit blasting with a powder such as aluminum oxide powder, to achieve a roughness between 2 μm and 5 μm. The roughness can be provided depending in part on the operating conditions of the spray deposition (e.g., type of metal, temperatures, droplet velocity).

Next, a custom polymeric mask with the desired structure pattern is provided. The polymeric mask can be prefabricated using several methods, such as laser cutting of a plastic sheet, 3D printing using a high-temperature photopolymer resin, or subtractive machining methods. The mask is placed over a surface of the base, which may be a recess machined in the base, and metal is sprayed through the mask. It has been found that it can take approximately 20-25 minutes to deposit a 1.3 mm thick layer of metal on the base plate with the following example operating conditions:

| Variable | Input |
|---|---|
| Torch | ValuArc |
| Wire feed rate | 7 m/min |
| Voltage applied | 28 V (Aluminum) |
| | 32 V (Copper) |
| Air inlet pressure | 690 kPa |
| Robot scanning speed | 250 mm/s |
| Spraying distance | 23 cm |
| Number of passes | 30 (Aluminum) |
| | 20 (Copper) |

After the spraying is complete, the mask is removed to reveal the pattern sprayed on the base plate.

In the context of designing and preparing the mask, several parameters can be controlled during the fabrication of the mask:
(1) The polymer used for the mask is selected to be able to withstand the temperature of the thermal spray during deposition. It was found that a standard Formlabs™ resin with 3 mm thickness did not withstand the thermal load under the above summarized conditions. Note that high-temp resins provided adequate thermal properties. The following heat deflection temperatures at 0.45 MPa are reported by Formlabs: Standard resin: 73° C., high temp resin: 120° C. Polymer resin selection can be performed accordingly and can also be tested to assess thermal suitability.
(2) The mask can be provided with adequate thickness to withstand the thermal stresses during structure deposition. It was found that certain polymer masks failed during structure deposition due to inadequate thickness, notably Formlabs standard and high temperature SLA resin with a thickness of 3 mm.
(3) The surface of the polymer mask can be polished to reduce build-up of material on the surface of the mask and clogging of the mask openings. Inadequate polishing can result in roughness that can lead to clogging of the mask openings, depending on the size and configuration of the openings and other conditions. An average roughness of 0.4 μm or lower was preferred at the tested operating conditions.
(4) The side walls defining the openings of mask structures are preferably vertical or have an outward taper toward the base (where the opening closer to the base is larger than the opening closer to the spray nozzle) to inhibit material build up in the mask and facilitate removal. Warping of the mask due to issues discussed in items (2) and (3) above can cause the bottom of the pattern to protrude into the pattern opening, resulting in material build-up, and clogging of the mask.

The next step is the deposition of the thermal spray through the mask onto the workpiece. Several parameters can be controlled during the deposition process to enhance this step of the process:
(1) The distance between the spray nozzle and the workpiece, or standoff distance, can be adjusted to control the temperature of the impacting thermal spray particles. Increasing the standoff distance reduces the temperature of the mask during deposition.
(2) The polymer mask should be offset from the workpiece, ideally by an amount greater than the desired height of the raised structures. Failure to include this gap can result in the structures bonding to the mask and cracking during mask removal.
(3) The mask openings that are receiving the sprayed droplets are preferably oriented normal to the spray nozzle. Deviations can result in a shadowing effect of the spray and cause lopsided structures.
(4) To facilitate uniform coating of the mask, the spray nozzle can be mounted to a robotic arm which can be controlled precisely by a control system.
(5) The workpiece is preferably given adequate time to cool between passes of the spray nozzle. Excessive temperatures may cause the raised metal structures to delaminate from the workpiece. This challenge can be more pronounced for larger structures, whereas for smaller structures it may be less of an issue.
(6) Compressed air, or other techniques, can be used to remove debris from the mask between passes of the spray nozzle. Failure to remove debris can result in clogging of the mask openings. The amount of debris collected on the surface of the mask can be reduced by reducing the surface roughness through polishing, as described in item (3) above of the mask fabrication method.
(7) Structures with a flat top can be fabricated by depositing metal to a height larger than the intended design and machining them to the desired height. It was found that the raised structures can initially have a dome-like shape after spraying, and these structures can be flattened by machining to provide flat surfaces which can be at a uniform height. For example, machining with an end mill or grinding has been used. Grinding is preferred for a better surface finish. Uniform height can be ensured during the machining process by controlling the height of the cutting or grinding tool.

Various examples of structures were fabricated using the mask techniques. FIG. 51 shows some of these structures deposited on a base. The example fabricated structures had length scales in the range of 0.5 mm to 74 mm. These structures had a height of 1 mm and were deposited in under 20 minutes. Typically, these complex structures would be fabricated using metal 3D printing, which is more time-consuming and costly compared to the mask methods described herein. These mask-made structures were fabricated out of aluminum using a wire-arc thermal spray technique. By way of example, 1 kg of aluminum wire costs only 10 USD, whereas the same amount of powder for 3D printing is approximately 140 USD. The potential cost savings for manufacturing these types of small complex structures is thus notable.

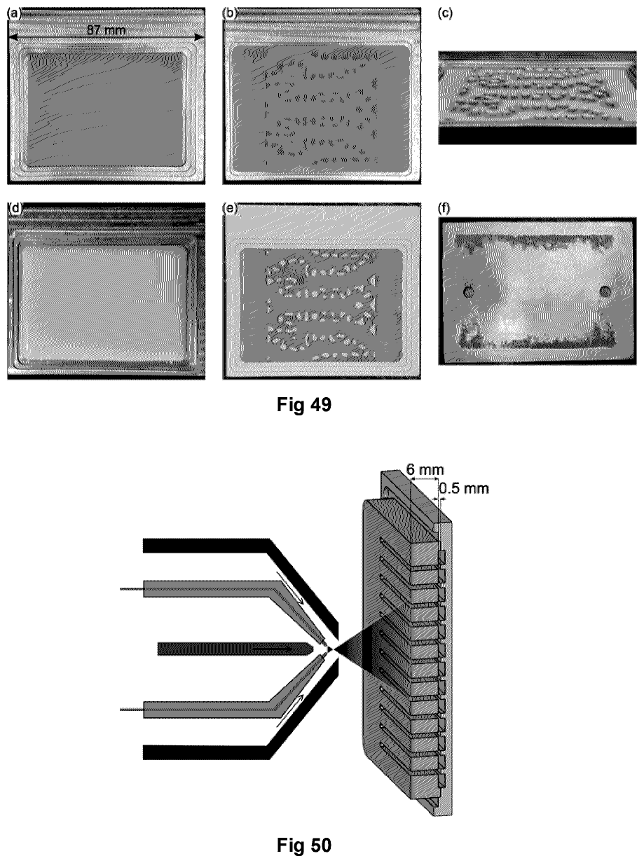

FIG. 49 illustrates the steps for the fabrication of an example heat sink in which internal flow channels are made using a removable mask. First, a 2.5 mm deep rectangular pocket with a length of 74 mm and a width of 51 mm was machined into an aluminum plate. Two steps with an offset of 2 mm and 4 mm from the pocket wall and respective depths of 1.5 mm and 0.75 mm from the top surface were added to improve the adhesion of the top coating. The bottom surface of the pocket was then roughened by grit blasting with aluminum oxide powder. The additional material above the pocket was kept for securing the heat sink to the support structure during the wire-arc spray process. Next, a custom mask was 3D printed using a high-temperature photopolymer resin and press-fit into the pocket, shown in FIG. 49 (b), with a gap between the central region of the mask and the base. FIG. 49 (c) shows the structures after they have been additively manufactured using wire-arc spraying. Polyvinyl Alcohol (PVA) paste (or other voidable polymer, which can be generally referred to as a substrate) was then deposited into the pocket and allowed to cure at room temperature (FIG. 49d). Once cured, the PVA paste was ground down to expose the internal structures at a height of 1 mm, coincident with the inner step height. The PVA paste, structures, and surrounding plate were grit blasted using the same parameters as described above. The resulting plate is shown in FIG. 49(e). A 1.5 mm layer of aluminum was then deposited into the pocket, forming a sealed cavity. After coating was complete, the plate was machined to the desired dimensions of 87 mm long by 64 mm wide by 4 mm thick and 5 mm inlet and outlet holes were added to the coated surface. The PVA paste was then dissolved by placing the heat sink in a water bath. The final heat sink is shown in FIG. 49(f). FIG. 51 shows different structures on aluminum plates that were made by spraying aluminum through 3D printed polymer masks, which could be formed into heat sink devices by providing a corresponding substrate followed by spray deposition of the top coating.

In some implementations, the process can include the mask-spray stage for the formation of the raised structures on the base and then removal of the mask, followed by an enclosing stage where a top is installed to enclose the recesses and form the flow channels or network. While the top can be provided using spray deposition, as described above, it could alternatively be provided in various other ways. For example, the top can be prefabricated, overlayed with respect to the base, and then coupled to the base and/or the raised structures using various techniques (e.g., welding, fasteners, adhesives, etc.) to form the enclosed channels, depending on the end use of the flow device. The top could be composed of metal or other materials, again depending on the end use of the flow device.

In terms of potential applications of the flow devices, the devices can be designed and manufactured for heat transfer (e.g., heat sinks, heat exchangers), microfluidics (e.g., microreactors), or to make fluid channels below surfaces that need to be uniformly cooled such as molds used for plastic injection molding or aluminum die casting, stamping dies, or furnaces, or other applications where a fluid is flowed through the channels.

In some implementations, the process can be used to apply spray deposited metal structures onto a base via a polymer mask for purposes other than the manufacture of flow devices. For example, thermal spray is used to repair mechanical components by depositing metal on worn and damaged areas and machining them back to their original dimensions, while the undamaged portions of the component are masked off with high temperature tape to prevent sprayed metal adhering to them. Cutting masking tape by hand is a laborious and time-consuming process. Instead, a polymer mask could be fabricated (e.g., via 3D printing) to cover the components, leaving only those portions exposed on which the spray should be deposited. Thus, the polymer mask could be used in such thermal spray-repair applications or similar situations. In other applications, masks can be used to spray features such as pins or fins on surfaces to enhance fluid turbulence or increase the area for heat transfer. The polymer masks could be used not only in processes to form closed flow channels or networks, but also in processes to form open channels or networks.

### Experimentation, Modelling & Discussion

The following sections relate to work conducted for making and evaluating example cold plates. The work included fabrication of cold plates, experimental testing, and modelling.

In general, a new spray forming method was developed for making channels just below the surfaces of cold plates. Channels were milled on the surface of aluminum or copper plates and inserts (also referred to herein as substrates) made from poly vinyl alcohol, a water-soluble polymer, by 3D printing were placed in them. A layer of molten metal, 2-3 mm thick was sprayed on the surfaces of the plates using a twin wire arc system so that the channels were completely buried. The plates were placed in water to dissolve the polymer inserts, leaving the channels open for coolant flow. Using this method, flat aluminum plates with coolant channels with either two or four passes through the plate were made. A conformal cooling channel was made in a copper cold plate, lying under a curved surface and following its contours.

The performance of the aluminum cold plates was tested by applying a heater block dissipating 500-1000 W on their surfaces while passing 1.0 to 3.0 L/min of water through the channels. The temperatures of the heater block, cold plate and water at the inlet and outlet were measured. The plates fabricated in this work were found to have a significantly lower thermal resistances than commercial cold plates made by bonding a copper tube to an aluminum plate. Thermal contact resistance between the tube and plate was avoided in the plates made by thermal spray. It was possible to machine multiple passes of the cooling channel in the same plate area, increasing the surface area wetted by the liquid. A longer flow path, and multiple bends in the channel, promoted turbulence in the flow and enhanced heat transfer. It was also possible to make conformal cooling channels that were closer to the surface than straight-drilled passages, enhancing heat transfer.

Cooling of devices that are producing high heat fluxes is a challenging technical problem since it is difficult to transport large amounts of energy rapidly and prevent the emitting surfaces from overheating. Electronic cooling is one example of such an application, where large amounts of heat are dissipated inside small electronic packages. Air cooling is often inadequate for power circuits that carry large currents, so circuit boards are mounted on metal cold plates that are water cooled. The design of internal channels in such plates to carry cooling liquid has been a subject of intensive research. The simplest configuration is to bond a copper tube to an aluminum cold plate; however, heat transfer in such plates is limited by the thermal resistance between the tube and plate. The cooling performance can be improved by directly drilling or machining holes in the plate, but this raises fabrication costs. Reducing the hydraulic diameter of channels increases the convective heat transfer coefficients at their walls and therefore high-performance heat exchangers employ small channels (100 μm to 1 mm in diameter). Machining small channels is difficult, so naturally porous materials, such as metal foams, have been used in heat transfer applications.

Cooling plates are often required for applications where individual heat sources are distributed over a large area, such as in circuit board for computer servers or batteries for electrical vehicles. In such applications, instead of placing regularly spaced cooling channels in a cold plate, it is more efficient to concentrate them under the principal heat sources. However, fabricating cold plates that are tailor-made for each particular circuit board is difficult. Additive manufacturing techniques are one possible way of developing custom-made heat exchangers, but it is expensive to use such techniques for mass production of metal components.

Dies for hot stamping and forging, and molds for casting and injection molding, also require fabrication of internal cooling channels. These applications offer the additional challenge that the surface to be cooled is usually not flat. In current practice straight cooling channels are drilled in the dies or molds, in which case the distance between the channel wall and the heated surface varies, creating temperature gradients and thermal stresses. Temperature differences can also create local variations in the metallurgical properties of the parts being made. It would be preferable to have channels that follow the surface profile and provide uniform heat transfer. Conformal cooling channels, that lie just below the face of the mold or die and follow its surface contours, have been made using powder metallurgy, lost wax molding, or other rapid prototyping methods.

In this work, a new method of fabricating conformal cooling channels in copper and aluminum plates using thermal spray techniques was developed. Channels are milled on the surface of a metal plate in any desired pattern. Inserts (also referred to as substrates) in the exact or similar shape of the channels are made using a 3D printer out of a water-soluble polymer. The inserts are placed in the channels and molten metal is sprayed on the surface of the metal plate using a twin wire-arc system. This wire-arc spray coating process is a widely used industrial process in which an electric arc is struck between the tips of two continuously fed wires. As the wires melt a compressed air jet is used to strip molten metal off the tips of the wires, creating a spray of droplets that land on the surface being coated, freeze and form a dense coating, 1-3 mm thick. The plate is then placed in an ultrasonic bath for several hours to dissolve the polymer inserts, leaving open the channels under the sprayed surface.

This technique was used to make serpentine channels in aluminum plates that had the same external dimensions as a commercially available cold plate. It was also used to make a conformal cooling channel in a copper block with a curved surface. The heat transfer performance of the fabricated plates was tested by placing heaters on them and measuring the temperatures of both the heater block and the cold plate while the water flow rate through the cooling channels was varied. It was shown that heat transfer to the fabricated cold plates was significantly higher than that to a commercial heat sink made by inserting copper tubes into an aluminum plate.

### Fabrication of Conformal Channels

The thermal performance of the cold plates that were fabricated was compared in experiments with that of a commercially available cold plate (Wakefield-Vette, 345-1423-ND, DIGI-KEY ELECTRONICS, Thief River Falls, Minnesota, USA). This consists of an aluminum plate 57.2 mm square and 16.8 mm thick, in which a copper tube with 9.5 mm OD and 1.25 mm wall thickness is bent in a U-shape and press fitted into a channel where it is held in place by a thermally conductive epoxy. The surface of the tube is ground flat to make it flush with the surface of the aluminum plate.

FIGS. 5a-5d and 6a-6d show the successive stages in fabricating aluminum cold plates containing cooling channels with either two passes (FIGS. 5a-5d) or four-passes (FIG. 6a-6d). The external dimensions of the cold plates were close to those of the commercial plate shown in FIG. 1, 57.2 mm square and 15.2 mm thick. Channels, 9.58 mm wide and 9.87 mm deep, were machined in both plates to give either two or four passes of the cooling fluid. A step, 1.3 mm wide and 2.5 mm deep was machined along the entire length of the channels to provide room for sprayed metal droplets to land and adhere to the substrate.

Sacrificial tubes to be placed in the channels during thermal spraying were 3D-printed by a Prusa I3 MK3S printer (Prusa Research, Prague, Czech Republic) using polyvinyl alcohol (PVA), a water-soluble polymer. The tubes had an outer diameter of 9.65 mm and 1.3 mm wall thickness. They were in substantially the same shape as the channels machined in the aluminum plates into which they were press-fitted. The plates were then grit blasted (alumina, grit size of 325-400, 3337K51, Mc Master Carr, Santa Fe Springs, California, USA) with an air pressure 520 kPa to clean them and make them ready for thermal spray coating.

An electric wire arc spray system (ValuArc, Suzler Metco Inc., Westbury, NY, USA) attached to a programmable robotic arm was used to melt and spray high purity aluminum wires (Catalog #1031591, Oerlikon Metco, Canada) onto the surface of the plates. The spray parameters reported in Table 1 are kept constant during the spray. The substrates were cooled by maintaining a continuous airflow on them during spraying to minimize thermal stresses. The polymer inserts survived having aluminum sprayed directly on them, though they showed signs of expanding so that after spraying they protruded slightly from the ports made for fittings (see FIG. 2, Row 4). The aluminum coating deposited had an average thickness of approximately 2.70 mm. The coating surface was then ground down and polished to make it flat and smooth so that the final roughness was less than 1 μm. The plates were placed in an ultrasonic water bath at a temperature of 50° C. for 4 hours to dissolve the polymer inserts, leaving behind coolant channels in the aluminum cold plates.

To demonstrate the feasibility of using the same thermal spray technique for making conformal cooling channels that follow the curvature of a surface, another cooling plate was made out of copper. The curved surface has been made by milling the surface of a copper block, 76.2 square and 25.4 mm thick, to create a curved face with an arc length of 78.3 mm as shown in FIG. 8a. A channel 14.2 mm wide and 2.5 mm deep was machined along the center axis of the curved surface. A slot 6.6 mm deep and 6.4 mm wide was made along the center of the channel.

A sacrificial polymer insert with a square cross-section, 6.35 mm on each side, and the same curvature as the channel in the copper block, was 3D printed out of PVA. FIG. 8a shows an insert within the channel of the copper block. The face of the copper block outside the central channel were covered with masking tape and the surface to be coated was grit-blasted. High purity copper wires (Catalog #1000446, Oerlikon Metco, Canada, spray parameters in Table 1) were sprayed on to the surface using the twin-wire arc system with the spray parameters shown in Table 1. The insert was then dissolved in an ultrasonic bath leaving an empty channel. The two open ends of the channel were sealed by brazing. Two 6.35 mm diameter holes were drilled and tapped into the flat back of the copper block, located symmetrically 25.4 mm on either side of the central plane, into which threaded fittings (51235K107, Mc Master Carr, Santa Fe Springs, California, USA) were installed. These provided inlet and outlet ports for water flow (FIG. 8b).

### Experimental Testing

The rate of heat transfer to the cold plates was measured by placing them in contact with heat sources that applied a uniform heat flux on their surfaces while water was passed through their internal channels. To test the commercial cold plate and the rectangular cold plates, which all had the same external dimensions, a copper heater block, 57.2 mm×57.2 mm×12.7 mm in size was made into which four 400 W cartridge heaters (35025K191, Mc Master Carr, Santa Fe Springs, California, USA) were inserted. The cold plate was clamped tightly to the surface of the cold plate with a 150 μm thick thermal graphite pad with thermal conductivity of 28 W/m K (EYG-S1818ZLX2 Panasonic, Digi-Key Electronics, Thief River Falls, MN) placed as an interface material between them. The entire assembly was covered with aerogel insulation (9590K1, Mc Master Carr, Santa Fe Springs, California, USA). The voltage supplied to the heaters was regulated by a variable transformer so that the power dissipated varied from 500 to 1000 W.

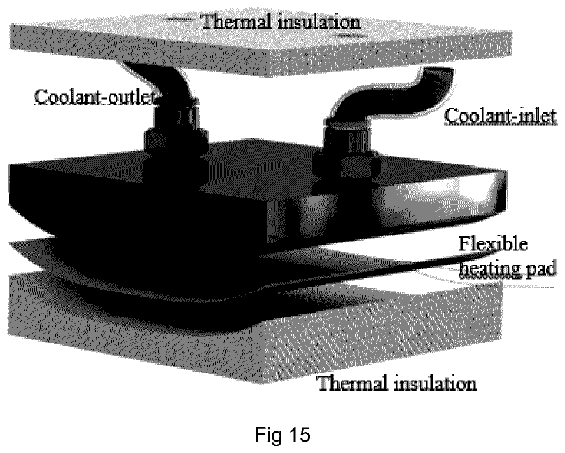

A similar arrangement was used to test the curved copper cold plate, but instead of a heater block a polyimide plastic sheet heater, 76.2 mm×76.2 mm in size (35475K183, Mc Master Carr, Santa Fe Springs, California, USA) was placed on the surface of the cold plate (see FIG. 15). In this case the heater power was varied from 25 W to 100 W.

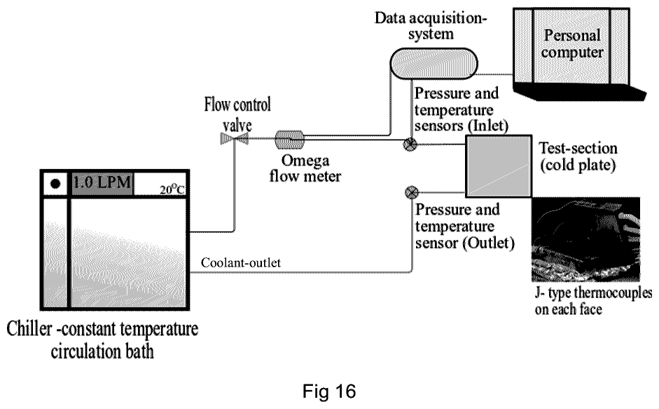

A schematic of the flow loop used for testing is shown in FIG. 16. A refrigerated circulating bath maintained the temperature of the water entering the cold plate at 20° C. The coolant flow rate was regulated by a flow valve and measured by a flow meter (Omega FLR-1000 D) that was interfaced to a data acquisition system (Omega Daq View™ DAQ-56). The coolant flow through the rectangular cold plates was varied between 1 L/min to 3 L/min, and for the curved cold plate flow rates varied from 0.1 L/min to 0.5 L/min.

Ten J-type thermocouples were used to record temperatures, out of which two of were inserted into the flow line at the inlet and outlet to the cold plate while the remaining eight were used to measure temperatures on the four faces of the cold plate and heater block. Two digital pressure transducers (TE Connectivity Measurement Specialties M3021-000005-100PG, DIGI-KEY ELECTRONICS, Thief River Falls, Minnesota, USA) were used to monitor pressures at the inlet and outlet to the rectangular cold plate. Temperatures on the curved cold plate were measured using 6 type J thermocouples. The pressure drop across the curved cold plate was too small to be measured (<3 kPa). The uncertainty in all the temperature measurements was ±1.1° C., which included the zero-order uncertainty associated with the DAQ.

### Numerical Modelling

Simulations of fluid flow and heat transfer in the cold plates were carried out by commercially available software ANSYS FLUENT 20.1. Two domains, solid and fluid, were generated. Heat transfer was by conduction in the solid, whereas the heat transfer in the liquid was assumed to be due to forced convection during incompressible, steady-state flow. Mesh independence studies were carried out. A k-ε model was used to simulate turbulence. The fluid domain boundary conditions were the water inlet temperature (20° C.) and mass flow rate (0.017 kg/s≈1 L/min) and outlet pressure (0.0 kPa). A no-slip condition was applied on the walls of the channel. Constant heat flux values were applied on the surface of the cold plate and all other surfaces were assumed to be adiabatic. The error in the simulated results is less than 5%.

### Results and Discussion

The two square cold plates, with either two-pass or four-pass coolant channels in them, were tested under three thermal loads (500, 750 and 1000 W) and five water flow rates (from 1.0 to 3.0 L/min, in 0.5 L/min increments). The commercial cold plate was also tested under the same conditions for comparison. The temperature of the water was recorded at the inlet and outlet ports. The temperatures of the heater block and the cold plate were recorded at each of their four corners for an hour after steady state was reached, which typically took 15 min, and then averaged. The energy transferred to the water was calculated in each case from the temperature rise as it passed through the cold plate and was found to be greater than 90% of the heater power. The difference represented heat lost to the surroundings through the insulation around the cold plates and heater block.

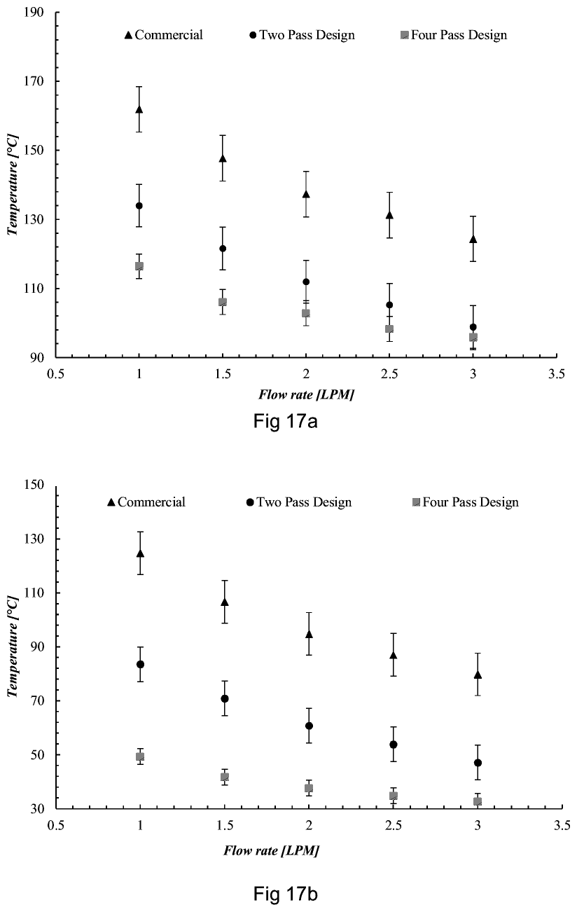

FIGS. 17a and 17b show the variation in the temperature of both the heater block (FIG. 17a) and the cold plate (FIG. 17b) with coolant flow rate when a thermal load of 1000 W was applied. At the lowest flow rate (1 L/min) the heater block temperature was 162° C. for the commercial cold plate, but reduced to 134° C. when the two-pass plate was used and 116° C. when the four-pass plate was used. The cold plate temperature (FIG. 17b) was always significantly lower than that of the heater block (FIG. 17a): at a flow rate of 1 L/min the difference was 38° C. for the commercial cold plate, 50° C. for the two-pass plate and 66° C. for the four-pass plate. This difference was due to the temperature drop (ΔT_{TIM}) across the resistance (R_{TIM}) of the thermal interface material (TIM) between the heater block and cold plate, defined as

$${R}_{TIM} = \frac{Δ {T}_{TIM}}{{Q}_{E}} \qquad ( 1 )$$

where Q_{E} is the electrical power supplied to the heater block. R_{TIM} varied in experiments from 0.04 to 0.07° C./W. As the water flow rate increased the temperature of both heater block and cold plate decreased. However, the difference in heater block temperature for the two-pass and four-pass cold plates decreased as flow rate increased. As the water flow rate increases the resistances of the cold plates decrease, but the total thermal resistance between the cooling water and the heater block is dominated by R_{TIM}. Improving heat transfer in the cold plate offers no further benefits.

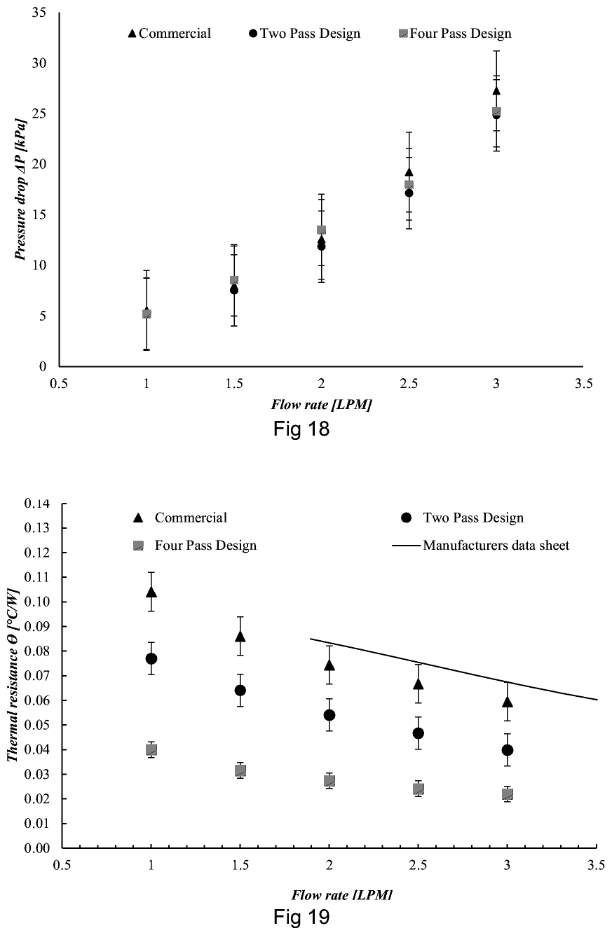

The pressure drop between the inlet and outlet ports of all the three cold plates is shown in FIG. 18 as a function of the water flow rate. seen as less significant in all the flow and thermal load conditions. The magnitude was approximately the same for all three plates tested and increased with flow rate. At low flow rates the pressure drop was so small as to be within the margin of error of the sensors (<2 kPa). The pressure drop became larger with increasing with flow rate.

Reduced temperatures at all the thermal and flow conditions are observed in the fabricated cold plates. These reduced temperatures are due to the lower thermal resistance of the fabricated cold plates with conformal coolant channels. The effective thermal resistance for the cold plates is evaluated by

$${R}_{e f f =} = \frac{( {T}_{B} - {T}_{i n} )}{{Q}_{w}} \qquad ( 2 )$$

where T_{B} is the average temperature of the heater block, Tᵢₙ the water temperature at the cold plate inlet, and Q_{w} the rate of energy transport by the cooing water. FIG. 19 shows the variation in effective resistance as a function of water flow rate for all three cold plates. The commercial cold plate had the highest values of resistance varying from 0.1 to 0.06° C./W. These values were close to those given in the manufacturer's data sheet, shown in the graph by a solid line. The two-pass channel plate had resistance varying from 0.08 to 0.04° C./W, while those for the four-pass channel varied from 0.04 to 0.02° C./W.

The improved heat transfer in the cold plates fabricated by thermal spray may have several reasons. Thermal resistances between the copper tube and aluminum plate, present in the commercial plate have been eliminated. The total surface area (Aₛ) in contact with liquid has been enhanced: for the commercial cold plate Aₛ≅536 mm², for the two-pass design Aₛ≅1106 mm² and for the four-pass design Aₛ≅2230 mm². Finally, greater turbulence in the flow as it passes through increasingly convoluted may also promote mixing and greater heat transfer. Simulation results were used to quantify these effects.

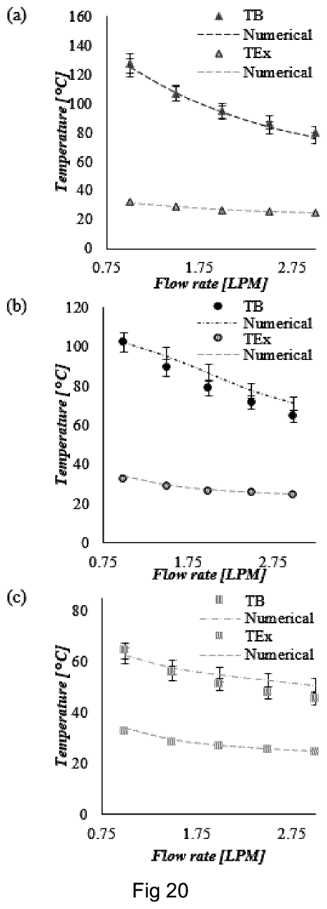

To validate the simulations experimental measurements of cold plate temperatures (T_{cp}) and the exit temperature (To) of water leaving them were compared with predictions from simulations. FIG. 20 shows results for all three plates and good agreement is observed. Increasing water temperature shows greater heat transfer and better cooling. The four-pass channel plate (FIG. 20c) showed a lower plate temperature and higher water temperature than the other two (FIGS. 20a and 20b).

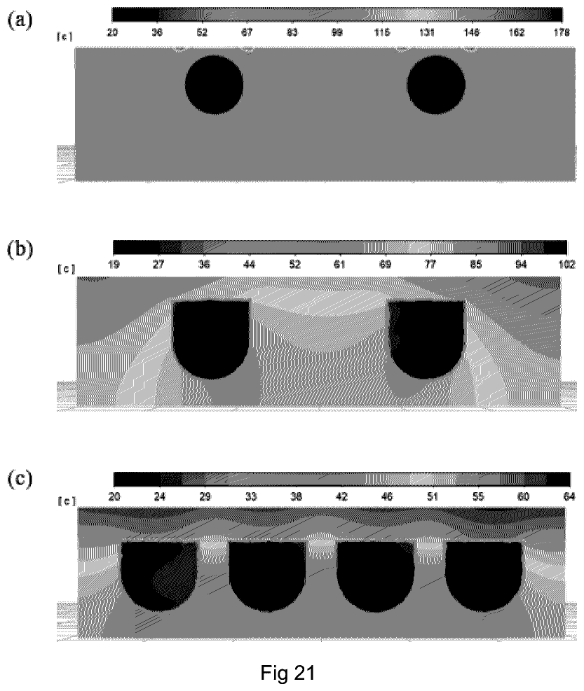

FIG. 21 shows the calculated temperature distributions along the central plane of the cold plates, cutting through all the water channels. In all cases 1000 W of heat was applied to the upper surface and the water flow rate was 3 LPM. The commercial cold plate (FIG. 21a) shows a fairly uniform temperature across the cross-section of the plate, with four hot-spots on the upper surface which correspond to the location of the epoxy that bonds the tubes to the plate. This has relatively low thermal conductivity and therefore high thermal resistance, creating high temperature regions. The two-pass (FIG. 21b) and four-pass (FIG. 21c) plates display uniform heat transfer across a larger area of the upper surface because of the greater surface area of the water channels and the absence of any localized thermal resistances.

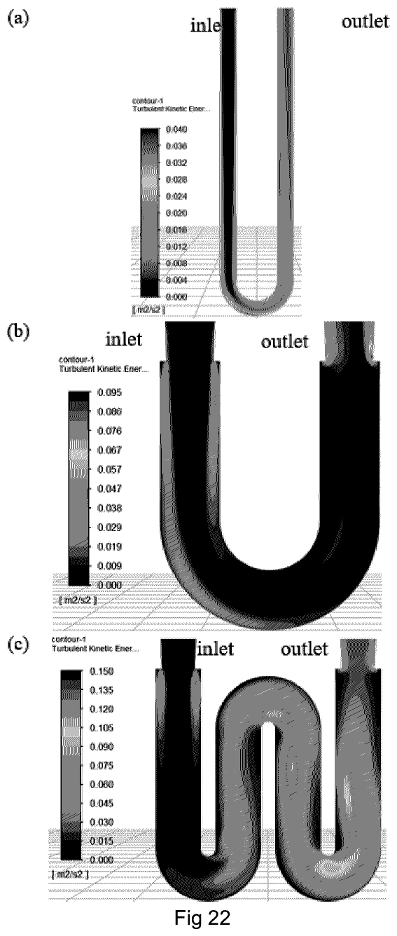

FIG. 22 shows the variation in turbulent kinetic energy intensity for the commercial (FIG. 22), two-pass (FIG. 22b) and four-pass (FIG. 22c) cold plates with 1000 W of heat applied to their upper surfaces and a water flow rate of 3 LPM. The turbulence intensity increases as the flow progresses from the inlet to the outlet of the channel through the cold plate. The longer the distance traversed, and the greater the curvature in the channels, the larger the increase in turbulent intensity. The highest turbulent kinetic energy seen in the commercial cold plate was 0.04 m²/s² (FIG. 22a), whereas it was 0.095 m2/s2 for the two-pass channel (FIG. 22b). and 0.15 m²/s² for the four-pass channel (FIG. 22c). Higher turbulence promotes more mixing in the liquid and higher heat transfer, though at the cost of a larger pressure drop. However, the pressure drop was very low in all these channels, so increased turbulence did not result in a significant penalty.

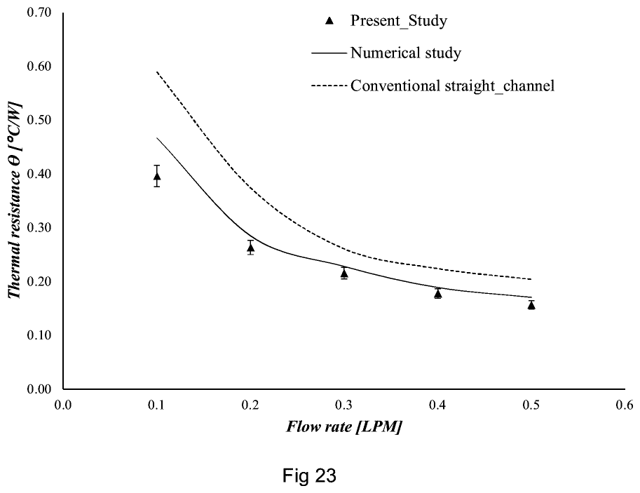

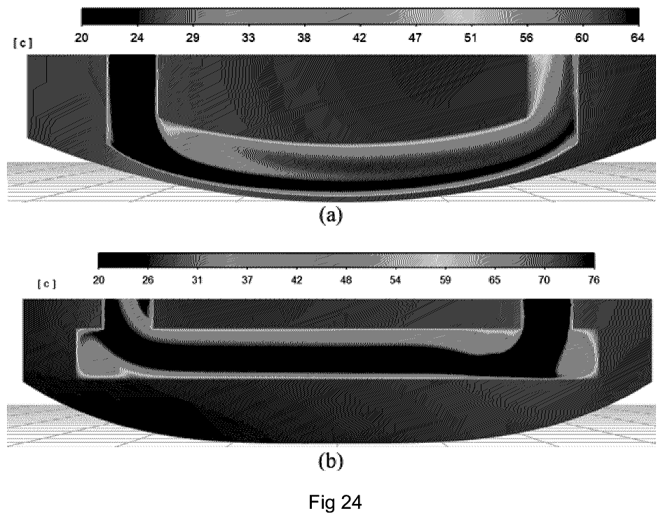

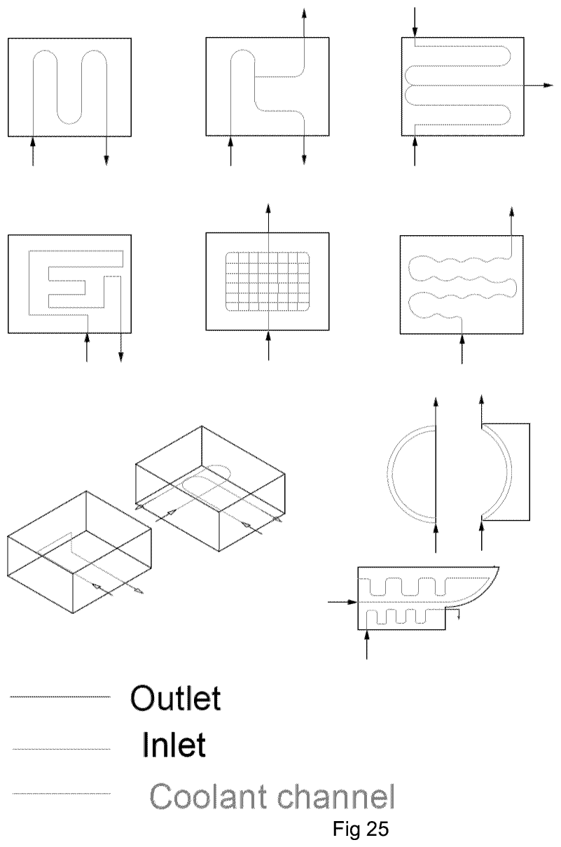

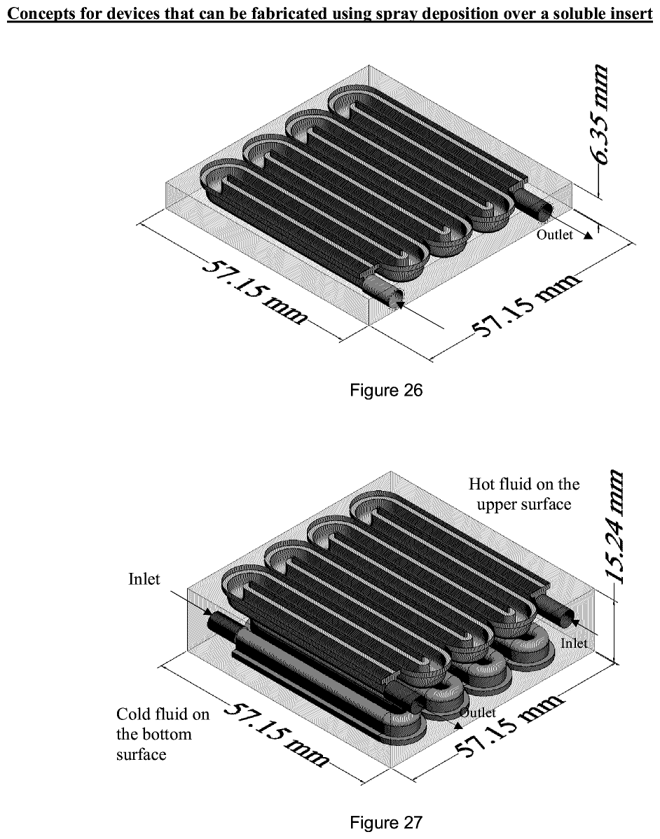

Tests were done on the copper block with a conformal cooling channel shown in FIG. 8. Measured values of the thermal resistance are shown in FIG. 23 as a function of flow rate. Tests were done at much lower flow rates than those for the aluminum cold plates, so resistance values were higher, ranging from 0.4 to 0.15° C./W for flow rates of 0.1 to 0.5 L/min. Simulations were done of the flow through the conformal cooling channel (see FIG. 24a) and the predicted thermal resistance calculated. Computed values of thermal resistance, shown by the solid line in FIG. 23, agreed well with measurements. Additional simulations were done for heat transfer to a channel that did not follow the curved surface but was straight instead, as would be made by drilling through the copper block directly (FIG. 24b). With a conformal cooling channel the maximum cold plate temperature was 64° C. (FIG. 24a) with a water flow rate of 0.5 L/min and 100 W thermal load applied, whereas it 76° C. under the same conditions for a plate with a straight channel (FIG. 24b). The calculated thermal resistance of the block with the straight channel is shown by the dashed line in FIG. 23 and is higher than that given by a conformal cooling channel.

In conclusion, a new method is presented for making channels just below the surfaces of cold plates. A channel is milled in the plate, a 3D printed insert made of a water-soluble polymer is placed inside it, and then molten metal deposited on it using a thermal spray process. The polymer inserts were dissolved in water, leaving the channels open for coolant flow. Using this method cold plates can be made of any metal that can be deposited using thermal spray, and with either flat or curved surfaces. Complex channel geometries can be built in cold plates, so that the flow path can be placed directly under regions exposed to the maximum heat flux. Conformal cooling channels can also be built.

Cold plates built using a thermal spray method were shown to have significantly lower thermal resistances than commercial cold plates made by bonding a copper tube to an aluminum plates. Avoiding the use of epoxy in the thermal conduction path contributed to reducing resistance. It was possible to machine multiple passes of the cooling channel in the same plate area, increasing the surface area wetted by the liquid. A longer flow path, and multiple bends in the channel, promoted turbulence in the flow and enhanced heat transfer.

TABLE 1
Typical ranges of spray parameters for metal
deposition using a wire-arc system.

| Variable | Input |
|---|---|
| Gas flow | 500-300 sL/m |
| Jet velocities | 50-100 m/s |
| Gas types | Air, N₂, Ar |
| Power | 2-5 kW |
| Particle velocities | 50-100 m/s |
| Material feed rate | 150-2000 g/min |

TABLE 2
Operating conditions for the cold plates

| Variable | Condition |
|---|---|
| Cold plate | Two-pass design, four-pass design and |
| | commercial cold plate |
| Coolant surface area | 0.00054 m², 0.00111 m² and 0.00223 m² |
| Hydraulic Diameter | 0.00765 m, 0.01156 m and 0.01163 |
| Flow rate | 0.5, 1.0, 1.5, 2.0, 2.5 and 3.0 L/min |
| Thermal load | 500, 750, and 1000 W |
| Cold plate | Curved surface cold plate |
| Hydraulic diameter | 0.00635 m |
| Flow rate | 0.1, 0.2, 0.3, 0.4 and 0.5 L/min |
| Thermal load | 25, 50, 75 and 100 W |

By way of example, the following information relates to potential operating conditions and properties for certain aspects of this technology:

TABLE 3
Thermal spray parameters for metal deposition in currentwork

| Variable | Input |
|---|---|
| Torch | ValuArc |
| Wire feed rate | 7 m/min |
| Voltage Applied | 30 V(Aluminum) 32 V (Copper) |
| Air inlet pressure, | 690 kPa |
| Spraying distance | 150-200 mm |
| Number of spray passes | 35 (Aluminum), 23(Copper) |
| Temperature of the | 80-100° C. |
| substrateduring spraying | |

TABLE 4
Optional desired properties of polymer for substrate

| Variable | Unit |
|---|---|
| Glass transition temperature | 80° C. |
| (based on PVAand PLA) | |
| Printing Temperature | 180 to 230° C. |
| Melting temperature | greater than 230° C. |
| Solubility | in water or organic solvent |
| Availability | Resin/powder/3D printable filament |

It is also noted that thermal spray properties can be based on known techniques, for example as shown in Table 1: Thermal spray process comparisons in J. R. Davis, “Handbook of Thermal Spray Technology,” ASM International, 2004, which is incorporated herein by reference. Other features of the methods described herein can be adapted based on the particular spray process used for the coating.

The following nomenclature was used in certain sections of the present application and is presented below for ease of reference. However, certain terms, such as ΔT, have been used in more than one way in the present description and thus it should be understood that terms and expressions herein should be viewed in the context in which they are used.
A_{c}—cross-sectional area (m²)
Aₛ—surface area (m²)
Cₚ—isobaric heat capacity

$$( \frac{J}{kg K} )$$

Dₕ—hydraulic diameter (m)
h—heat transfer coefficient

$$( \frac{W}{{m}^{2} K} )$$

Kₘ—thermal conductivity of metal

$$( \frac{W}{m K} )$$

K_{w}—thermal conductivity of water

$$( \frac{W}{m K} )$$

\dot{m}—mass flow rate

$$( \frac{k g}{s} )$$

Pᵢₙ—Pressure reading at the inlet of the cold plate (Psi)
Pₒᵤₜ—Pressure reading at the outlet of the cold plate (Psi)
Q_{E}=Electrical energy supplied (externally) (W)
qₛ″—heat flux

$$( \frac{W}{{m}^{2}} )$$

Q_{w}=\dot{m} cₚ ΔT (heat flow estimation) (W)
T_{B}—the average temperature of the heater block (° C.)
T_{cp}—the average temperature of the cold plate (° C.)
Tₒ—exit temperature of the coolant (° C.)
Tᵢₙ—inlet temperature of the coolant (° C.)
V—velocity of the moving fluid

$$( \frac{m}{s} )$$

ΔP—Pressure difference between inlet and outlet (Psi)
ΔT—Temperature difference between inlet and outlet (° C.)

$$θ = Thermal resistance = \{ \frac{( {T}_{B} - {T}_{i n} )}{{Q}_{E}} \} ( \frac{° C .}{W} )$$

ρ—density of the fluid

$$( \frac{k g}{{m}^{3}} )$$

μ—dynamic viscosity

$$( \frac{Ns}{{m}^{2}} )$$

$$Pr = \frac{ϑ}{α} = \frac{momentum diffusivity}{thermal diffusivity} = ( \frac{{C}_{p} μ}{{K}_{w}} ) > 5$$

in the present study

$$R e = Reynold ' s number = \frac{4 \dot{m}}{π D μ} ,$$

Nu=Nusselt number (hD/K)

### Additional Information and Discussion

Thermal spray technology is a technique for applying metal coatings on metal substrates. Thermal sprayed coatings are formed by the impact of molten metal particles on a substrate where they freeze during impact to form “splats”. The surface of the substrate should have certain penetrability properties, such as roughness (e.g., average roughness of about 2 to 10 μm; or a roughness above 1, 2, 3, 4 or 5 μm and up to 10, 9 or 8 μm) so that molten metal can penetrate crevices and solidify, forming mechanical bonds. The present description includes information regarding thermal spraying of metals onto polymers that are not soluble in water and such information can be used to apply and adapt thermal spraying onto water-soluble polymers.

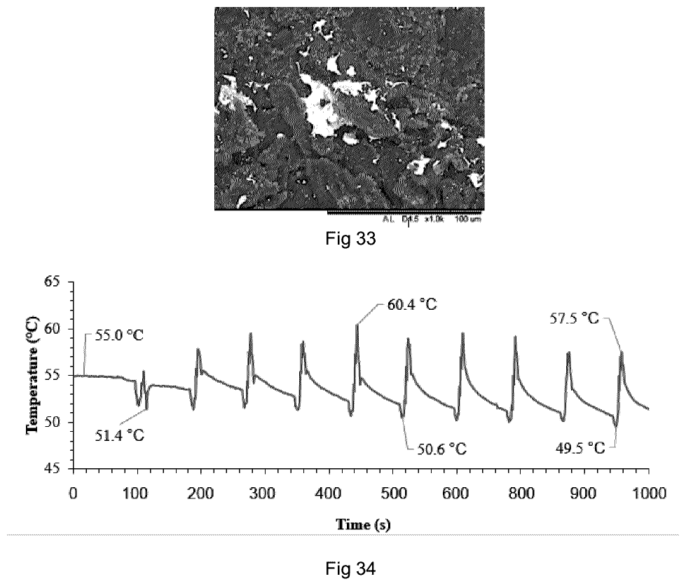

FIG. 33 shows a single zinc splat that has landed on a rough polyethylene (PE) surface where it has entered surface cracks. Subsequent droplets coalesce with these and form a dense coating.

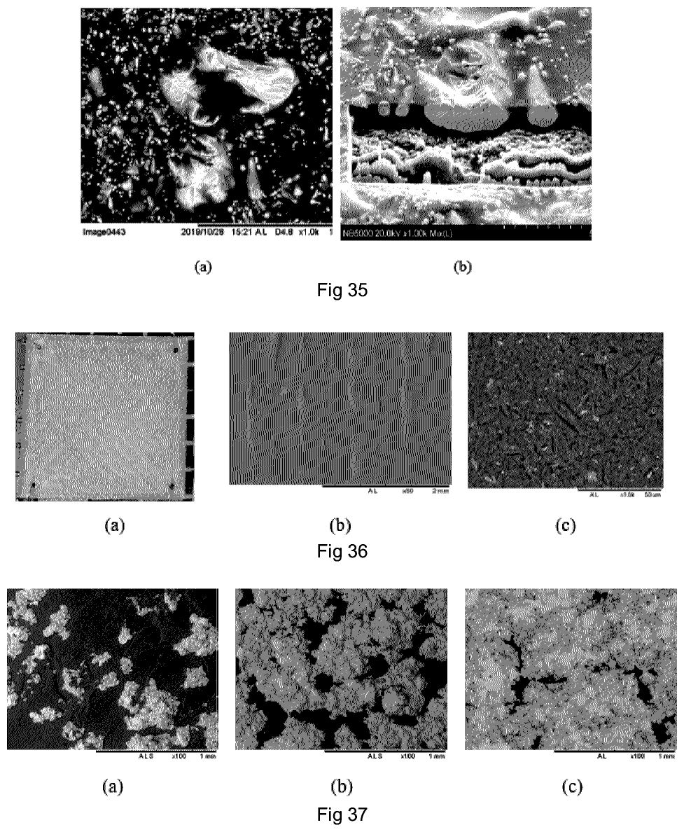

Adhesion of the metal to the polymer substrate can also be improved by heating the surface to close to its glass transition temperature (T_{g}), above which thermoplastics begin to soften. For polyethylene the glass transition temperature is ˜75° C. and the melting temperature (Tₘ) is ˜130° C. FIG. 34 shows the measured temperature of a polyethylene substrate that was preheated to 55° C. before spraying zinc on it. The temperature variation is shown during 10 passes of the of the spray torch. The temperature increased to ˜60° C. when the torch was directly over the substrate and then cooled as it moved away. An impacting zinc particle which has a melting temperature of 420° C. would then increase the temperature further, softening the substrate and promoting penetration. FIG. 35 shows zinc particles after impact on a preheated PE surface. The particles appear partially buried (FIG. 35a) and a cross-section through the surface (FIG. 35b) shows that they have penetrated deep into the polymer, providing good adhesion.

The temperature of the substrate and the surface can be controlled during spraying to promote coatings with desired properties. If the temperature exceeds the melting temperature of the polymer, there is localized melting under the impacting droplet and surface asperities are destroyed. The molten metal then does not have a crevice in which can anchor itself during solidification, particularly for polymers with low to no porosity. In findings described in Devaraj et Ia. “Thermal spray deposition of aluminum and zinc coatings on thermoplastics”, Surface & Coatings Technology 399 (2020), which is incorporated herein by reference, zinc was applied on polyethylene (PE) and PTFE, but aluminum could not be applied as a coating on the tested PE surfaces at least in part because it has a higher melting temperature (Tₘ=660° C.) than zinc (Tₘ=420° C.). Impacting Al particles melted the substrate and did not leave large enough cavities for molten metal to flow into. However, Al can be applied on Teflon (PTFE), which has a higher glass transition temperature, about 130° C.

Coatings were also applied on polymers that can be dispensed by a 3D printer. FIG. 36a shows a coupon of Polyvinyl Alcohol (PVA), 50 mm×50 mm in size, made by a 3D printer. The average roughness was approximately 1.5 μm. The glass transition temperature of PVA is 85° C. and the melting point is 200° C. FIG. 36b shown a Scanning Electron Microscope (SEM) image of the coupon. The polymer is laid down in layers so lines are visible showing the direction of deposition. The coupon was grit-blasted using aluminum oxide particles propelled onto the surface using a compressed air nozzle. The roughness of the grit-blasted surface in FIG. 36c is 1.5 μm.

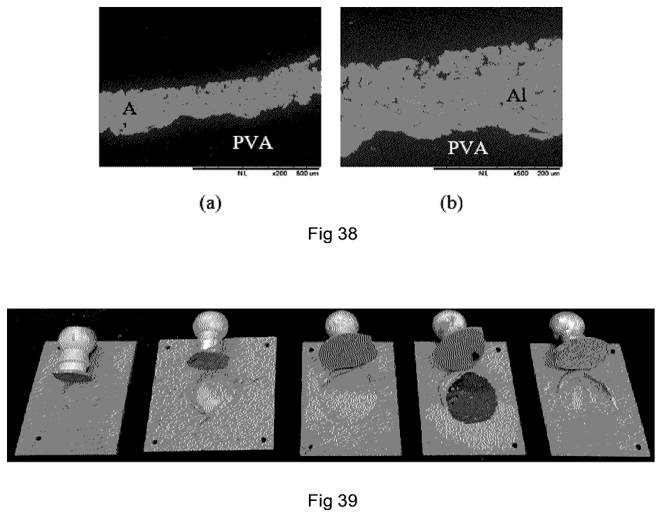

FIG. 37 shows SEM images of the coupon surface after successive passes of the wire-arc spray. The first pass (FIG. 37a) deposited individual splats that adhered well. These provided surfaces on which the more splats adhered after the second (FIG. 37b) and third pass (FIG. 37c) of the torch. After 4-5 passes of the torch a coating 150 to 200 μm thick formed on the surface. FIG. 38 shows a cross-section through an aluminium coating on a PVA substrate. There is some porosity in the coating due to voids between splats.

Coating adhesion strength (σ_{A}) was measured using a pull test as per ASTM standard D4541. A standard aluminum pull stub, 20 mm in diameter was bonded to the centre of the coated samples using an epoxy adhesive. Once the epoxy hardened, the coating was pulled off using a tensile testing machine and the stress required to pull of the coating recorded. Additional tests were done on coupons made of a composite material consisting of a polymer, Polylactic Acid (PLA), mixed with fillers such as aluminum powder, copper powder, or carbon fibre. These additives increase the roughness of the coupon and make it more resistant to heating. They also make the thermal expansion coefficient of the composite material closer to that of the metal that is added. FIG. 39 shows the coupons and pull stubs after the pull test was completed. Tests were also done on a copper coating applied on a copper substrate to serve as a reference.

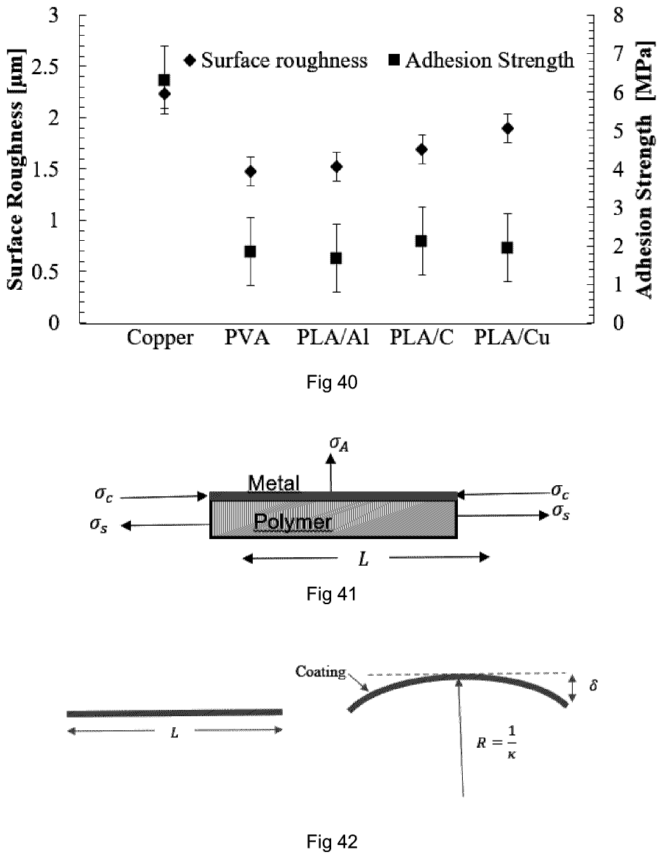

FIG. 40 shows values of the measured surface roughness of coupons and the corresponding adhesion strength of copper coatings. A total of 5 measurements were taken for each sample and error bars used to show the standard deviation in measurements. The copper coupon had the highest roughness (2.2 μm) and the highest adhesion strength (6.3 MPa). The PVA coupon had a roughness of 1.5 μm and this increased to 1.9 μm for the PLA/copper composite. The adhesion strength of all the coatings was approximately the same, about 2 MPa.

TABLE 1A
Thermal properties of metals and 3D-printable polymers

| | | Glass | Coefficient |
|---|---|---|---|
| | Melting | transition | of thermal |
| | temperature | temperature | expansion |
| Material | Tₘ [° C.] | T_{g} [° C.] | [° C.⁻¹] |
| Aluminum | 660 | | 23 × 10⁻⁶ |
| Copper | 1085 | | 17 × 10⁻⁶ |
| Poly (vinyl alcohol) | 200 | 85 | 70 × 10⁻⁶ |
| (PVA) | | | |
| Polylactic acid (PLA) | 150-160 | 60 | 68 × 10⁻⁶ |
| ASA (acrylonitrile | 235-255 | 110 | 60-110 × 10⁻⁶ |
| styrene acrylate) | | | |
| Poly(carbonate) (PC) | 270-310 | 147 | 65-70 × 10⁻⁶ |
| ABS (acrylonitrile | 220-235 | 80-110 | 81-95 × 10⁻⁶ |
| butadiene styrene) | | | |

TABLE 2A
Thermal properties of metals

| | | Coefficient |
|---|---|---|
| | Melting | of thermal |
| | temperature | expansion |
| Metal | Tₘ [° C.] | [° C.⁻¹] |
| Aluminum | 660 | 23 × 10⁻⁶ |
| Bismuth | 271 | 13-13.5 × 10⁻⁶ |
| Brass | 930 | 18-19 × 10⁻⁶ |
| Bronze | 950 | 17.5-18 × 10⁻⁶ |
| Copper | 1085 | 16-16.7 × 10⁻⁶ |
| Iron, cast | 1204 | 10.4-11 × 10⁻⁶ |
| Steel | 1370 | 10.8-12.5 × 10⁻⁶ |
| Steel Stainless (316) | 1400 | 16 × 10⁻⁶ |
| Magnesium | 650 | 25-26.9 × 10⁻⁶ |
| Zinc | 420 | 30-35 × 10⁻⁶ |

TABLE 3A
Thermal properties of polymers

| | | Glass | |
|---|---|---|---|
| | Melting | transition | Coefficient |
| | temper- | temper- | of thermal |
| | ature | ature | expansion |
| Polymer | Tₘ [° C.] | T_{g} [° C.] | [° C.⁻¹] |
| ABS - Acrylonitrile | 220-235 | 80-110 | 81-95 × 10⁻⁶ |
| butadiene styrene | | | |
| ASA - Acrylonitrile | 235-255 | 110 | 60-110 × 10⁻⁶ |
| styrene acrylate | | | |
| HIPS - High Impact | 242 | 88-92 | 70 × 10⁻⁶ |
| Polystyrene | | | |
| HDPE High density | 210 | −120 | 120 × 10⁻⁶ |
| polyethylene | | | |
| LDPE - Low Density | 180 | −110 | 108-200 × 10⁻⁶ |
| Polyethylene | | | |
| PEEK - | 357 | 145 | 45-55 × 10⁻⁶ |
| Polyetheretherketone | | | |
| PET - Polyethylene | 264 | 73-78 | 59 × 10⁻⁶ |
| Terephthalate | | | |
| PMMA - | 200 | 90-110 | 50-100 × 10⁻⁶ |
| Polymethylmethacrylate | | | |
| PVA -Poly vinyl | 200 | 85 | 70 × 10⁻⁶ |
| alcohol | | | |
| PC - Polycarbonate | 270-310 | 160-200 | 65-70 × 10⁻⁶ |
| PLA- Polylactic acid | 150-160 | 60 | 68 × 10⁻⁶ |
| PP - Polypropylene | 179 | −10 | 36 × 10⁻⁶ |
| PVC Polyvinyl | 276 | 60-100 | 54-110 × 10⁻⁶ |
| Chloride | | | |
| Teflon - | 327 | 130 | 112-135 × 10⁻⁶ |
| Polytetrafluorethylene | | | |
| (PTFE) | | | |

Thermal stresses can lead to delamination of a metal coating after it has been applied and the component has cooled down. Metals have coefficients of thermal expansion (a) in the range of 10-30×10⁻⁶° C.⁻¹, lower than those of most polymers which are typically in the range of 50-100×10⁻⁶° C.⁻¹ (see Tables 1A-3A). After spraying, as the component cools, both the substrate and the coating bonded to it contract (see FIG. 41), with the substrate contracting by a larger amount. The change in length of the substrate is ΔLₛ=αₛLΔT where ΔT is the temperature decrease as the component cools from the peak temperature it reached during spraying back to room temperature, L is the initial length of the coated component and αₛ the coefficients of thermal expansion of the substrate. If the coating was free-standing it would contract by ΔL_{c}=α_{c}LΔT where α_{c} is the coefficient of thermal expansion of the coating. However, when the substrate is much thicker than the coating, the coating is forced to contract by the same amount as the substrate, ΔLₛ. The strain (E) produced in the coating due to this mismatch is:

$$ε = \frac{( Δ {L}_{c} - Δ {L}_{s} )}{L} = ( {α}_{c} - {α}_{s} ) Δ T$$

As an illustration, for the case of a copper coating on a PVA substrate, that is assumed to cool by ΔT=35° C.,

$$ε = ( {α}_{c} - {α}_{s} ) Δ {T}_{1} = ( 16.7 - 70 ) \times 1 {0}^{- 6} ° C {.}^{- 1} \times 35 ° C . = - 1.866 \times {10}^{- 6}$$

stress is generated in the coating equal to:

$${σ}_{c} = \frac{{E}_{c}}{( 1 - {ν}_{c} )} ε = \frac{{E}_{c}}{( 1 - {ν}_{c} )} ( {α}_{c} - {α}_{s} ) Δ T$$

where E_{c} is the Young's modulus of the coating material and v_{c} its Poisson's ratio.

For copper E_{c}=117 GPa and v_{c}=0.34, so the stress in the coating in the example above is −330 kPa. The negative sign implies that it is a compressive stress. The length mismatch between the coating and substrate forces the polymer substrate to curve and its curvature is:

$$κ = 6 \frac{( 1 - {ν}_{s} )}{{E}_{s}} \frac{{t}_{c}}{{t}_{s}^{2}} {σ}_{c}$$

where Eₛ and vₛ are the Young's modulus and Poisson's ratio of the substrate and tₛ and t_{c} are the thicknesses of the substrate and coating respectively. For PVA Eₛ=2 GPa and vₛ=0.5, and we assume that t_{c}=100 μm and tₛ=3.25 mm. Substituting these values gives κ=−4.69 m⁻¹. Since in general as for polymers is greater than α_{c} for metals (see Tables 1A and 2A), σ_{c} is negative and therefore the curvature κ is negative, meaning that the surface curves with the coating on the convex side (see FIG. 42).

As the substrate curves, its ends arc away from the plane of the center as shown in FIG. 42 and the radius of the arc R=1/κ. In the example above, if the length L of the substrate is 50 mm the radius R=0.213 m and the ends will deflect by approximately δ=1.5 mm. This pulls the coating away from the substrate and if the normal stress generated is greater than the adhesion strength of the coating (σ_{A}), the coating will detach from the substrate. The greater the length L of the substrate, the greater the deflection and the stresses. Delamination in metal coated polymer samples can start around the edges where stresses are maximum.

Conditions and considerations for coating adhesion will now be discussed. A metal coating will adhere to a polymer substrate if: (A) The substrate has enough roughness for impinging droplets to penetrate crevices, solidify, and form mechanical bonds. A minimum average roughness of 1-2 μm can be necessary for this to happen and can be as large as 8-10 μm. It is also possible for a substrate to be smooth but have a porosity below the outer smooth surface enabling penetration. (B) The substrate temperature during spraying should preferably exceed the glass transition temperature (T_{g}) at which the polymer begins to soften so that molten metal droplets penetrate the surface and partially bury themselves inside it. However, the substrate temperature should not exceed the melting temperature (Tₘ) of the polymer, otherwise surface asperities will melt and there will not be enough roughness for splats to form bonds.

The stress in the coating due to mismatch of thermal expansion coefficients of the metal and substrate is given by

$${σ}_{c} = \frac{{E}_{c}}{( 1 - {ν}_{c} )} ε = \frac{{E}_{c}}{( 1 - {ν}_{c} )} ( {α}_{c} - {α}_{s} ) Δ T$$

This produces a curvature in the substrate that acts to pull the coating off it. If the normal stress exceeds σ_{A}, the adhesion strength of the coating, the coating will delaminate. The curvature of the substrate increases with coating thickness (t_{c}); limiting coating thickness keeps stresses lower. The deflection (δ) of the ends of the substrate due to substrate curvature should be minimized; the ratio δ/L can be maintained below 1%. Stress in the coating (σ_{c}) can be minimized or reduced by reducing the temperature rise of the substrate during spraying so that the temperature decrease (ΔT) as it cools back to room temperature is minimized or reduced. This can be done by cooling the part during spraying by directing air jets on it; making the polymer component hollow so that air circulates in it also promotes cooling. In addition, making the cross-sectional area of the substrate thin also reduces its stiffness so that some stress is transferred from the coating to the polymer, reducing the likelihood of delamination. In addition, the thermal expansion coefficient of the substrate can be made closer to that of the metal sprayed on by mixing metal powder with the polymer so that the substrate is a polymer-metal composite.

Referring to Tables 2A-3A, some of the listed polymer-metal combinations have been tested. All of the polymers could benefit from some pre-treatment to produce a roughness of at least 1 μm since the sheets available commercially have lower roughness. Zinc adhered to all of the polymers tested (PE, PTFE, ABS, PVA) at least in part since it has a low melting temperature (420° C.) and does not damage the polymer. Aluminum, which has a higher melting temperature (660° C.) adhered to PTFE in certain test work, but not to polyethylene (PE) or ABS which have lower melting temperatures. Aluminum splats may have melted the substrate on impact and interlocking did not occur.

Nevertheless, aluminum can adhere to porous PE, even if it did not adhere to solid PE. For porous polymer, the metal penetrates pores in the substrate and adheres, even if it melts the surface. Thus, porous polymers can have a smooth outer layer or surface and yet sufficient porosity can still enable penetration and adherence to form the metal coating. The polymer substrate can thus be rough and non-porous, rough and porous, or smooth and porous. The porosity of a polymer would typically be consistent throughout the bulk of the polymer substrate, but it is noted that the key region where porosity would be required is in the surface region of the substrate that comes into contact with the metal. The polymer-metal combinations that showed good performance did so within operating parameters: the surface temperature was controlled, the dimensions of the polymer substrate were maintained so that the stresses produced were not too large, and the substrate was configured to be cooled during spraying.

Furthermore, the range of difference in coefficient of thermal expansion (104° C.⁻¹) discussed above is based on assuming that the polymer substrate is approximately 50-100 mm in length and the coating is approximately 100 μm thick. However, if the polymer substrate is very small (e.g., −1 mm) then the stresses induced by thermal expansion will be smaller and potentially too small to matter. Most of the polymers listed in the above tables are within this range with respect to the coefficient of thermal expansion.

As noted above, some of the polymer-metal combinations do not work under certain conditions (e.g., tested conditions of Aluminum and non-porous PE or Aluminum and non-porous ABS) for certain reasons, which can include the melting of the substrate upon contact with the metal droplets. Thus, for high melting temperature metals, such as Al, one approach can be to select a higher melting temperature polymer to avoid melting, as the higher Tₘ of PTFE allowed it to survive the impact of aluminum droplets without melting. Another approach could be to provide a polymer with certain properties, such as higher porosity, that help enable adherence for such metal-polymer combinations.

In addition, adhesion strength would not have an impact on the ability of dissolving the polymer after it is embedded with the metal coating. The water-soluble polymer can dissolve in water irrespective of the adhesion strength with the metal coating.

As can be appreciated from the above description, metal coating of a polymer substrate involves various considerations. Based on recent work, Tables 1B and 2B show the results of a test that was conducted to measure deposition efficiency on polymer surfaces as a function of different spray parameters. In the study, there was a window of surface roughness and temperature during spraying that allowed metal droplets to adhere. The particular window is different for each polymer and metal, and thus parameters can be adapted for each metal-polymer combination.

In general, the spraying stage should be performed such that the polymer substrate does not deform during the coating process. If the substrate is relatively thick, there are temperature gradients in it during spraying and thermal stresses build up as different areas expand by different amounts. The substrate was made to be hollow so that air could circulate in it and cools it internally during spraying. However, if the wall thickness of the hollow substrate is too small the structure may fail due to molten metal particles impacting on it. The wall thickness can thus be provided to enable the structural and mechanical properties that are desired. In addition, the base plate can also be cooled during coating using air jets or other cooling fluids. Furthermore, the water-soluble substrate can be designed so that it dissolves easily, and making it hollow allows water to circulate internally and dissolve it in a relatively efficient manner. Further, 3-D printing a part out of water-soluble polymer required obtaining an open-source printer and changing the filament to print such a component, since commercially available printers that were assessed were not compatible for printing the substrate out or water-soluble polymer.

Various advantages and features can be provided by embodiments of the technology: complex channel shapes can be made; channel sizes can range from sub-millimeter to centimeters; channels can be made on curved surfaces; the channel cross-section can be varied (e.g., one could make a sinusoidally varying wall profile to increase surface area and promote fluid circulation); structures such as micro-pillars can be made inside channels to increase surface area and promote mixing of fluids; coatings of a different material can be deposited on the insides of channels, to make corrosion or heat resistant channels, or to electrically insulate the channels from the fluid; the polymer substrate may be made from two materials, only one of which is soluble (e.g., the non-soluble structure would then remain inside the channel, and in this way one could build fluid mixers, valves, linings for channels or other components inside the channel); and one can make networks of microchannels, to make micro-fluidic circuits, micro-reactors, or heat exchangers.

Adhesion of sprayed metal on polymers has been studied and various findings are presented below. To study the effect of metal deposition (aluminium and copper) on 3D printed structures (using secondary filament as primary), studies included carrying out an optimization assessment (L9 orthogonal array) on the surface preparation, the voltage of metal spraying, and spray distance. A comparison with the aluminium samples was made. The weight of the samples was compared before and after spray. A microstructural examination, adhesion test and porosity in the coatings were done. Tables 1B to 3B provide information regarding these tests.

TABLE 1B
Experimental parameters varied

| Sample No | Voltage | Surface | Distance |
|---|---|---|---|
| Sample-1(S-1) | 28 | Grit blasted | 125 |
| Sample-2(S-2) | 28 | Resin_Metal | 150 |
| Sample-3(S-3) | 28 | Glue_Metal | 175 |
| Sample-4(S-4) | 30 | Grit blasted | 150 |
| Sample-5(S-5) | 30 | Resin_Metal | 175 |
| Sample-6(S-6) | 30 | Glue_Metal | 125 |
| Sample-7(S-7) | 32 | Grit blasted | 175 |
| Sample-8(S-8) | 32 | Resin_Metal | 125 |
| Sample-9(S-9) | 32 | Glue_Metal | 150 |

TABLE 2B
Deposition efficiency of sprayed coatings

| | | | Deposition |
|---|---|---|---|
| Sample No | Voltage | Distance | Efficiency |
| Sample-1(S-1_1) | 28 | 125 | 100% |
| Sample-2(S-2_1) | 28 | 150 | 50% |
| Sample-3(S-3_1) | 28 | 175 | 50% |
| Sample-4(S-4_1) | 30 | 125 | 50% |
| Sample-5(S-5_1) | 30 | 150 | 100% |
| Sample-6(S-6_1) | 30 | 175 | 33% |
| Sample-7(S-7_1) | 32 | 125 | 33% |
| Sample-8(S-8_1) | 32 | 150 | 100% |
| Sample-9(S-9_1) | 32 | 175 | 100% |

TABLE 3B
Weight of the deposition on bare Al_sample

| | | | Weight of | | The |
|---|---|---|---|---|---|
| | Weight of | | Aluminum | | efficiency |
| | sample in grams | | sample in grams | | of the |
| | | Metal | | Metal | deposit |
| Sample No | Bare | Deposited | Bare | Deposited | PVA |
| Sample-1(S-1) | 1.7 | 1.9 | 2.8 | 3.0 | 100% |
| Sample-2(S-2) | 1.8 | 1.9 | 3.1 | 3.2 | 50% |
| Sample-3(S-3) | 1.8 | 1.9 | 3.1 | 3.2 | 50% |
| Sample-4(S-4) | 1.5 | 1.8 | 2.9 | 3.2 | 100% |
| Sample-5(S-5) | 1.8 | 1.9 | 3.2 | 3.2 | 33% |
| Sample-6(S-6) | 1.6 | 1.7 | 3.1 | 3.2 | 50% |
| Sample-7(S-7) | 1.6 | 1.8 | 2.7 | 2.9 | 100% |
| Sample-8(S-8) | 1.8 | 1.9 | 3.2 | 3.3 | 33% |
| Sample-9(S-9) | 1.8 | 2.0 | 2.8 | 3.0 | 100% |

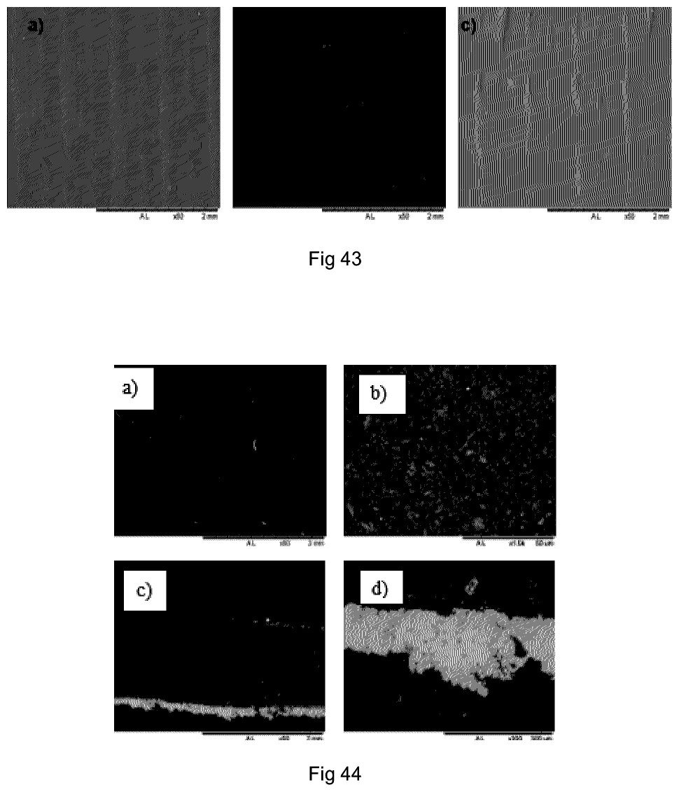

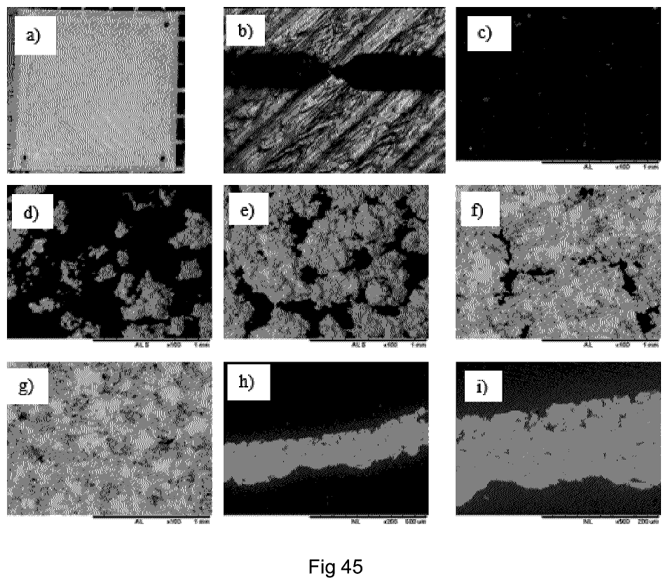

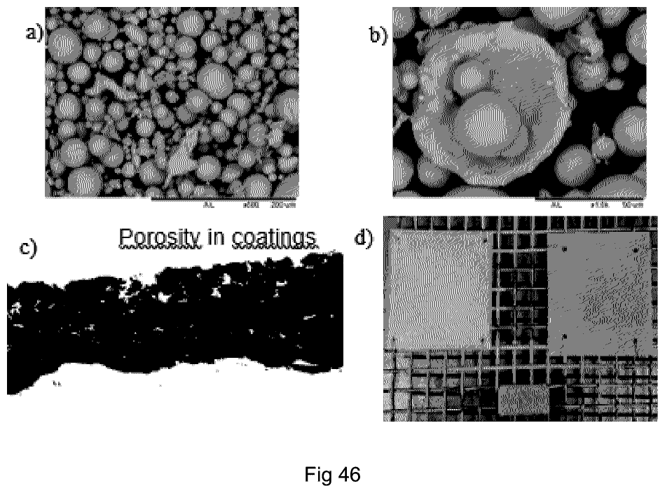

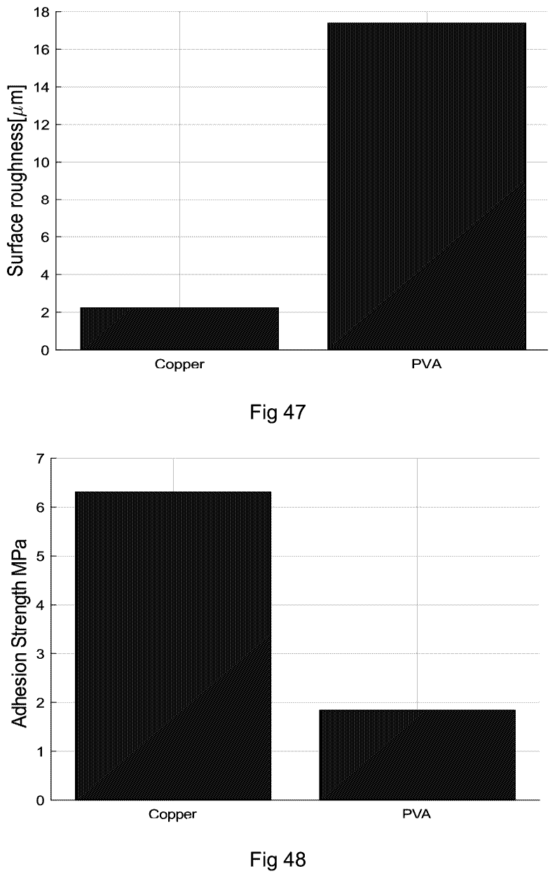

Regarding results, FIG. 43 SEM images of the 3D printed samples with different layer heights in 3D printing. a) 0.05 mm layer height, b) 0.1 mm layer height, c) 0.25 mm layer height. FIG. 44 shows SEM images of PVA sample with aluminum as metal deposit a) Bare sample 3D printed b) Grit blasted, c) SEM image at 50× magnification d) SEM image at 300× magnification. FIG. 45 shows SEM images of PVA samples with aluminum as metal deposit as follows: a) Bare sample 3D printed b) Grit blasted, c) SEM image at 50× magnification d) SEM image at 300× magnification. FIG. 44 shows SEM images of the 3D printed PVA as follows: a) Image before spraying; b) Image from surface profiler c) Grit blasted surface at 100× magnification; d) First Pass; e) the Second pass; f) the third pass; g) the fourth pass; h) Interface between metal and Polymer 200× magnification; i) Interface between metal and Polymer 500× magnification. FIG. 46 shows SEM images of the copper deposit a) copper particle from wire-arc spray; b) Surface roughness measurement; c) Porosity in coatings, d) samples for adhesion test and microstructure. FIG. 47 shows surface roughness of the samples (average of 3 samples), and FIG. 48 shows adhesion strength of the coating (average of 3 samples).

In summary, conditions have been assessed for thermal spraying of metals onto polymer-based substrates and can be adapted to various polymeric materials, such as water-soluble thermoplastics, to provide a metal coating in the context of the techniques described herein. Operating conditions for various metal-polymer combinations can be adapted based on this work and description.

The following documents are incorporated herein by reference:
S. G. Kandlikar and C. N. Hayner, Liquid Cooled Cold Plates for Industrial High-Power Electronic Devices Thermal Design and Manufacturing Considerations, Heat Transf Eng., 2009, 30(12), p 918-930.
W. Qu and I. Mudawar, Experimental and Numerical Study of Pressure Drop and Heat Transfer in a Single-Phase Micro-Channel Heat Sink, Int. J. Heat Mass Transf, 2002, 45(12), p 2549-2565.
J. Judy, D. Maynes, and B. W. Webb, Characterization of Frictional Pressure Drop for Liquid Flows through Microchannels, Int. J. Heat Mass Transf., 2002, 45(17), p 3477-3489.
W. Owhaib and B. Palm, Experimental Investigation of Single-Phase Convective Heat Transfer in Circular Microchannels, Exp. Therm. Fluid Sci., 2004, 28(2-3), p 105-110.
V. Singh, H. Kumar, S. S. Sehgal, and R. Kukreja, Effect of Plenum Shape on Thermohydraulic Performance of Microchannel Heat Sink, J. Inst. Eng. Ser. C, Springer India, 2020, 101(1), p 73-84, DOI:10.1007/s40032-019-00515-z.
R. K. Shah, Advances in Science and Technology of Compact Heat Exchangers, Heat Transf Eng., 2006, 27(5), p 3-22.
T. Dixit and I. Ghosh, Review of Micro- and Mini-Channel Heat Sinks and Heat Exchangers for Single Phase Fluids, Renew. Sustain. Energy Rev., Elsevier, 2015, 41, p 1298-1311, doi:10.1016/j.rser.2014.09.024.
B. Shen, H. Yan, B. Sunden, H. Xue, and G. Xie, Forced Convection and Heat Transfer of Water-Cooled Microchannel Heat Sinks with Various Structured Metal Foams, Int. J. Heat Mass Transf, 2017.
Ramakrishnan, B., Hadad, Y., Alkharabsheh, S., Chiarot, P. R., & Sammakia, B. (2019). Thermal Analysis of Cold Plate for Direct Liquid Cooling of High Performance Servers. Journal of Electronic Packaging, 141(4).
T. Deng, G. Zhang, and Y. Ran, Study on Thermal Management of Rectangular Li-Ion Battery with Serpentine-Channel Cold Plate, Int. J. Heat Mass Transf, Elsevier Ltd, 2018, 125, p 143-152, DOI:10.1016/j.ijheatmasstransfer.2018.04.065.
S. Panchal, R. Khasow, I. Dincer, M. Agelin-Chaab, R. Fraser, and M. Fowler, Thermal Design and Simulation of Mini-Channel Cold Plate for Water Cooled Large Sized Prismatic Lithium-Ion Battery
J. Smith, R. Singh, M. Hinterberger, and M. Mochizuki, Battery Thermal Management System for Electric Vehicle Using Heat Pipes, Int. J. Therm. Sci., Elsevier, 2018, 134 (June 2017), p 517-529, DOI:10.1016/j.ijthermalsci.2018.08.022.
M. A. Arie, A. H. Shooshtari, and M. M. Ohadi, Experimental Characterization of an Additively Manufactured Heat Exchanger for Dry Cooling of Power Plants, Appl. Therm. Eng., Elsevier Ltd, 2018, 129, p 187-198, DOI:10.1016/j.applthermaleng.2017.09.140.
H. Liu, C. Lei, and Z. Xing, Cooling System of Hot Stamping of Quenchable Steel BR1500HS: Optimization and Manufacturing Methods, Int. J. Adv. Manuf Technol., 2013, 69(1-4), p 211-223.
H. Hoffmann, H. So, and H. Steinbeiss, Design of Hot Stamping Tools with Cooling System, CIRP Ann.—Manuf Technol., 2007, 56(1), p 269-272
B. A. Behrens, A. Bouguecha, M. Vucetic, M. Bonhage, and I. Y. Malik, Numerical Investigation for the Design of a Hot Forging Die with Integrated Cooling Channels, Procedia Technol., The Author(s), 2016, 26, p 51-58, doi:10.1016/j.protcy.2016.08.008.
B. B. Kanbur, S. Suping, and F. Duan, Design and Optimization of Conformal Cooling Channels for Injection Molding: A Review, Int. J. Adv. Manuf Technol., The International Journal of Advanced Manufacturing Technology, 2020, 106(7-8), p 3253-3271.
H. S. Park and X. P. Dang, Development of a Smart Plastic Injection Mold with Conformal Cooling Channels, Procedia Manuf., The Author(s), 2017, 10, p 48-59, doi:10.1016/j.promfg.2017.07.020.
B. A. Behrens, M. Kammler, A. Klassen, N. Vahed, and M. Bonhage, Development of a Powder Metallurgical Self Cooling Forging Die with Inner Cavities, Procedia Technol., Elsevier B. V., 2014, 15, p 456-464, doi:10.1016/j.protcy.2014.09.005.
C. C. Kuo, W. H. Chen, J. W. Zhang, D. A. Tsai, Y. L. Cao, and B. Y. Juang, A New Method of Manufacturing a Rapid Tooling with Different Cross-Sectional Cooling Channels, Int. J. Adv. Manuf Technol., The International Journal of Advanced Manufacturing Technology, 2017, 92(9-12), p 3481-3487.
M. S. Shinde and K. M. Ashtankar, Additive Manufacturing-Assisted Conformal Cooling Channels in Mold Manufacturing Processes, Adv. Mech. Eng., 2017, 9(5), p 1-14.
R. Gonzalez, H. Ashrafizadeh, A. Lopera, P. Mertiny, A. McDonald, A review of thermal spray metallization of polymer-based structures, J. Therm. Spray Technol. 25 (2016) 897-919
S. Devaraj, B. Anand, M. Gibbons, A. McDonald, and S. Chandra, Thermal Spray Deposition of Aluminum and Zinc Coatings on Thermoplastics, Surf. Coatings Technol., 399 (2020) 126114.
http://polymerdatabase.com
ASTM D4541-17, Standard Test Method for Pull-Off Strength of Coatings Using Portable Adhesion Testers, ASTM International, West Conshohocken, PA, 2017, www.astm.org
C. A. Klein, R. P. Miller, Strains and stresses in multilayered elastic structures: The case of chemically vapor-deposited ZnS/ZnSe laminates, J. of Applied Physics 87, (2000) 2265-2272.
C. A. Klein, How accurate are Stoney's equation and recent modifications, J. of Applied Physics 88, (2000), 5487-5489.

Additional work related to various aspect of the technology was also performed and will be described below.

Further Work Regarding a Novel Method of Fabricating Water-Cooled Heat Sinks with Complex Internal Structures Using Wire-Arc Spray

Miniaturization and performance improvements of electronic devices in recent decades have significantly increased heat dissipation rates. To overcome this, researchers have developed heat sinks with miniature fluid channels to maintain small device footprints with increased heat transfer performance. These channels are often fabricated using either subtractive fabrication methods, such as etching or micro-milling, or additive methods such as direct metal laser sintering (DMLS). These methods are limited by their long processing times, low geometric accuracy, or high cost. To overcome these limitations, a novel additive manufacturing method is developed using twin wire-arc spray. Wire-arc spray was used to build complex aluminum structures with length scales varying from 0.5 mm to 74 mm. Surface structures were built on a metal plate by spraying aluminum through a 3D printed polymer mask. Internal flow passages were made by filling surface channels with a water-soluble polyvinyl alcohol (PVA) paste that was allowed to harden, spraying metal over it, and then dissolving the PVA. The influence of wire-arc spray process parameters, such as standoff distance and scanning speed, on coating solid PVA with aluminum, were also investigated.

By way of introduction, miniaturization of electronic devices and improvements in their performance in recent decades have increased their heat dissipation rates while reducing their surface area available for heat transfer. Between 2010 and 2026, the average heat flux of electronic chips is projected to rise by a factor of nine. This has created a demand for effective thermal management solutions to maintain device temperatures within their safe operating range, and this has led to development of heat sinks with channels on the millimetre scale. The primary benefits of small diameter channels, compared to the larger channels that have traditional been used, are the larger fluid surface area to volume ratio, low coolant flow rates, and compact devices footprints.

Difficulties and costs associated with common methods of fabricating these channels present a major obstacle in the complexity of structures that can be fabricated. Common subtractive fabrications include etching (wet or dry), micro-milling, electrical discharge machining (EDM), and laser processing. Etching is typically limited to silicon and either has a low etching accuracy (dry etching), or a long processing time (wet etching). The remaining subtractive methods often use metal as their base material for enhanced thermal conduction but require long processing times. Additive manufacturing techniques such as direct metal laser sintering (DMLS) have been employed to allow for the fabrication of complex structures in an enclosed channel for which all sides are metal. However, these techniques are limited by their low geometric accuracy, high material cost, limited material options, long processing times, difficulty in fabricating overhang structures, and need for post-processing to remove support structures or unprocessed powder.

Metal spraying techniques have been used to fabricate an open-faced pin fin array heat sink, a metal foam heat exchanger, and a heat pipe. The goal of the present work is to develop a novel additive manufacture method using twin wire-arc spray to create fully enclosed liquid-cooled heat sinks with complex internal structures.

### Heat Sink Fabrication Method

FIG. 49 summarizes the key steps in the present heat sink fabrication method. A high-density wire-arc spray coating system (Thermion, WA, USA) was used for all coatings. Commercially available aluminum wire (Oerlikon Metco, NY, USA) was used in all wire-arc spraying steps with an input arc voltage of 28 V and dry air at a pressure of 690 kPa as the atomizing gas. During wire-arc spraying, the heat sink was cooled using two compressed airjets at a pressure of 690 kPa. Nozzle stand-off distance and scanning speed varied between fabrication steps and are discussed in subsequent sections.

First, a 2.5 mm deep rectangular pocket with a length of 74 mm and a width of 51 mm was machined into an aluminum plate (McMaster-Carr, IL, USA). Two steps with an offset of 2 mm and 4 mm from the pocket wall and respective depths of 1.5 mm and 0.75 mm from the top surface were added to improve the adhesion of the top coating. The bottom surface of the pocket was then roughened by grit blasting 80 grit aluminum oxide powder at a constant air pressure of 550 kPa at 25 cm from the plate, shown in FIG. 49(a). The additional material above the pocket was kept to secure the heat sink to the support structure during the wire-arc spray process. Next, a custom mask was 3D printed using a high-temperature photopolymer resin (formlabs, MA, USA) and press-fit into the pocket, shown in FIG. 49(b). FIG. 49(c) shows the structures after they have been additively manufactured using wire-arc spraying. Polyvinyl Alcohol (PVA) paste (Aleene's, CA, USA) was then deposited into the pocket and allowed to cure at room temperature for 24 hours (FIG. 49(d)). Once cured, the PVA paste was ground down to expose the internal structures at a height of 1 mm, coincident with the inner step height. The PVA paste, structures, and surrounding plate were grit blasted using the same parameters as described above. The resulting plate is shown in FIG. 49(e). A 1.5 mm layer of aluminum was then deposited into the pocket, forming a sealed cavity. After coating was complete, the plate was machined to the desired dimensions of 87 mm long by 64 mm wide by 4 mm thick and 5 mm inlet and outlet holes were added to the coated surface. The PVA paste was then dissolved by placing the heat sink in a water bath. This process was expedited by using a miniature water jet (Waterpik, CO, USA) at the inlet and outlet holes. The final heat sink is shown in FIG. 49(f). Preliminary experiments on the heat sink have been conducted. Water was passed through the heat sink at a flow rate of 1 L/min, with a resultant pressure drop of 11.5 kPa. No leakage was detected after two 5-hour runs.

### Structure Deposition

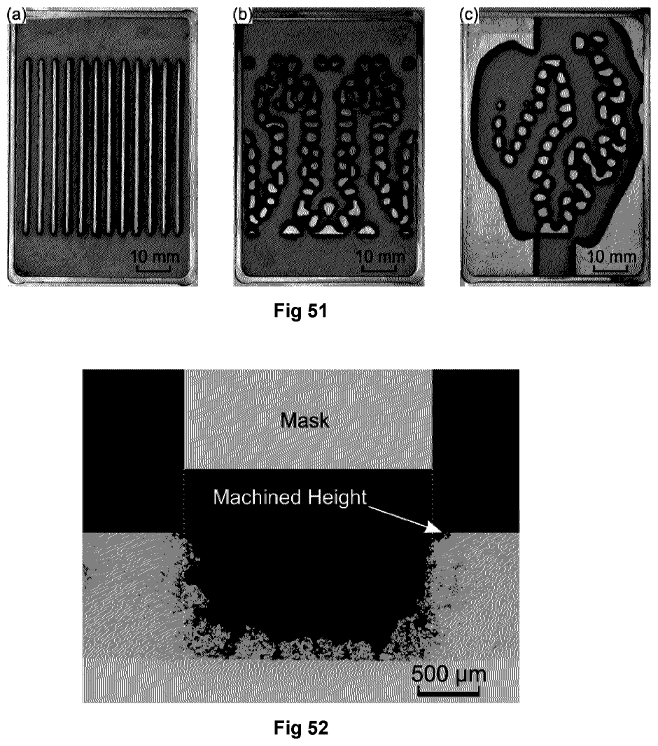

Structures were deposed into the heat sink cavity through a 3D printed photopolymer mask of high-temperature photopolymer resin. A schematic of the spraying process through the mask is shown in FIG. 50. The mask was designed to fit into the inner step of the plate, providing accurate control of the structure placement. A 0.5 mm offset was added from the bottom of the mask (1.5 mm from the bottom of the heat sink pocket) to ensure that the structures would not bond to the mask once they reached the desired height. A total mask thickness of 6.5 mm was used to prevent warping of the mask during ultraviolet curing of the 3D printed part after printing and during the wire-arc spraying process. Initial trials considered a mask thickness of 3 mm; however, the mask was found to warp into the pocket, causing the central structures to bond to the mask. Before spraying, the surface of the mask was polished with 600 grit silicon carbide paper to reduce the adhesion of the aluminum to the mask.

To ensure coating uniformity of the structures across the heat sink, the wire-arc spray nozzle was mounted to a robotic arm with a standoff distance of 23 cm. The robotic arm was programmed to travel at a speed of 250 mm/s in a serpentine pattern consisting of parallel passes spaced 10 mm apart. All plates were coated with 30 pass patterns, and 70 seconds between each pass pattern to allow the substrate to cool. Compressed air was used to clear the mask of any particles between pass patterns to prevent the coating from covering the mask openings. The resulting structures had a height of approximately 1.3 mm. These structures were ground to a height of 1 mm to form a flat surface.

FIG. 51 shows various 1 mm tall structures deposited into heat sinks, demonstrating the versatility of this method. FIG. 51(a) is a set of 1 mm wide by 50 mm long parallel fins, a commonly used geometry in mini-channel heat sinks. FIG. 51(b) is a set of topologically optimized structures to deliver the fluid uniformly around the heat sink pocket, demonstrating the ability to fabricate complex non-traditional structures. FIG. 51(c) is a topologically optimized design intended to deliver flow to one specific area in the heat sink, demonstrating the ability to modify the outer shape of a fluid channel given a standard pocket. The optimization method used to develop the structures shown in FIG. 51(b) and FIG. 51(c) is outside the scope of the present study and will be discussed elsewhere.

Plates with 1 mm wide fins spaced 2 mm apart were fabricated using the method described above and cross-sections take through them to examine their microstructure using a scanning electron microscope (SEM). The location of the mask relative to the structures is shown in FIG. 52, sitting 1.5 mm above the bottom surface of the pocket. Dotted lines are added to show the projection of the mask toward the base. A porous section can be seen on the structures between the dotted lines and along the bottom of the channel between the structures. This is attributed to satellite particles ricocheting from the vertical walls of the mask and the sides of the structures. As the structures increase in height with each pass, the impact angle of the particles decreases, resulting in fewer particles sticking to the structure. This phenomenon has been similarly observed in cold spray applications at small impact angles.

The machine height of the channels is also shown in FIG. 52 by a shaded region located 1 mm above the base of the pocket. The machining operation provides accurate and repeatable control of the structure height and width by removing the dome region.

### Aluminum Deposition on PVA Paste

The influence of the wire-arc nozzle standoff distance from a PVA substrate was studied by depositing aluminum onto 25 mm×50 mm coupons of cured PVA paste at standoff distances of 6 inches (15 cm), 9 inches (23 cm), and 14 inches (36 cm). The wire-arc nozzle was mounted to a robotic arm which was programmed to travel in a single horizontal line across the coupon at a speed of 250 mm/s. Passes were performed in 2-minute intervals to allow the coupon to cool. The coupon was carefully mounted to a steel holder to ensure the center of the coupon was coincident with the center of the spray nozzle.

FIG. 53 shows the coupons after 6, 18, and 30 single horizontal passes of the spray nozzle at the various standoff distances. At a 6-inch standoff, the coating does not adhere to the PVA coupon, regardless of the number of passes. After 18 passes there is evidence of some particles adhering to the PVA coupon. However, after subsequent passes, these particles are dislodged, resulting in a bare surface after 30 passes. At 9 inches, the coating shows evidence of adhering to the PVA coupon at a low deposition efficiency. After 6 passes, the coating is very sparse across the coupon. The deposition efficiency appears to improve as the number of passes increases. From 6 to 18 passes, the difference in surface area covered by the coating is lower than the difference between 18 and 30 passes. This is attributed to the coating adhering well to the deposited aluminum nucleation sites at a higher rate than the bare PVA coupon. The result is concave islands of aluminum forming throughout the substrate, where the edges of the coating are raised due to thermal stresses. In this case, a complete coating is formed once adjacent islands connect with subsequent passes. At a 14-inch standoff, the coating adheres uniformly across the PVA coupon. An increased number of adhered particles is observed after 6 passes compared to the closer standoff distances. This results in more nucleation sites for subsequent particles to adhere to. The result is a uniform coating after 30 passes without the weld lines of connecting islands seen at a 9-inch standoff.

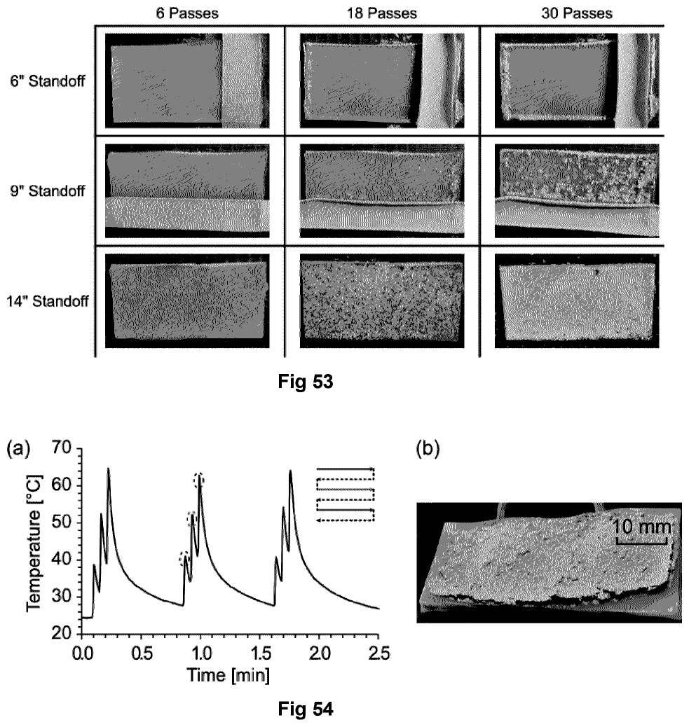

Since the PVA paste in the present heat sink has dimensions of 74 mm by 51 mm, a single pass along the center of the pocket would result in an uneven coating. To address this, the serpentine robot program used to fabricate the internal structures was used. The spray nozzle was turned on for alternating passes, as shown by the solid lines in the inset of FIG. 54(a). The resulting spray pattern was three horizontal passes spaced 20 mm apart. Two K-type thermocouples were placed 22 mm apart at the surface of a PVA paste coupon to measure the surface temperature during spraying. The coupon was mounted to ensure the center of the coupon was coincident with the center of the nozzle during the second of three passes in the pass pattern. FIG. 54(a) shows the temperature during three pass patterns. Each spike in the temperature represents one of the three horizontal passes in each pattern, increasing with each pass to a maximum of 65° C. and allowed to cool for 46 seconds between pass patterns. FIG. 54(b) shows the coupon after applying a 0.3 mm coating with 18 pass patterns. Unlike the single-pass study in FIG. 54, the coating exhibited delamination at a 6-inch standoff distance. This was attributed to the 15° C. increase in surface temperature between the first and third passes of the pass pattern.

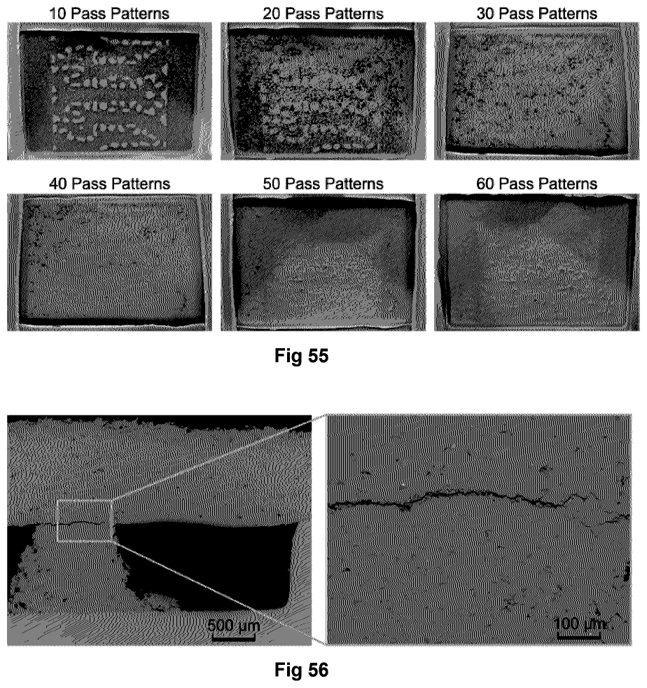

To reduce the substrate temperature while spraying the large PVA paste surface of the heat sink, the scanning speed was increased while maintaining the three-pass pattern. Due to the maximum speed limitations of the robot, the coating of the heat sink was performed by hand at a scanning speed of approximately 1 m/s. FIG. 55 shows the coating evolution of the heat sink sprayed manually. Each pass pattern represents three manual passes at approximately 1 m/s. This process was repeated for manual 240 pass patterns until a top coating thickness of 1.5 mm was achieved.

A sacrificial plate with 1 mm tall and 1 mm wide structures and the top coating was fabricated using the identical processes as described above. FIG. 56 shows a structure and 1.5 mm thick top coating. The coating adhered well to the top of the machined pocket in the left image of FIG. 56. However, delamination was observed between the top coating and the structure. A 15 μm wide crack developed during the spray process and appears to be propagating toward the right of the structure. This did not affect the mechanical integrity of the cold plate, but can reduce the heat transfer to the fins.

### Findings

This work demonstrated a novel additive manufacturing method for heat sinks with complex geometries using wire-arc spray. Internal structures were fabricated in a machined pocket by spraying aluminum through a 3D printed photopolymer mask. Sealed flow passages were formed by filling the surface channels with a PVA paste, allowing it to cure, coating it in aluminum, then dissolving the PVA.

A variety of complex structures were shown with a wide range of length scales. Individual structures were observed under SEM, revealing a dense inner structure with a porous outer layer. Low substrate temperatures were required for the adhesion of the coating to the PVA substrate. This was achieved manually by using a 14-inch standoff distance and approximately 1 m/s scanning speed.

The deposition efficiency of aluminum onto hardened PVA paste could be enhanced by assessing deposition variables. For example, preliminary results indicate that embedding metal powder into the surface of the PVA paste results in improved coating quality by creating many densely packed nucleation sites.

The following references are incorporated herein by reference:
H. E. Ahmed, B. H. Salman, A. S. Kherbeet, M. I. Ahmed, Optimization of thermal design of heat sinks: A review, Int. J. Heat Mass Transf. 118 (2018) 129-153. https://doi.org/10.1016/j.ijheatmasstransfer.2017.10.099.
T. G. Karayiannis, M. M. Mahmoud, Flow boiling in microchannels: Fundamentals and applications, Appl. Therm. Eng. 115 (2017) 1372-1397. https://doi.org/10.1016/j.applthermaleng.2016.08.063.
D. Deng, L. Zeng, W. Sun, A review on flow boiling enhancement and fabrication of enhanced microchannels of microchannel heat sinks, Int. J. Heat Mass Transf. 175 (2021) 121332. https://doi.org/10.1016/j.ijheatmasstransfer.2021.121332.
D. B. Tuckerman, R. F. W. Pease, High-performance heat sinking for VLSI, IEEE Electron Device Lett. EDL-2 (1981) 126-129. https://doi.org/10.1109/EDL.1981.25367.
E. S. Cho, J. W. Choi, J. S. Yoon, M. S. Kim, Experimental study on microchannel heat sinks considering mass flow distribution with non-uniform heat flux conditions, Int. J. Heat Mass Transf. 53 (2010) 2159-2168. https://doi.org/10.1016/j.ijheatmasstransfer.2009.12.026.
Z. Wan, Y. Wang, X. Wang, Y. Tang, Flow boiling characteristics in microchannels with half-corrugated bottom plates, Int. J. Heat Mass Transf. 116 (2018) 557-568. https://doi.org/10.1016/j.ijheatmasstransfer.2017.09.029.
S. A. Jajja, W. Ali, H. M. Ali, A. M. Ali, Water cooled minichannel heat sinks for microprocessor cooling: Effect of fin spacing, Appl. Therm. Eng. 64 (2014) 76-82. https://doi.org/10.1016/j.applthermaleng.2013.12.007.
P. Cui, Z. Liu, Enhanced flow boiling of HFE-7100 in picosecond laser fabricated copper microchannel heat sink, Int. J. Heat Mass Transf. 175 (2021) 121387. https://doi.org/10.1016/j.ijheatmasstransfer.2021.121387.
I. L. Collins, J. A. Weibel, L. Pan, S. V. Garimella, Experimental characterization of a microchannel heat sink made by additive manufacturing, Proc. 17th Intersoc. Conf. Therm. Thermomechanical Phenom. Electron. Syst. ITherm 2018. (2018) 171-177. https://doi.org/10.1109/ITHERM.2018.8419588.
A. Verma, S. Tyagi, K. Yang, Modeling and optimization of direct metal laser sintering process, Int. J. Adv. Manuf. Technol. 77 (2015) 847-860. https://doi.org/10.1007/s00170-014-6443-x.
E. Atzeni, A. Salmi, Study on unsupported overhangs of AlSi10Mg parts processed by Direct Metal Laser Sintering (DMLS), J. Manuf. Process. 20 (2015) 500-506. https://doi.org/10.1016/j.jmapro.2015.04.004.
J. Perry, P. Richer, B. Jodoin, E. Matte, Pin fin array heat sinks by cold spray additive manufacturing: Economics of powder recycling, J. Therm. Spray Technol. 28 (2019) 144-160. https://doi.org/10.1007/s11666-018-0758-3.
N. Tsolas, S. Chandra, Forced convection heat transfer in spray formed copper and nickel foam heat exchanger tubes, J. Heat Transfer. 134 (2012) 1-10. https://doi.org/10.1115/1.4006015.
C. Feng, M. J. Gibbons, M. Marengo, S. Chandra, A novel ultra-large flat plate heat pipe manufactured by thermal spray, Appl. Therm. Eng. 171 (2020) 115030. https://doi.org/10.1016/j.applthermaleng.2020.115030.
K. Binder, J. Gottschalk, M. Kollenda, F. Gartner, T. Klassen, Influence of impact angle and gas temperature on mechanical properties of titanium cold spray deposits, J. Therm. Spray Technol. 20 (2011) 234-242. https://doi.org/10.1007/s11666-010-9557-1.

### Additive Manufacturing of Metal Components by Thermal Spray Deposition on 3D-Printed Polymer Parts

In further work, metals were deposited using wire-arc spray-on components made by 3D printing with polyvinyl alcohol (PVA), a water-soluble polymer. The polymer was then dissolved, leaving a metal layer whose surface topography was negative to that of the polymer. This is a rapid and low-cost alternative to 3D printing directly using metal, but to succeed it is essential for the sprayed metal to adhere to the polymer substrate. Tests were done in which aluminum and copper were sprayed using a twin-wire arc spray system onto 3D printed coupons, 50 mm×50 mm in size, made from PVA, polylactic acid (PLA), and PLA mixed with metal (aluminum, copper) or carbon fiber. Adhesion depended on substrate roughness (minimum 1-2 μm) substrate temperature (above the glass transition temperature but below the melting temperature of the polymer) and minimizing residual stresses due to mismatch of the thermal expansion coefficients of metal and polymer. It was shown that surface features could be made on metal components using this technique. Plates with internal flow passages were made by placing 3D printed PVA parts in channels machined in the plates, spraying metal over the polymer, and then dissolving the polymer.

In the below section, the following nomenclature applies:

### Nomenclature

Al Aluminum
Cu Copper
PLA Polylactic acid
PVA Polyvinyl alcohol
SEM Scanning electron microscope
E_{c} Young's Modulus (N/mm²)
L length of the component (m)
ΔLₛ change in substrates length (m)
t_{c} thickness of the coating (m)
tₛ thickness of the substrate (m)
T_{g} glass transition temperature (° C.)
Tₘ melting temperature (° C.)
R radius of curvature (m)
Rₐ surface roughness (μm)
ΔT temperature decrease (° C.)
V voltage (V)

### Greek Symbols

α_{c} coefficient of thermal expansion of coating material (° C.⁻¹)
αₛ coefficient of thermal expansion of substrate material (° C.⁻¹)
δ deflection in the component (m)
ε strain in the component
v_{c} Poission's ratio of the coating material
vₛ Poission's ratio of the substrate material
σ_{A} adhesive strength (MPa)
σ_{c} stress in the coating (N/mm²)
K curvature (m⁻¹)

### Subscripts

c coating
s substrate

### Introduction

Thermal spray, especially cold spray, is increasingly being used as an additive manufacturing technique, motivated by the fact that it has much higher deposition rates and lower energy consumption than other methods used to make functional metal components, such as powder bed fusion. However, the resolution of a part made by a spray process is determined by its spot size, currently, about 4 mm for a cold spray system and, being a line-of-sight method, cannot deposit material in interior cavities. Components made with thermal spray typically need machining to achieve the tolerances and surface finish required for practical use. It is much easier to make components from polymers rather than metals using 3D printing methods since relatively low-cost printers are readily available to fabricate objects from a broad variety of polymers with extremely good resolution, but these cannot withstand the high temperatures and stresses encountered in many applications.

We propose a novel method of making metal components with complex geometries by combining thermal spray with 3D printing of polymers. Water-soluble polymers are available in the form of filaments that can be deposited by 3D printers. These are usually used to create voids and overhangs in parts by forming supports during fabrication that are dissolved after printing is completed. We propose to print shapes out of water-soluble polymer, spray metal on them, and then dissolve the polymer leaving only metal behind. By this method, the shape of the polymer is transferred to the metal. We can also use this method to make internal channels with complex shapes in metal plates.

Depositing metal coatings on polymer surfaces has its own challenges. Gonzalez et al. reviewed the current state of the art for thermal spray metallization of polymers and found that the low melting point and soft nature of most thermoplastics made it difficult to apply metal coatings on them using thermal spray techniques. Thermal sprayed coatings are formed by the impact of molten metal particles on a substrate where they freeze during impact to form “splats”. The surface is preferably rough (average roughness ˜1 to 10 μm) so that molten metal can penetrate crevices and solidify, forming mechanical bonds

Several studies have been done on using cold spray to coat polymers, and they have shown that high-velocity particles tend to erode the substrate which prevents good adhesion of the coating. Deposition efficiencies are therefore low, except for low-melting-point metals. Flame spraying, in which particles are largely molten at the time of impact and impact velocities are relatively low, has been used to deposit metal coatings on polymers to create sensors or heating elements. Wire-arc spraying, in which metal droplets are completely molten, has also been used to deposit metal coatings on polymers.

Devaraj et al showed that the temperature of the substrate needs to be controlled carefully during spraying. If the temperature exceeds the melting temperature of the polymer there is localized melting under the impacting droplet and surface asperities are destroyed, leaving no place for molten metal to anchor itself as it solidifies. Zinc could be coated on polyethylene coupons, but aluminum could not because it has a higher melting temperature (Tₘ=660° C.) than zinc (Tₘ=420° C.). Impacting aluminum particles melted the substrate and did not leave large enough cavities for molten metal to flow into. However, aluminum can be applied to Teflon (PTFE), which has a higher melting temperature.

To get good coating adhesion the polymer surface is preferably rough (average roughness ˜1 to 10 μm) so that molten metal can penetrate crevices and solidify, forming mechanical bonds. Grit blasting is usually used to roughen substrates prior to coating, but polymers are often too soft to be made sufficiently rough in this way. The thermal expansion coefficients of polymers are also significantly greater than those of metals. Thermal stresses that develop as the metal solidifies and cools can also lead to detachment of the coating.

Some objectives of this study were to: (a) demonstrate that it is possible to deposit aluminum and copper coatings on 3D printed polymer components, (b) determine spray conditions under which the metal would adhere well to the polymer, and (c) show that it is possible to make complex metal parts by spraying metal on sacrificial polymer components that were then dissolved.

### Experimental Methods

Test coupons (50 mm×50 mm×3 m) were made using an open-source 3D printer (Prusa I3 MK3S, Prusa Research, Prague, Czech Republic) two commonly used polymers: polyvinyl alcohol (PVA), which is soluble in water, and polylactic acid (PLA), which is not soluble. The PLA filaments contained additives to increase their thermal conductivity, with aluminum or copper powders or carbon fibers mixed in the polymer. The printer used a Fused Deposition Modelling (FDM) process in which the polymer filament is heated to its melting point and then extruded in layers, each 50±0.05 μm thick, to form an object. The coupons, therefore, had ridges on them corresponding to the edges of the filament. The surface roughness of the 3D-printed coupons was measured by a skid-reference profilometer (Precision Devices Inc., Michigan, USA) with at least 6 measurements taken for each sample. The 3D printed coupons had an apparent surface roughness of 3 to 4 μm, but this was created by regularly spaced ridges with smooth regions in-between and did not help coating adhesion. To remove the ridges the coupons were grit blasted using alumina grit (mesh size 325-400, 3337K51, Mc Master Carr, California, USA) at an air pressure of 310 kPa, creating a uniform roughness of 1.5 to 2 μm.

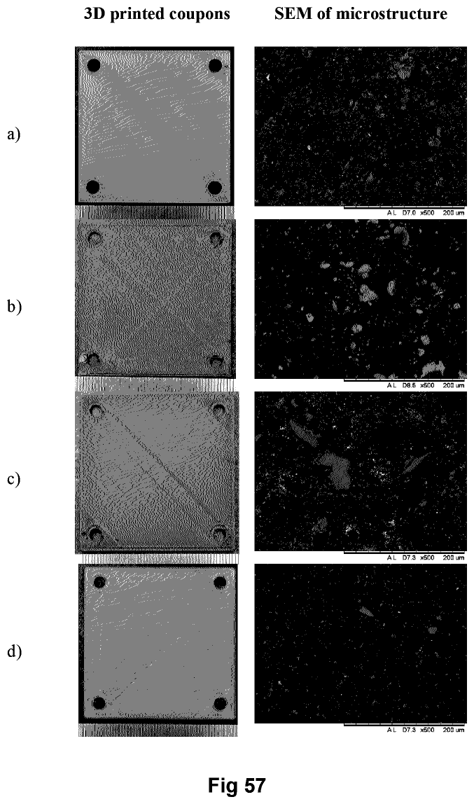

FIG. 57 shows photographs of coupons of PLA filled with aluminum (FIG. 57a), PLA filled with copper (FIG. 57b), PLA filled with carbon fibres (FIG. 57c), and PVA (FIG. 57d). The ridged texture of the coupons can be seen, created by the FDM process. Next to each photograph in FIG. 57 is a micrograph of the coupon taken using a scanning electron microscope (SEM) (Hitachi Tabletop, TM 3000, Tokyo, Japan). The SEM images were taken after grit blasting, which removed the ridges on the surface and made their roughness uniform. A copper tape was attached to the substrate and aluminum mount on which the sample was placed to avoid specimen charging.

A twin wire-arc spray coating system (AVD 456 HD, Thermion, Washington, USA) mounted on a programmable robot arm was used to deposit metal on 3D printed polymer substrates. Commercially available aluminum (#1031591, Oerlikon Metco, New York, USA) and copper (#1000446, Oerlikon Metco, New York, USA) were used. The spray parameters were kept constant and are listed in Table 1C.

TABLE 1C
Thermal spray parameters for metal deposition using wire arc

| Variable | Input |
|---|---|
| Torch | ValuArc |
| Wire feed rate m/min | 7 |
| Voltage applied, V | 32 for Cu, 30 for Al |
| Air inlet pressure, kPa | 690 |
| Spray distance, mm | 150 |
| Number of spray passes | 5 for Cu, 8 for Al |

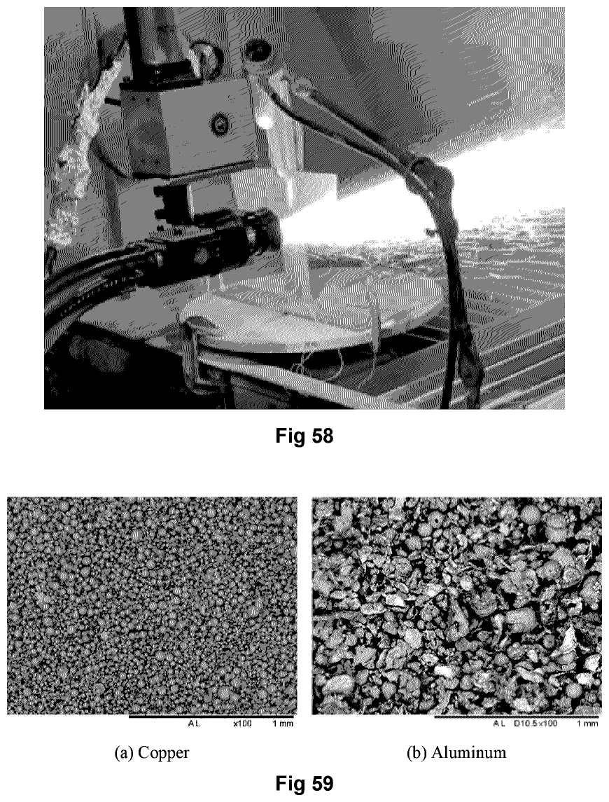

Two air jets at a pressure of 690 kPa (100 psi) were blown continuously over the polymer substrates during spraying to keep them from overheating. The substrate temperature was recorded using four K-type thermocouples (TT-K-40-SLE-, Omega Engineering Inc., Connecticut, USA), connected to a data acquisition module (OMB-DAQ-56, Omega Engineering Inc., Connecticut, USA). FIG. 58 shows a photograph of the spray nozzle in operation in which the test coupon and cooling air nozzles can be seen. Metal particles were collected in a water bath, dried and SEM images were taken (see FIG. 59). The average diameter of the particles was determined by a laser diffraction particle size analyzer, Mastersizer 2000, (Malvern Instruments Ltd., Malvern UK). The mean diameter of the aluminum particles was 70±10 μm and that of the copper was 80±10 μm.

The adhesion strength of metal coatings on polymer substrates was measured using a pull test according to the ASTM standard D4541 using a PosiTest AT-M Manual Tester (DeFelsko, New York, USA). Six measurements were taken for each of the four polymers using a 20 mm diameter aluminum pull stub, bonded to the metal coating with a high-strength aluminum-filled two-part epoxy (Devcon-19770, ITW Performance Polymers, Ontario, Canada) that was allowed to cure for around 24 hours before testing. Copper was also deposited on a copper coupon with the same dimensions as the 3D printed ones to compare the adhesion strengths. Scoring on the samples, a process of isolating the aluminum stub attached to the metal deposited polymer by a saw-toothed circular tool was not necessary since the coating thickness was less than 500 μm.

### Results and Discussion

### Adhesion of Metal Coatings on Polymers

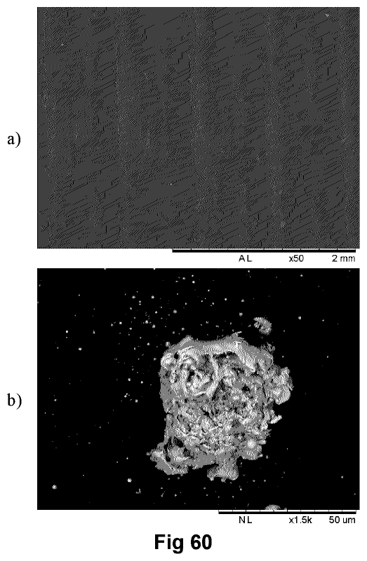

FIG. 60a shows an SEM of the surface of a PVA coupon as printed, without being grit-blasted. The lines visible on it are the ridges left by the printing process that lays down the polymer filament in layers. Though the average surface roughness was measured to be 3-4 μm, the area between the ridges was much smoother and did not provide any crevices in which impacting splats could penetrate and anchor themselves. FIG. 60b shows an aluminum particle deposited on the PVA coupon. Small fragments embedded in the substrate show the extent to which the molten droplet spread during impact. However, it was unable to remain attached and the surface tension forces pulled it back to form a roughly spherical mass that was only weakly bonded to the surface. The 3D printed coupons were therefore grit-blasted using aluminum oxide particles propelled onto the surface by a compressed air nozzle at a pressure of 310 kPa giving a uniform roughness (Rₐ) of approximately 1.5 μm. Average roughness of 1-2 μm is found to be sufficient for deposition of a 200±20 layer by wire-arc spraying.

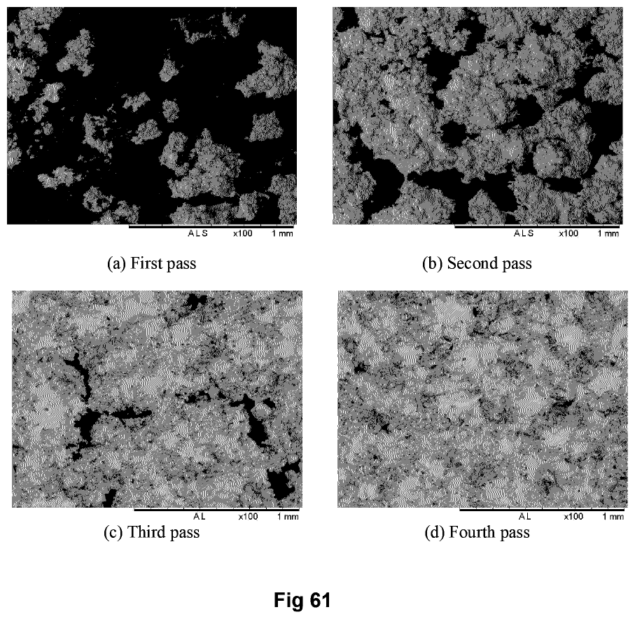

FIG. 61 shows SEM images of the surface of a PVA coupon surface after successive passes of the wire-arc spray. The first pass (FIG. 61a) deposited individual splats of aluminum that adhered well. The mean diameter of the spray particles was measured to be 70 μm, but many smaller splats can be seen as well. These provide anchors for subsequent splats to attach to the substrate (FIG. 61 b and c), so by the fourth pass (FIG. 61d) of the torch the polymer substrate was almost completely covered by aluminum. After 5 passes of the torch, a coating 150 to 200 μm thick formed on the surface.

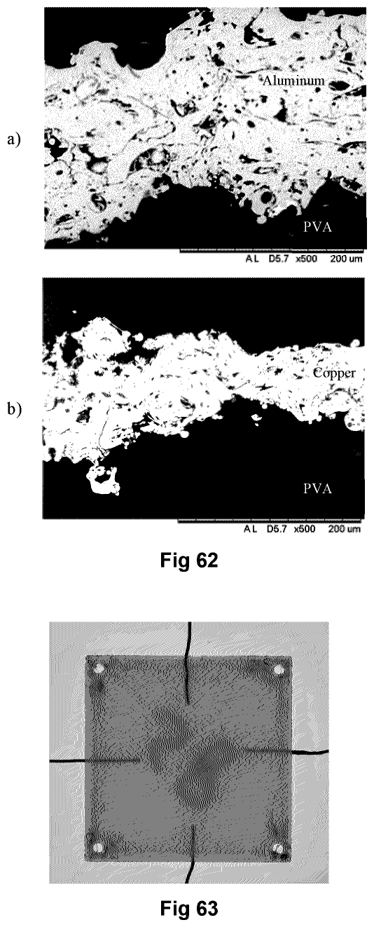

FIG. 62 shows a cross-section through aluminum (FIG. 62a) and copper (FIG. 62b) coatings on PVA substrates. Photographs of the coating at different locations were taken with a magnification of 500× and analyzed with Image J software that converted them into 8-bit resolution images. The average thickness of the copper coating was 200±20 μm and of the aluminum, coating was 150±20 μm. The porosity of the coating, measured by averaging the area of all the visible pores at four different locations, was 17% for aluminum coatings and 14% for copper coatings with a standard deviation of 5% in both cases. Both coatings adhered well to the substrate, filling in all the surface asperities.

The temperature of the substrate during coating is important in achieving good coating adhesion. Previous studies have shown that the temperature should exceed the glass transition temperature where the polymer begins to soften so that impacting droplets pierce the substrate, but remain well below the melting point at which surface asperities are destroyed so that the splats cannot find crevices to penetrate. The glass transition temperature of PVA is approximately 50° C., and the melting temperature is 220° C. Thermocouples were inserted into four holes, 650 μm in diameter and 15 mm deep, that were drilled into the edges of the 3 mm thick polymer coupons. FIG. 63 shows an image of a coupon with thermocouples inserted, which are visible through the translucent polymer. The maximum heat flux on the surface during spraying was estimated by multiplying the mass flux of metal by its latent heat of fusion. This was used to estimate the temperature differences between the sprayed surface of the coupon and the thermocouples, which was found to be less than 2° C. in all cases. All the thermocouples were interfaced with a data acquisition system to continuously record the temperature during spraying.

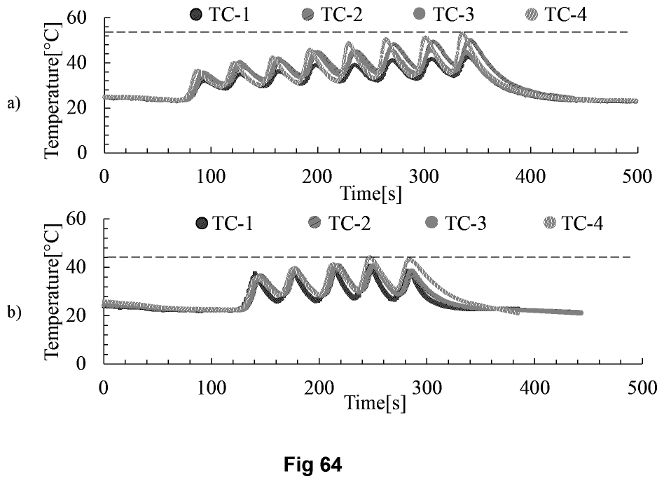

FIG. 64a shows the temperature variation of PVA coupons on which aluminum was being sprayed. The signals from all four thermocouples inserted into the coupon are shown. The spray torch passed over the coupon 8 times, with a 30s interval between passes. The peak temperature increased during the first 5 passes and reached a maximum value of 52° C. This is close to the glass transition temperature of PVA, but well below its melting point. FIG. 64b shows the temperature variation during the spraying of copper, which took only 5 passes of the torch. In this case, the peak temperature reached 44° C.

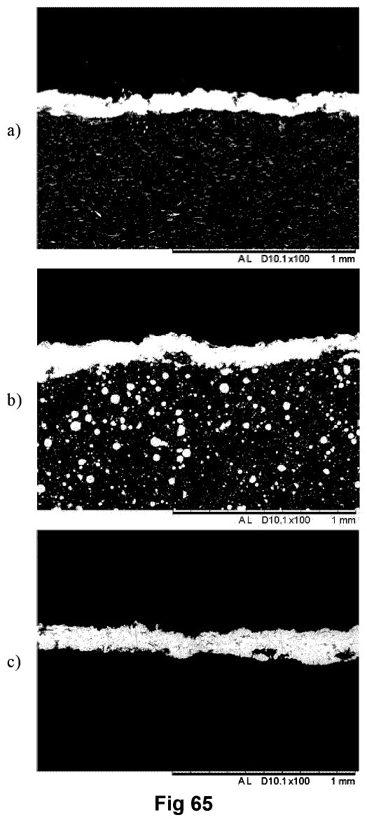

Adding fillers to the polymer can aid adhesion in two ways: it can increase the effective thermal conductivity of the polymer coupons, making them easier to cool; and exposed metal particles in the polymer can act as sites to which impacting splats attach. FIG. 65 shows cross-sections through coatings of copper deposited on PLA substrates filled with either aluminum (FIG. 65a), copper (FIG. 65b) or carbon fiber (FIG. 65c). The coatings adhere well to all three substrates and fill in crevices at the interface. There is evidence of the coating adhering to the metal powder, especially to the copper particles (see FIG. 65b).

The adhesive strength (σ_{A}) of the coating was measured using a pull test as per ASTM standard ASTM D4541-17. A standard aluminum pull stub, 20 mm in diameter was bonded to the centre of the coated samples using an epoxy adhesive Once the epoxy hardened, the coating was pulled off using a Posi-tester and the stress required to pull off the coating was recorded. Additional tests were done on coupons, for monitoring temperatures, evaluating the adhesive strengths, and microstructural examinations, to arrive at conditions for coating copper onto 3D printed polymers. Polymers mixed with additives (fillers such as aluminum powder, copper powder, or carbon fibre) increased the roughness of the coupons and make them more resistant to heating. Adhesion tests were also done on a copper substrate where copper was deposited to serve as a reference.

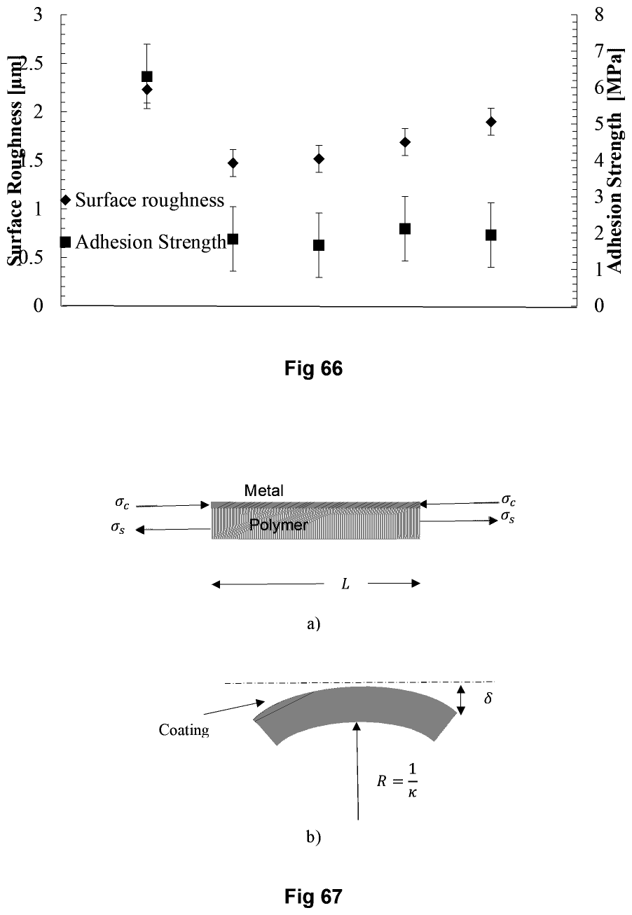

FIG. 66 shows the values of measured surface roughness of coupons and the corresponding adhesive strengths of copper coatings applied to them. A total of 5 measurements were taken for each type of coupon and the data points show their average value. The error bars show the standard deviation in measurements. The average surface roughness of the polymer coupons ranged from 1.5 μm to 1.9 μm, while that of the copper coupon was higher, 2.33 μm. The average adhesion strength of the polymer coupons when copper was deposited is also shown in FIG. 10. The average value of adhesion strength was similar for all the polymer samples, ranging from 1.7 MPa for copper coatings on PLA with aluminum fillers to 2.1 MPa on PLA with carbon fibers. For comparison, the average adhesive strength of copper coatings on copper coupons was 6.3 MPa.

FIG. 39 shows photographs of coupons after the pull tests. The coatings detached fully from the substrate, so that the failure was at the coating-substrate interface, rather than within the coating itself or within the epoxy holding the pull-stub to the coating.

### Thermal Stresses and Coating Delamination

Thermal stresses can lead to delamination of a metal coating after it has been applied and the component has cooled down. Tables 2C and 3C list coefficients of thermal expansion for several metals and polymers, including some not tested here, to show typical values. Metals have coefficients of thermal expansion (a) in the range of 10-35×10⁻⁶° C.⁻¹ (see Table 2C), lower than those of most polymers which are typically in the range of 60-220×10⁻⁶° C.⁻¹ (see Table 3C).

TABLE 2C
Thermal properties of metals

| | | Coefficient |
|---|---|---|
| | Melting | of thermal |
| | temperature | expansion α |
| Metal | Tₘ [° C.] | [° C.⁻¹] |
| Aluminum | 643-657 | 18-24 × 10⁻⁶ |
| Copper | 1085 | 17-18 × 10⁻⁶ |
| Stainless Steel | 1370-1530 | 10-15 × 10⁻⁶ |
| Magnesium | 650 | 25-26 × 10⁻⁶ |
| Zinc | 420 | 30-35 × 10⁻⁶ |

TABLE 3C
Thermal properties of polymers

| | | Glass | Coefficient |
|---|---|---|---|
| | Melting | transition | of thermal |
| | temperature | temperature | expansion α |
| Polymer | Tₘ [° C.] | T_{g} [° C.] | [° C.⁻¹] |
| ABS - Acrylonitrile | 220-260 | 102-107 | 60-110 × 10⁻⁶ |
| butadiene styrene | | | |
| PVA - | 178-230 | 34-85 | 70-120 × 10⁻⁶ |
| Polyvinylalcohol | | | |
| PC - Polycarbonate | 270-310 | 160-200 | 65-70 × 10⁻⁶ |
| PLA - Polylactic acid | 164-178 | 55-75 | 68 × 10⁻⁶ |
| Teflon - | 317-345 | 130 | 111-220 × 10⁻⁶ |
| Polytetrafluorethylene | | | |

After spraying, as the component cools, both the substrate and the coating bonded to its contract (see FIG. 67), with the substrate contracting by a larger amount. The change in length of the substrate is ΔLₛ=αₛLΔT where ΔT is the temperature decrease as the component cools from the peak temperature it reached during spraying back to room temperature, L is the initial length of the coated component and as the coefficients of thermal expansion of the substrate. If the coating was free-standing it would contract by ΔL_{c}=α_{c}LΔT where α_{c} is the coefficient of thermal expansion of the coating. However, since the substrate is much thicker than the coating, the coating is forced to contract by the same amount as the substrate, ΔLₛ. The strain (ε) produced in the coating due to this mismatch is:

$$ε = \frac{( Δ {L}_{c} - Δ {L}_{s} )}{L} = ( {α}_{c} - {α}_{s} ) Δ T \qquad ( Eq . 1 )$$

As an illustration, for the case of an aluminum coating (α_{c}=18×10⁻⁶° C.⁻¹ see Table 2C) on a PVA substrate (as =70×10⁻⁶° C.⁻¹=70×10⁻⁶, see Table 3C) which is assumed to cool from its peak temperature back to room temperature after spraying by approximately ΔT=36° C., which was the average temperature change of 6 PVA coupons that were sprayed with aluminum, Eq. (1) give a strain ε=−1.9×10⁻³.

The stress (see FIG. 67) generated in the coating is:

$${σ}_{c} = \frac{{E}_{c}}{( 1 - {ν}_{c} )} ε = \frac{{E}_{c}}{( 1 - {ν}_{c} )} ( {α}_{c} - {α}_{s} ) Δ T \qquad ( Eq . 2 )$$

where E_{c} is the Young's modulus of the coating material and v_{c} It's Poisson's ratio. For aluminum (E_{c}=70 GPa and v_{c}=0.34), so the stress in the coating in the example above is −200 MPa. The negative sign implies that it is compressive stress while the substrate experiences tensile stress. The stress mismatch between the coating and substrate forces the polymer substrate to curve and its curvature is:

$$κ = 6 \frac{( 1 - {ν}_{s} )}{{E}_{s}} \frac{{t}_{c}}{{t}_{s}^{2}} {σ}_{c} \qquad ( Eq . 3 )$$

where Eₛ and vₛ are Young's modulus and Poisson's ratio of the substrate and tₛ and t_{c} are the thicknesses of the substrate and coating respectively. For PVA filaments Eₛ=25.2 GPa and vₛ=0.4. In our 6 sprayed samples the average coating thickness was t_{c}=220 μm and the substrate thickness tₛ=3.0 mm giving a curvature κ=−6.8×10⁻⁴ m⁻¹. A negative curvature implies that the surface curves with the coating on its convex side, as shown in FIG. 12b. As the substrate curves its ends arc away from the plane of the center and the radius of the arc is given by R=κ⁻¹, which is 1.48 m.

Experimental measurement of the radius of curvature due to thermal stresses was done on six PVA coupons coated with aluminum using an optical comparator (HE-400, Starrett Kinemetric Engineering, Inc, California, USA). A total of four measurements (one on each face) were taken on the six samples with six points to determine the radius of the arc formed by these points. The radius of curvature of the coupons was measured both before and after spraying and the difference in the values of the measured radii was 0.90 m, the same order of magnitude as that calculated (1.48 m). Given the uncertainties in the measurements of the coating thickness and properties and variations in the temperature of the coupons, it is difficult to predict the curvature with greater accuracy.

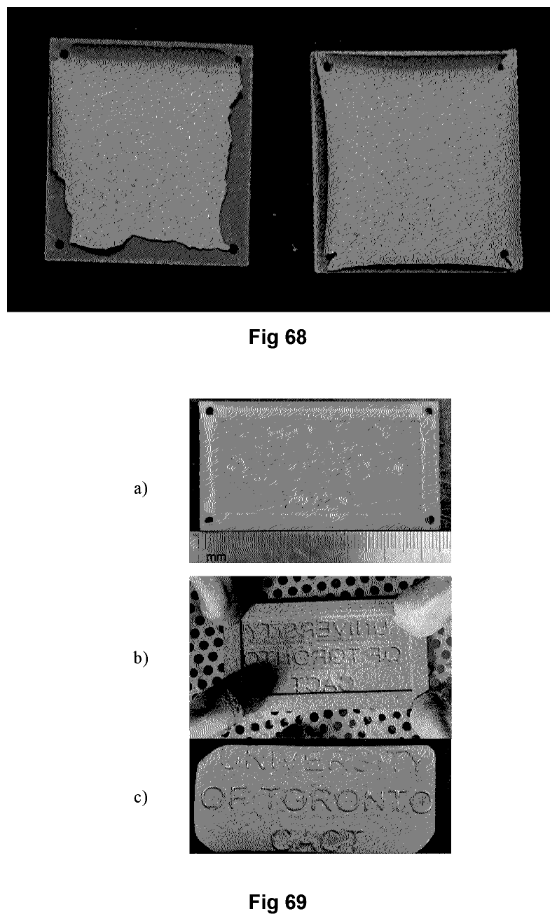

If the length L of the substrate is 50 mm and the radius of curvature R=0.9 m the ends will deflect by approximately δ=0.4 mm. This pulls the coating away from the substrate and if the normal stress generated is greater than the adhesion strength of the coating (σ_{A}), the coating will detach from the substrate. The greater the length L of the substrate, the greater the deflection and the stresses. FIG. 68 shows delamination in copper coated polymer coupons, starting around the edges where stresses are maximum which was observed after more than 5 passes of the spray gun over the substrate, which both increased the substrate temperature and the coating thickness.

Stresses in the coating can be minimized by reducing the temperature rise of the substrate during spraying so that the temperature decrease (ΔT) as it cools back to room temperature is minimized. This can be done by cooling the part during spraying using air jets, making the polymer component hollow to allow internal air circulation, or by increasing the interval between successive passes of the spray, giving the substrate more time to cool. Reducing the cross-sectional area of the substrate also reduces its stiffness so that some stress is transferred from the coating to the polymer, reducing the likelihood of a delamination. The thermal expansion coefficient of the substrate can be made closer to that of the metal sprayed on by mixing metal powder with the polymer so that the substrate is a polymer-metal composite.

Transferring Surface Features from Polymer to Metal

The spray technique can also be used to transfer surface patterns from the polymer to the metal sprayed on it. FIG. 69 shows a 65 mm×30 mm plate 3D printed using PVA in which writing was inscribed in Arial 20-point font in letters that were 0.5 mm deep (FIG. 69a). The surface was roughened by grit blasting with alumina particles (325-400 mesh size) and then a 150±10 μm thick layer of aluminum was deposited on it using a wire-arc spray (FIG. 69b). Epoxy was poured on the back of this and allowed to set to make the metal shell rigid. The plate was then placed in an ultrasonic bath for 30 minutes until the PVA detached. FIG. 69c shows the metal surface on which the writing from the polymer has been transferred with good resolution.

### Fabricating Internal Channels in Plates

Complex networks of channels, often used in microfluidics applications, can be created in metal plates using a thermal spray method. FIGS. 1-4 show steps in the fabrication of a serpentine channel, 1.5 mm wide and 1 mm high, in a copper plate that is 65 mm×6 mm×3 mm in size. The desired channel shape was 3D printed out of PVA (FIG. 15a). A groove was machined in the same shape in the copper plate and the insert was placed in it (FIG. 15b). The surface was grit-blasted and copper sprayed over the plate, creating a layer approximately 350±30 μm thick on the surface, completely covering the PVA insert (FIG. 15c). The plate was then placed in an ultrasonic water bath at 50° C. for approximately 4 hours until the PVA insert completely dissolved, leaving an open channel.

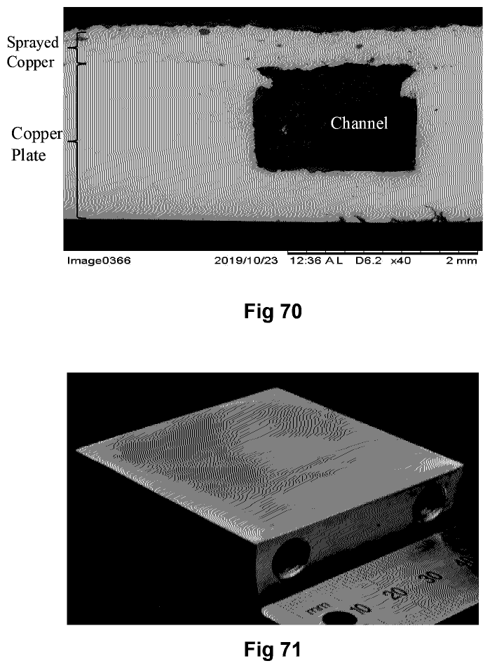

FIG. 70 shows a cross-section through a plate made by this method, in which the channel is visible. The channel shape was well-defined, though the sprayed copper is seen to penetrate the gap between the insert and the groove in the plate. The sprayed copper deposit had pores in it but was watertight when water was pumped through the channel. Photographs of the coating at different locations were taken with a magnification of 1.2K and analyzed with Image J software. The porosity of the coating, measured by averaging the data from four different locations was 17%.

Cold plates, which typically consist of aluminum plates in which copper water pipes are press-fitted, are frequently used for cooling electronic circuit boards that are placed on them. To maximize heat transfer it is important to have a large contact area between the water pipe and the plates, but in practice, this is limited by the minimum bending radius of the pipe. We used a thermal spray technique to make an aluminum cold plate that had internal cooling channels with a large wetted area. An aluminum plate, 57.2 mm square and 15.2 mm thick, had channels, 9.58 mm wide and 9.87 mm deep, machined in it to give four passes of the cooling fluid as shown in FIG. 6a. A step, 1.3 mm wide and 2.5 mm deep was machined along the entire length of the channels to provide room for sprayed metal droplets to land and adhere to the substrate.

Sacrificial tubes to be placed in the channels during thermal spraying were 3D-printed using water-soluble PVA. The tubes had an outer diameter of 9.65 mm and were hollow with a 1.3 mm wall thickness to make them easier to cool during spraying (see FIG. 6b). They were in the same shape as the channels machined in the aluminum plates into which they were press-fitted (see FIG. 6c). The plates were then grit blasted (alumina, grit size of 325-400) with an air pressure of 520 kPa to clean them and make them ready for thermal spray coating. An electric wire arc spray system was used to melt and spray high purity aluminum wires onto the surface of the plates. The substrates were cooled by maintaining a continuous airflow on them during spraying to minimize thermal stresses. The polymer inserts survived having aluminum sprayed directly on them, though they showed signs of expanding so that after spraying they protruded slightly from the ports made for fittings (see FIG. 6d). The aluminum coating deposited had an average thickness of approximately 2.70 mm. The coating surface was then ground down and polished to make it flat and smooth so that the final roughness was less than 1 μm. The plates were placed in an ultrasonic water bath at a temperature of 50° C. for 4 hours to dissolve the polymer inserts, leaving behind coolant channels in the aluminum cold plates (see FIG. 71). This technique can be used to make internal channels with arbitrary shapes and on curved surfaces.

### Conclusions and Findings

Copper and aluminum were deposited using a wire-arc system on PLA and PVA, polymers that are commonly used in 3D printers. For the metal coating to adhere the substrate is preferably rough enough for impinging droplets to penetrate crevices, solidify, and form mechanical bonds. A minimum average roughness of 1-2 μm is necessary for this to happen. The substrate temperature during spraying should preferably exceed the glass transition temperature at which the polymer begins to soften so that molten metal droplets penetrate the surface and partially bury themselves inside it. However, the substrate temperature should not exceed the melting temperature of the polymer, otherwise, surface asperities will melt and there will not be enough roughness for splats to form bonds. The adhesion strength of copper on all the polymers was approximately 1.5 to 2 MPa, sufficient to allow a coating of 200-300 μm to be built up.

Stresses are produced in the coating due to a mismatch of the thermal expansion coefficients of the metal and substrate. Polymers expand much more than metals when heated, so upon cooling, there is a compressive stress in the coating. This creates a curvature in the substrate, which increases with coating thickness, that acts to pull the coating off. Coating thickness and substrate heating during spraying should preferably both be limited to prevent coating delamination.

Surface features can also be made in metal by 3D printing them in a PVA panel, spraying metal over it, and then dissolving the PVA. Internal channels can be made in a plate by 3D printing a PVA insert in the shape of the channels, placing it in grooves machined in the same shape in the plate and spraying metal over the insert. The PVA insert is dissolved in water, leaving an open channel in the plate.

The following references are incorporated herein by reference:
J. Villafuerte, Considering Cold Spray for Additive Manufacturing, Adv. Mater. Process., 2014, 172(5), p 50-52.
N. Shahrubudin, T. C. Lee, and R. Ramlan, An Overview on 3D Printing Technology: Technological, Materials, and Applications, Procedia Manuf., 2019, 35, p 1286-1296.
R. Gonzalez, H. Ashrafizadeh, A. Lopera, P. Mertiny, and A. McDonald, A Review of Thermal Spray Metallization of Polymer-Based Structures, J. Therm. Spray Technol., 2016, 25(5), p 897-919.
G. Archambault, B. Jodoin, S. Gaydos, and M. Yandouzi, Metallization of Carbon Fiber Reinforced Polymer Composite by Cold Spray and Lay-up Molding Processes, Surf. Coatings Technol., 2016, 300, p 78-86.
H. Che, P. Vo, and S. Yue, Metallization of Carbon Fibre Reinforced Polymers by Cold Spray, Surf. Coatings Technol., 2017, 313, p 236-247.
H. Che, A. C. Liberati, X. Chu, M. Chen, A. Nobari, P. Vo, and S. Yue, Metallization of Polymers by Cold Spraying with Low Melting Point Powders, Surf. Coatings Technol., 2021, 418, p 127229.
Rezzoug, S. Abdi, A. Kaci, and M. Yandouzi, Thermal Spray Metallisation of Carbon Fibre Reinforced Polymer Composites: Effect of Top Surface Modification on Coating Adhesion and Mechanical Properties, Surf. Coatings Technol., 2018, 333, p 13-23.
Chen, X. Xie, Y. Xie, X. Yan, C. Huang, S. Deng, Z. Ren, and H. Liao, Metallization of Polyether Ether Ketone (PEEK) by Copper Coating via Cold Spray, Surf. Coatings Technol., 2018, 342, p 209-219.
R. Melentiev, N. Yu, and G. Lubineau, Polymer Metallization via Cold Spray Additive Manufacturing: A Review of Process Control, Coating Qualities, and Prospective Applications, Addit. Manuf., 2021, 48(PB), p 102459.
R. Gonzalez, A. McDonald, and P. Mertiny, Effect of Flame-Sprayed AI-12Si Coatings on the Failure Behaviour of Pressurized Fibre-Reinforced Composite Tubes, Polym. Test, 2013, 32(8), p 1522-1528.
Lopera-Valle and A. McDonald, Flame-Sprayed Coatings as de-Icing Elements for Fiber-Reinforced Polymer Composite Structures: Modeling and Experimentation, Int. J. Heat Mass Transf., 2016, 97, p 56-65.
S. T. Dehaghani, A. Dolatabadi, and A. McDonald, Thermally Sprayed Metal Matrix Composite Coatings as Heating Systems, Appl. Therm. Eng., 2021, 196, p 117321.
S. Nigam, S. S. Mahapatra, and S. K. Patel, Study of Various Aspects of Copper Coating on ABS Plastic by Electric Arc Spraying, Mater. Today Proc., 2018, 5(2), p 8446-8453.
S. Devaraj, B. Anand, M. Gibbons, A. McDonald, and S. Chandra, Thermal Spray Deposition of Aluminum and Zinc Coatings on Thermoplastics, Surf. Coatings Technol., 2020, 399, p 126114.
C. Feng, M. Gibbons, and S. Chandra, Fabrication of Composite Heat Sinks Consisting of a Thin Metallic Skin and a Polymer Core Using Wire-Arc Spraying, J. Therm. Spray Technol., 2019, 28(5), p 974-985.
S. Devaraj, A. McDonald, and S. Chandra, Metallization of Porous Polyethylene Using a Wire-Arc Spray Process for Heat Transfer Applications, J. Therm. Spray Technol., 2021, 30(1-2), p 145-156.
Fran Cverna, Therm. Prop. Met., ASM International, 2002.
G. Wypych, Handbook of Polymers, Elsevier, 2016
“Standard Test Method for Pull-Off Strength of Coatings Using Portable Adhesion Testers”, ASTM D4541-17, ASTM International, West Conshohocken, PA, 2017.
J. Andrade, C. González-Martinez, and A. Chiralt, The incorporation of carvacrol into poly (vinyl alcohol) films encapsulated in lecithin liposomes. Polymers, 2020, 12(2), p. 497.
C. A. Klein, R. P. Miller, Strains and stresses in multilayered elastic structures: The case of chemically vapor-deposited ZnS/ZnSe laminates, J. of Applied Physics 87, (2000) 2265-2272.
C. A. Klein, How accurate are Stoney's equation and recent modifications, J. of Applied Physics 88, (2000), 5487-5489.

### Miniature Liquid Cold-Plate Enabled by Metal Spraying: A Thermal Management Solution for a Modular 1 kW Bi-Directional GaN-Based Dc-Ac Converter

In recent years, power electronic systems have been consistently required to achieve higher power while also minimizing footprint. Addressing these demands has produced new electro-thermal challenges within these highly coupled systems. This work utilizes metal spraying techniques to fabricate a custom miniature liquid cold-plate to cool a 1 kW high-frequency bi-directional GaN-based dc-ac converter. A commercially sourced ‘off-the-shelf’ cold-plate, comprised of a serpentine copper tube embedded in an aluminum block and buried in low thermal conductivity epoxy is used as a baseline to compare the thermal performance of the proposed cold-plate. Experimental results show that the metal sprayed cold-plate yields lower junction temperatures at the same flow rate while also decreasing volume and mass when compared to the off-the-shelf system.

### Introduction

Over the last few decades, heat dissipation of wide band-gap (WBG) power electronic devices such as Gallium Nitride High Electron-Mobility Transistors (GaN HEMTs), has increased from 100 W/cm² to >1 kW/cm², while junction temperatures have remained constrained to below 150° C.-200° C. This growing trend has propagated new engineering challenges for the electro-thermal design of these highly coupled systems. Many researchers have investigated a spectrum of thermal management techniques for WBG devices such as channel design for enhanced heat transfer, jet impingement, and sub-zero environments. With regards to liquid cold-plates, Li et al. proposed the use of a metal foam liquid cold-plate for power electronics cooling. However, due to increasing demands of footprint miniaturization, this solution would yield extremely high pressure drops, an undesirable byproduct of these systems. Researchers have also investigated improving the coolant medium itself: Ijaz et al. investigated graphene oxide doped nano fluids with the goal of increasing heat transfer in liquid cooled heat sinks. The downside to this approach is that the coolant creates high pressure drops which could lead to potential clogging and corrosion of the piping network.

Despite these advancements in heat transfer research, thermal management systems are still lacking to meet the needs of these constantly higher power density systems. In our past work, three distinct electro-thermal design philosophies were utilized to design a 6.6 kW bi-directional on-board charger. This prior work demonstrated how traditional thermal management techniques fail to adequately cool high power density systems. The current work proposes the utilization of metal spraying to fabricate a custom miniature liquid cold-plate for a high-frequency bi-directional GaN-based dc-ac converter. The goal of this work is to miniaturize the thermal management system while targeting similar thermal performance as provided by commercial solutions, working within the constraints of low-cost bottom-side cooling methods through the utilization of copper filled vias.

### Metal Spraying Fabrication Method

Metal spraying has been used to fabricate heat exchangers, heat sinks, and heat pipes. Metal sprayed cold-plates offer the following advantages over traditional cold-plates: (i) iterative rapid prototyping; (ii) custom arrangement of flow channels to fit thermal needs without traditional manufacturing limitations; (iii) miniaturization of volume and mass; (iv) reduction of materials, therefore, reducing thermal resistances. Additionally, material costs for metal spraying are of the order of 9.79 USD/kg of aluminum, while the same quantity of aluminum costs 138 USD for 3D metal printing, demonstrating the cost benefit of this technique. Metal spraying is suited for mass manufacturability as fabrication time and cost are much lower than additive manufacturing techniques. The metal sprayed cold-plate, shown in FIG. 13, features two symmetric channels with two inlets and two outlets. The channels are designed to pass below the heat dissipating elements and avoid the mounting holes on the PCB. The straight section near the inlets passes below the GaN devices, and the serpentine section near the outlets passes below the high-frequency inductors. The cold-plate was fabricated using a novel wire-arc thermal spray deposition technique involving six steps:
1) Machine desired channel profile
2) Press-fit water-soluble insert
3) Roughen surface by grit blasting
4) Deposit aluminum coating
5) Dissolve water-soluble insert
6) Machine to final dimensions

First, the desired channel profile and inlet and outlet ports were machined into a 6.35 mm thick sheet of 6061 aluminum. The channel profiles, shown in FIG. 13, have a width of 8 mm and a depth of 4 mm. A lip with an offset of 1 mm from the channels and a depth of 1 mm was machined to enhance adhesion of the thermal spray, resulting in a channel cross section of 8 mm by 3 mm. An insert made of water-soluble Polyvinyl Alcohol (PVA) was then 3D printed and press-fit into the machined profile. The insert was made hollow with 1 mm thick walls to allow for thermal expansion of the insert during spraying and to reduce the amount of material to be dissolved once spraying was completed. The surface of the plate and insert were roughened by grit blasting 80 grit aluminum oxide powder using a constant air pressure of 80 psi at a distance of 25.4 cm to increase the adhesion of the metal spray. A 1 mm layer of aluminum was deposited onto the plate using wire-arc spray (Thermion, Silverdale, WA, USA), creating a sealed channel around the insert. A thickness of 1 mm was chosen for wall rigidity and to ensure sealing of the channel. Thinner walls can be deposited, though this limit was not investigated in the present study. For comparison, the copper tubing embedded in the off-the-shelf cold-plate has a wall thickness of 1.25 mm. The wire-arc process is shown in FIG. 50. An input arc voltage of 28 V was used and dry air at 100 psi was used as the atomizing gas. During coating deposition, the plate was cooled using two pressurized airjets at 100 psi. After the coating was complete, the plate was placed into an ultrasonic bath of water to dissolve the PVA insert. Mounting holes were added, and the plate was machined to its final shape. The heated surface of the cold-plate was polished using 1200 grit silicon carbide paper prior to testing to reduce thermal resistance between the plate and the thermal interface material (TIM).

### Electro-Thermal System Architectures

A reference cold-plate was used to compare with the proposed cold-plate. The off-the-shelf cold-plate was selected because it provides a compact, inexpensive commercially available solution to cool the PCB, as well as two high-frequency inductors that are outside the focus of this initial study. These commercial cold-plates have standardized serpentine flow loops and, therefore, the selected off-the-shelf cold-plate provides the necessary cooling for the targeted system. The off-the-shelf cold-plate presents mounting challenges for the converter topology, as evidenced by requiring the LS devices to be placed directly underneath the low thermal conductivity epoxy, and for reducing the number of usable mounting holes, due to the dimensions of the fluid channel. The volume and mass of the off-the-shelf cold-plate is 576.6 cm3 and 1.25 kg, respectively. In contrast, the mass and volume of the metal sprayed cold-plate is 78.5 cm3 and 0.09 kg, respectively. The dominant heat generating components on the PCB are the low-side (LS) and high-side (HS) GaN HEMTs as well as the current sensing resistors. These components are preferably maintained below 100° C. for reliable operation. Typically, the largest resistances are due to the PCB and the TIM.

### Electrical Design of High-Frequency Bidirectional DC-AC Converter

A 1 kW, 120 VAC bi-directional dc-ac converter is designed in a modular fashion for ease of scalability. The converter is connected to a 240 V dc bus voltage and a high switching frequency, fsw, of 200 kHz is enabled using GaN HEMTs as power switches. To reduce the volume of the output filter, a Sinusoidal PWM (SPWM) control scheme with unipolar voltage switching is implemented which results in the inductor current harmonics appearing at higher frequencies compared to other switching schemes.

The dc-ac converter is comprised of four switches, S1-S4, implemented using the bottom-side cooled GaN HEMTs, GS66508B, from GaN Systems. These GaN HEMTs achieve an ultra-low package inductance of 2 nH, which allows for low gate and drain voltage ringing, enabling high dV/dt at the switching node. The power-stage layout of the dc-ac converter is carefully designed to minimize the parasitic PCB inductance while maintaining symmetry along both axes. Due to the positioning of the gate and kelvin source pins on the GaN HEMT package, there are challenges in minimizing variations in the Gate Drive (GD) traces of all four switches. However, the effects of this variation are minimized by routing the gate driver traces for two switches, S2,4, beneath the switching node.

### Experimental Results

A prototype system is tested to validate the performance of the metal sprayed cold-plate. At 1 kW, the power stage dissipates a total of 52.4 W through the GaN HEMTs (13 W each) and the current sensors (0.2 W each). During testing, four J-type thermocouples (2.2° C. accuracy) are mounted on the top surface of each GaN HEMT while another two are used to measure inlet and outlet temperatures. The pressure drop across the cold-plates is measured using a differential pressure transducer (Omega PX2300-10DI) and the flow rate is measured from the chiller. Thermal data is captured over a 20 minute period to ensure thermal steady-state conditions. Water-glycol 50-50 is used as the coolant, and the inlet temperature is maintained at 17.5° C., while the surrounding air was measured to be 23° C.

The measured case temperatures were obtained. The thermal performance is insensitive to the coolant flow rate within this thermal resistance stack, as demonstrated for the metal sprayed cold-plate; therefore, the off-the-shelf system is only tested under one flow rate of 1.6 L/min, equivalent to a pumping power of 0.2 W, to establish a baseline. Th data shows that the off-the-shelf cold-plate can sustain device temperatures of 94.5° C. and 93° C. for LS devices, and 80° C. and 89° C. for the HS devices at 1 kW. In contrast, the metal sprayed cold-plate under the same flow rate, equivalent to a pumping power of 0.9 W, is able to maintain device temperatures of 67.5° C. and 73° C. for the LS devices and 87° C. for the HS devices at 1 kW. The metal sprayed cold-plate reduces device temperatures by 25% and 2.95% for the LS and HS devices, respectively, under the same flow rate, while also reducing the volume and mass by 88% and 93%, respectively. Moreover, the metal sprayed cold-plate achieves lower device temperatures as compared with the off-the-shelf cold-plate at even lower pumping power. The metal sprayed cold-plate also exhibited similar device temperatures at pumping powers ranging from 0.1 W to 2.3 W, demonstrating the independence between flow rate and case temperature. The temperature difference of the LS devices between the two cold-plates is due to the placement of the low thermal conductivity epoxy on the off-the-shelf cold-plate.

### Numerical Analysis

To complement experimental measurements, numerical simulations were conducted. All multi-physics electro-thermal models were solved using AN-SYS Icepak R20.1. Experimental conditions are imposed as boundary conditions in both numerical models. The boundary conditions are as follows: water-glycol 50-50 at 17.5° C. and 1.6 L/min at both inlet geometries. The ambient temperature is set to 23° C. The GaN HEMTs are modeled as network blocks which imposes a 0.5° C./W thermal resistance from junction-to-case and a 24° C./W junction-to-ambient thermal resistance as prescribed by the manufacturer. Then 13 Ware imposed at the center of the device volume. The material property of these devices is set to GaN. The PCB is modeled using an ODB++ representation of the actual fabricated layout from Altium, which takes into consideration the copper and FR4 traces throughout the PCB. The current sensors are modeled using an SiC material properties of: 3200 kg/m3, 1200 J/kg-K, 450 W/m-K for density, specific heat, and thermal conductivity, respectively, with 0.2 W distributed throughout the entire device volume. The TIM is modeled using the material properties given by the manufacturer which are as follows: 2800 kg/m3, 850 J/kg-K, 1.9 W/m-K, for density, specific heat, and thermal conductivity, respectively. The temperature contours of the PCB and heat generating devices were obtained when cooled with the off-the-shelf cold-plate. The error between measured and numerical values is 16%. This error is due to the system being exposed to the ambient environment during testing. It is calculated that 85% of the heat transfer occurs through conduction and therefore 15% is convected away to the surrounding medium. Similarly, FIG. 6(b) shows the temperature contours of the PCB and heat generating devices when cooled with the metal sprayed cold-plate. The error for this simulation is also 16%, as previously explained; this error is consistent with the heat that was convected away to the surrounding ambient air. With this accounted, the simulated temperatures show good agreement with the measured temperatures. To investigate the noticeable temperature gradient between the LS and HS devices, it was found that the temperature contours with the TIM replaced by aluminum, and that the resulting contours with the isolation clearance removed around the HS devices. The isolation clearance imposes a significant thermal resistance around the HS devices which causes a noticeable temperature gradient between the two sets of devices.

To further understand the thermal resistances within the simulated systems, the temperature profiles from the devices to the working fluid were plotted, for both the metal-sprayed and off-the-shelf cold-plates. These temperature profiles showed that the majority of the thermal resistance occurs in the PCB and TIM layers of the system stack. Furthermore, these profiles corroborate the higher device temperatures exhibited by the HS devices, due to the temperature gradient within the PCB layers. The metal sprayed cold-plate has a much lower thermal resistance since the heat is conducted only through aluminum compared to the off-the-shelf cold-plate where layers of epoxy and copper are present underneath the LS devices. Finally, using these temperature profiles, the total thermal resistance from device to working fluid is estimated to be 3.22° C./W for the LS devices and 4.70° C./W for the HS devices when mounted to the metal sprayed cold-plate, and 5.84° C./W for the LS devices and 6.28° C./W for the HS devices when mounted to the off-the-shelf cold-plate. Due to the homogeneity of the metal sprayed cold-plate, the overall thermal resistance is lower compared to the off-the-shelf cold-plate, where layers of copper and low thermal conductivity epoxy are present, thus, reducing device temperatures.

### CONCLUSIONS AND FINDINGS

This work demonstrates that the metal sprayed liquid cold-plate offers device temperature reductions of 25% and 2.95% for the LS and HS GaN HEMT devices, respectively, while simultaneously reducing volume and mass compared to the off-the-shelf system. This is primarily due to the reduced thermal resistance, achieved by replacing the various material layers on the off-the-shelf cold-plate with a thin layer of aluminum. Additionally, the metal spray fabrication process allows for custom cooling channels to target the GaN HEMT switches and high-frequency inductors, while concurrently providing clearance around the PCB mounting locations. It was also shown that bottom-side cooling with PCB-mounted devices and a miniature custom cold-plate is attractive for these relatively low-power (sub 10 kW), low-cost, high-frequency converters. A top-side cooled version of this system could also be constructed to enhance thermal management performance enabled by metal spraying fabrication techniques.

### Additional Comments Regarding Technology, Terms & Implementations

It is noted that the various methods and systems described herein can be inter-combined in various ways. For example, one or more of the methods for spraying onto a substrate to form enclosed flow regions can be combined with one or more of the methods for spraying through a mask to form raised structures on a base. It is also noted that the term “substrate” used herein refers to a structure upon which a sprayed coating is provided to form enclosed regions and which is removed or voided by methods such as dissolution, while the term “mask” as used herein refers to a structure that has one or more openings through which sprayed material passes to form corresponding raised structures on a base and which is removed after spray deposition. The substrate and mask are described herein as being optionally polymeric and having certain preferable properties for their respective purposes in the context of the processes described herein. In addition, while embodiments are described where the substrate and mask both composed of polymers, it should be noted that processes could be performed where the mask is polymeric while the substrate is not or where the substrate is polymeric while the mask is not. It is also possible to envision processes where neither the mask nor the substrate is polymeric, e.g., using a removable metal mask in a first spray stage and then using a metal substrate in the second spray stage where the metal substrate is melted for removal after the second spray stage.

1. A process for manufacturing a heat transfer device, comprising:
spraying molten metal droplets onto a polymer substrate having a surface region comprising a soluble thermoplastic to form metal splats on the surface region, wherein the surface region has surface properties and the molten metal droplets impact the surface region at a splat temperature such that the metal splats penetrate into the surface region and mechanically interlock to form a solid metal coating adhered to the polymer substrate; and
contacting the polymer substrate with a solvent fluid to dissolve the soluble thermoplastic and remove the polymer substrate to form an enclosed flow region defined at least in part by the solid metal coating, the enclosed flow region being configured for passage of a heat transfer fluid.

2. The process of claim 1, wherein the surface properties comprise a surface roughness between 1 μm and 10 μm.

3. The process of claim 1, wherein the surface properties comprise a surface roughness between above 2 μm.

4. The process of claim 2, wherein the surface roughness enables the metal splats to penetrate the surface region, and the soluble thermoplastic and the splat temperature are provided such that the surface region remains below a melting temperature of the water-solution thermoplastic during contact with the metal splats.

5. The process of claim 1, wherein the surface properties comprise a porosity with pore size between 1 μm and 10 μm, and the splat temperature is sufficiently high to enable the metal splats to melt an outer surface of the polymer substrate and penetrate into pores thereof.

6. The process of claim 5, wherein the porosity is above 2 μm.

7. The process of claim 1, wherein the surface properties and the splat temperature are provided such that the solid metal coating adheres to the surface region at an adhesion strength above 2 MPa.

8. The process of claim 1, further comprising preheating the polymer substrate above a glass transition temperature of the soluble thermoplastic prior to impacting with the metal splats to reduce a temperature difference between the surface region and the metal splats during the spraying.

9. The process of claim 1, further comprising removing heat from the polymer substrate during the spraying to restrict a maximum temperature of the surface region below a melting temperature thereof and reduce a temperature differential between the maximum temperature during the spraying and a cooled temperature of the polymer substrate attained after completion of the spraying, thereby reducing stresses generated in the solid metal coating during formation thereof.

10. The process of claim 1, wherein the polymer substrate is positioned on a metal base prior to the spraying, and the spraying is performed such that the polymer substrate is at least partially enclosed by the solid metal coating and the metal base.

11. The process of claim 1, wherein the splat temperature is provided based at least on a melting temperature of the metal, a spray distance from the polymer substrate, and a spray pass rate.

12. The process of claim 1, further comprising providing an adhesion strength between the solid metal coating and the polymer substrate that is greater than a stress generated in the heat transfer material.

13. The process of claim 1, wherein the polymer substrate has a hollow shape and a cooling fluid is provided therein during the spraying to remove heat therefrom.

14. The process of claim 1, wherein the polymer substrate is configured as grid comprising a network of openings such that the enclosed flow region has the form of an interconnected flow network.

15. (canceled)

16. The process of claim 1, wherein the soluble thermoplastic comprises a water-soluble thermoplastic and the solvent fluid comprises an aqueous fluid.

17. The process of claim 16, wherein the water-soluble thermoplastic comprises polyvinyl alcohol (PVA), polyethylene oxide (PEO), and/or a natural polymer.

18. The process of claim 16, wherein the aqueous fluid comprises water that is flowed in contact the polymer substrate to dissolve and remove the polymer substrate.

19. (canceled)

20. The process of claim 1, wherein the polymer substrate further comprises an additive that reduces a thermal expansion coefficient of the polymer substrate.

21. (canceled)

22. (canceled)

23. (canceled)

24. (canceled)

25. The process of claim 10, wherein the metal base comprises abase surface and raised structures extending from the base surface defining recesses, and the substrate is provided in the recesses prior to the spraying.

26. (canceled)

27. (canceled)

28. (canceled)

29. (canceled)

30. The process of claim 25, wherein the polymer substrate is provided as a paste that is provided to fill the recesses and then cured to provide a cured substrate prior to the spraying thereon.

31. (canceled)

32. (canceled)

33. (canceled)

34. (canceled)

35. (canceled)

36. (canceled)

37. (canceled)

38. (canceled)

39. (canceled)

40. A process comprising:
spraying molten metal droplets through a polymeric mask comprising openings and overlying and being spaced-away from a metal base to form raised metal structures extending from the base to a height at or below a lower surface of the mask;
removing the mask to expose a recessed region defined between the raised metal structures;
filing the recessed region with a substrate;
spraying molten metal droplets to form a solid metal coating adhered to and enclosing the substrate; and
removing the substrate to form an enclosed flow region defined by the solid metal coating, the metal base and the raised structures.

41. The process of claim 40, wherein the substrate is composed of a polymer, and the removing comprises dissolving using a solvent.

42. (canceled)

43. (canceled)

44. (canceled)

45. A process comprising:
spraying molten metal droplets through a polymeric mask comprising openings and overlying a metal base to form raised metal structures extending from the base; and
removing the mask to expose a recessed region define between the raised metal structures; and
wherein the polymeric mask is positioned to provide a gap between a lower surface of the mask and the base surface, has a smoothness inhibiting adhesion of metal during the spraying, and has a composition and thickness to inhibit thermal deformation during spraying, such that molten metal droplets impact the base and agglomerate to form the raised structures having a height at or below a lower surface of the mask for facilitating release of the mask after the spraying.
